(19) United States
(12) Patent Application Publication
(10) Pub. No.: US 2024/0117102 A1
(43) Pub. Date: Apr. 11, 2024

(54) POLYMER, COMPOSITION, METHOD FOR PRODUCING POLYMER, COMPOSITION FOR FILM FORMATION, RESIST COMPOSITION, RESIST PATTERN FORMATION METHOD, RADIATION-SENSITIVE COMPOSITION, COMPOSITION FOR UNDERLAYER FILM FORMATION FOR LITHOGRAPHY, METHOD FOR PRODUCING UNDERLAYER FILM FOR LITHOGRAPHY, CIRCUIT PATTERN FORMATION METHOD, AND COMPOSITION FOR OPTICAL MEMBER FORMATION

(71) Applicant: Mitsubishi Gas Chemical Company, Inc., Tokyo (JP)

(72) Inventors: Kodai MATSUURA, Hiratsuka-shi, Kanagawa (JP); Junya HORIUCHI, Hiratsuka-shi, Kanagawa (JP); Yu OKADA, Hiratsuka-shi, Kanagawa (JP); Tadashi OMATSU, Hiratsuka-shi, Kanagawa (JP); Masatoshi ECHIGO, Tokyo (JP)

(21) Appl. No.: 18/273,014

(22) PCT Filed: Jan. 11, 2022
(86) PCT No.: PCT/JP2022/000590

§ 371 Date: Jul. 18, 2023

(30) Foreign Application Priority Data
Jan. 19, 2021 (JP) 2021-006655

(51) Int. Cl. C08G 61/02; C08G 8/16; C08G 8/22; G03F 7/038; G03F 7/039; G03F 7/11; G03F 7/22; G03F 7/26; H01L 21/027

(52) U.S. Cl. CPC C08G 61/025; C08G 8/16; C08G 8/22; G03F 7/038; G03F 7/039; G03F 7/11; G03F 7/22; G03F 7/26; H01L 21/027

(57) ABSTRACT

A polymer having a constituent unit derived from a monomer represented by the following formula (0), wherein the polymer has sites in which the constituent units are linked by direct bonding between aromatic rings of the monomer represented by the formula (0):

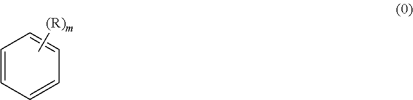

wherein R is a monovalent group, and m is an integer of 1 to 5, wherein at least one R is a hydroxyl group, an alkoxy group having 1 to 40 carbon atoms and optionally having a substituent, or an amino group having 0 to 40 carbon atoms and optionally having a substituent.

### TECHNICAL FIELD

The present invention relates to a polymer, a composition, a method for producing a polymer, a composition for film formation, a resist composition, a resist pattern formation method, a radiation-sensitive composition, a composition for underlayer film formation for lithography, a method for producing an underlayer film for lithography, a circuit pattern formation method, and a composition for optical member formation.

### BACKGROUND ART

Polyphenol-based resins having repeating units derived from a hydroxy-substituted aromatic compound or the like are known as sealants, coating agents, resist materials, and semiconductor underlayer film forming materials for semiconductors. For example, Patent Literatures 1 and 2 propose the use of a polyphenol compound or resin having a specific skeleton.

Meanwhile, as a method for producing a polyphenol-based resin, there is known a method for producing a novolac resin or a resol resin by addition-condensation of a phenol and formalin in the presence of an acid or an alkali catalyst. This method for producing a phenol resin uses formaldehyde, which has been pointed out to have a problem in safety, as a raw material for the phenol resin. Thus, various other methods using substances other than formaldehyde have been studied in recent years. As a method for producing a polyphenol-based resin to solve this problem, there has been proposed a method for producing a phenol polymer by oxidative polymerization of a phenol in a solvent such as water or an organic solvent using an enzyme having a peroxidase activity such as peroxidase and a peroxide such as hydrogen peroxide. Further, there is also known a method for producing polyphenylene oxide (PPO) by oxidative polymerization of 2,6-dimethylphenol (see Non Patent Literature 1).

In the production of semiconductor devices, fine processing is practiced by lithography using photoresist materials. In recent years, further miniaturization based on pattern rules has been demanded along with increase in the integration and speed of LSI.

Lithography using light exposure, which is currently used as a general purpose technique, is approaching the limit of essential resolution derived from the wavelength of a light source.

The light source for lithography used upon forming resist patterns has been shifted to ArF excimer laser (193 nm) having a shorter wavelength from KrF excimer laser (248 nm). However, as the miniaturization of resist patterns proceeds, the problem of resolution or the problem of collapse of resist patterns after development arises. Therefore, resists have been desired to have a thinner film. If resists merely have a thinner film in response to such a demand, it is difficult to obtain the film thicknesses of resist patterns sufficient for substrate processing. Therefore, there has been a need for a process of preparing a resist underlayer film between a resist and a semiconductor substrate to be processed, and imparting functions as a mask for substrate processing to this resist underlayer film in addition to a resist pattern.

Various resist underlayer films for such a process are currently known. Examples thereof can include resist underlayer films for lithography having the selectivity of a dry etching rate close to that of resists, unlike conventional resist underlayer films having a fast etching rate. As a material for forming such resist underlayer films for lithography, an underlayer film forming material for a multilayer resist process containing a resin component having at least a substituent that generates a sulfonic acid residue by eliminating a terminal group under application of predetermined energy, and a solvent has been suggested (see, for example, Patent Literature 3). Another example thereof can include resist underlayer films for lithography having the selectivity of a dry etching rate smaller than that of resists. As a material for forming such resist underlayer films for lithography, a resist underlayer film material comprising a polymer having a specific constituent unit has been suggested (see, for example, Patent Literature 4). Further examples thereof can include resist underlayer films for lithography having the selectivity of a dry etching rate smaller than that of semiconductor substrates. As a material for forming such resist underlayer films for lithography, a resist underlayer film material comprising a polymer prepared by copolymerizing a constituent unit of an acenaphthylene and a constituent unit having a substituted or unsubstituted hydroxyl group has been suggested (see, for example, Patent Literature 5). A resist underlayer film material comprising an oxidized polymer of a specific bisnaphthol compound has been suggested (see, for example, Patent Literature 6).

Meanwhile, as materials having high etching resistance for this kind of resist underlayer film, amorphous carbon underlayer films formed by chemical vapor deposition (hereinafter also referred to as “CVD”) using methane gas, ethane gas, acetylene gas, or the like as a raw material are well known. However, resist underlayer film materials that can form resist underlayer films by a wet process such as spin coating or screen printing have been demanded from the viewpoint of a process.

Recently, layers to be processed having a complicated shape have been desired to form a resist underlayer film for lithography. Thus, there is a demand for a resist underlayer film material that can form an underlayer film excellent in embedding properties or film surface flattening properties.

As for methods for forming an intermediate layer used in the formation of a resist underlayer film in a three-layer process, for example, a method for forming a silicon nitride film (see, for example, Patent Literature 7) and a CVD formation method for a silicon nitride film (see, for example, Patent Literature 8) are known. Also, as intermediate layer materials for a three-layer process, materials comprising a silsesquioxane-based silicon compound are known (see, for example, Patent Literature 9).

The present inventors have suggested a composition for underlayer film formation for lithography comprising a specific compound or resin (see, for example, Patent Literature 10).

Various optical member forming compositions have been suggested, and, for example, an acrylic resin (see, for example, Patent Literatures 11 and 12) and polyphenol having a specific structure derived from an allyl group (see, for example, Patent Literature 13) have been suggested.

### CITATION LIST

### Patent Literature

Patent Literature 1: International Publication No. WO 2013/024778
Patent Literature 2: International Publication No. WO 2013/024779
Patent Literature 3: Japanese Patent Laid-Open No. 2004-177668
Patent Literature 4: Japanese Patent Laid-Open No. 2004-271838
Patent Literature 5: Japanese Patent Laid-Open No. 2005-250434
Patent Literature 6: Japanese Patent Laid-Open No. 2020-027302
Patent Literature 7: Japanese Patent Laid-Open No. 2002-334869
Patent Literature 8: International Publication No. WO 2004/066377
Patent Literature 9: Japanese Patent Laid-Open No. 2007-226204
Patent Literature 10: International Publication No. WO 2013/024779
Patent Literature 11: Japanese Patent Laid-Open No. 2010-138393
Patent Literature 12: Japanese Patent Laid-Open No. 2015-174877
Patent Literature 13: International Publication No. WO 2014/123005

### Non Patent Literature

Non Patent Literature 1: Hideyuki Higashimura, Shiro Kobayashi, Chemistry and Industry, 53, 501 (2000)

### SUMMARY OF INVENTION

### Technical Problem

The materials described in Patent Literatures 1 and 2 still have room for improvement in performance such as heat resistance and etching resistance, and there is a need to develop new materials that are even better in these properties.

Further, the polyphenol-based resin obtained based on the method of Non Patent Literature 1 contains both an oxyphenol unit and a unit having a phenolic hydroxy group in the molecule as constituent units. The oxyphenol unit is usually obtained by forming a bond between a carbon atom on an aromatic ring of one phenol as a monomer and a phenolic hydroxy group of the other phenol. Further, the unit having a phenolic hydroxy group in the molecule is obtained by bonding a phenol as a monomer between carbon atoms on the aromatic ring. Such a polyphenol-based resin becomes a polymer having flexibility because the aromatic rings are bonded to each other via an oxygen atom, but is not preferable from the viewpoint of crosslinkability and heat resistance because the phenolic hydroxy group disappears.

As mentioned above, a large number of film forming materials for lithography have heretofore been suggested. However, none of these materials achieve both of heat resistance and etching resistance at high dimensions. Thus, the development of novel materials is required.

Furthermore, a large number of compositions intended for optical members have heretofore been suggested. However, none of these compositions achieve all of heat resistance, transparency and an index of refraction at high dimensions. Thus, the development of novel materials is required.

The present invention has been made in view of the above problems, and an object of the present invention is to provide a polymer excellent in heat resistance and etching resistance, a composition, a method for producing a polymer, a composition for film formation, a resist composition, a resist pattern formation method, a radiation-sensitive composition, a composition for underlayer film formation for lithography, a method for producing an underlayer film for lithography, a circuit pattern formation method, and a composition for optical member formation.

### Solution to Problem

The present inventors have, as a result of devoted examinations to solve the above problems, found out that use of a polymer having a specific structure can solve the above problems, and reached the present invention.

Specifically, the present invention includes the following aspects.

<1> A polymer comprising a constituent unit derived from a monomer represented by the following formula (0),
wherein the polymer has sites in which the constituent units are linked by direct bonding between aromatic rings:

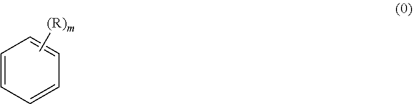

wherein R is a monovalent group, and m is an integer of 1 to 5, wherein at least one R is a hydroxyl group, an alkoxy group having 1 to 40 carbon atoms and optionally having a substituent, or an amino group having 0 to 40 carbon atoms and optionally having a substituent.

<2> The polymer according to <1>, wherein in the formula (0), m is 2 or more, and at least two R are a hydroxyl group, an alkoxy group having 1 to 40 carbon atoms and optionally having a substituent, or an amino group having 0 to 40 carbon atoms and optionally having a substituent.

<3> The polymer according to <1> or <2>, further comprising a constituent unit derived from an other copolymerizable compound that is copolymerizable with the monomer represented by the formula (0), wherein a molar ratio (x:y) of the constituent unit (x) derived from the monomer represented by the formula (0) to the constituent unit derived from the other copolymerizable compound (y) is 1:99 to 99:1.

<4> The polymer according to <3>, wherein the other copolymerizable compound is selected from the group consisting of monomers represented by the following formulas (1A) to (1D), and a heteroatom-containing aromatic monomer:

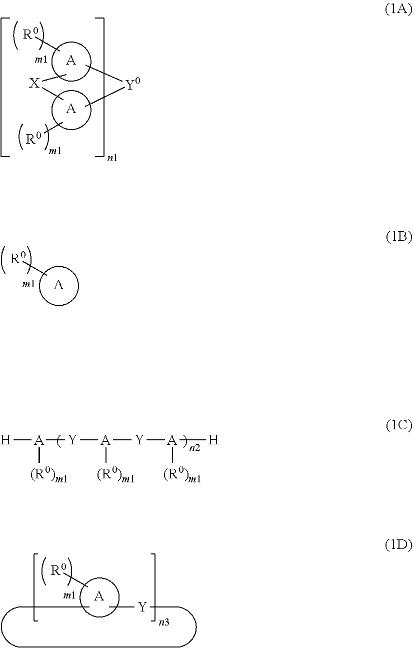

wherein in the formula (1A), each X independently represents an oxygen atom, a sulfur atom, a single bond or not a crosslink, Y⁰ is a 2n-valent group having 1 to 60 carbon atoms or a single bond, wherein when X is not a crosslink, Y⁰ is the 2n1-valent group, each A is independently benzene, biphenyl, terphenyl, diphenylmethylene, or a fused ring, each R⁰ is independently a hydrogen atom, an alkyl group having 1 to 40 carbon atoms and optionally having a substituent, an aryl group having 6 to 40 carbon atoms and optionally having a substituent, an alkenyl group having 2 to 40 carbon atoms and optionally having a substituent, an alkynyl group having 2 to 40 carbon atoms, an alkoxy group having 1 to 40 carbon atoms and optionally having a substituent, a halogen atom, a thiol group, an amino group, a nitro group, a carboxyl group, or a hydroxyl group, wherein at least one R⁰ is a hydroxyl group, an alkoxy group having 1 to 40 carbon atoms and optionally having a substituent, or an amino group having 0 to 40 carbon atoms and optionally having a substituent, each m1 is independently an integer of 1 or more, and n1 is an integer of 1 to 4;
in the formula (1B), A, R⁰, and m1 are as defined in the formula (1A), and at least one R⁰ is a hydroxyl group, an alkoxy group having 1 to 40 carbon atoms and optionally having a substituent, or an amino group having 0 to 40 carbon atoms and optionally having a substituent;
in the formula (1C), n2 is an integer of 1 to 500, and Y is a divalent group having 1 to 60 carbon atoms or a single bond, and A, R⁰, and m1 are as defined in the formula (1A), and at least one R⁰ is a hydroxyl group, an alkoxy group having 1 to 40 carbon atoms and optionally having a substituent, or an amino group having 0 to 40 carbon atoms and optionally having a substituent; and
in the formula (1D), n3 is an integer of 1 to 10, Y is as defined in the formula (1C), A, R⁰, and m1 are as defined in the formula (1A), and at least one R⁰ is a hydroxyl group, an alkoxy group having 1 to 40 carbon atoms and optionally having a substituent, or an amino group having 0 to 40 carbon atoms and optionally having a substituent.

<5> The polymer according to <4>, wherein the compound represented by the following formula (1A) is a compound represented by the following formula (1A-1):

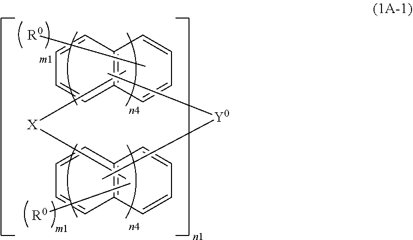

wherein each n4 is independently an integer of 0 to 3, and X, Y⁰, R⁰, m1, and n1 are as defined in the formula (1A).

<6> The polymer according to <4>, wherein A is benzene, biphenyl, terphenyl, diphenylmethylene, naphthalene, anthracene, naphthacene, pentacene, benzopyrene, chrysene, pyrene, triphenylene, corannulene, coronene, ovalene, or fluorene.

<7> The polymer according to <4>, wherein the compound represented by the formula (1C) is a compound represented by the following formula (1C-1):

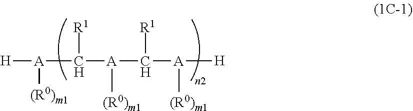

wherein each R¹ is independently a hydrogen atom, an alkyl group having 1 to 40 carbon atoms and optionally having a substituent, an aryl group having 6 to 40 carbon atoms and optionally having a substituent, an alkenyl group having 2 to 40 carbon atoms and optionally having a substituent, an alkynyl group having 2 to 40 carbon atoms, an alkoxy group having 1 to 40 carbon atoms and optionally having a substituent, a halogen atom, a thiol group, an amino group, a nitro group, a carboxyl group, or a hydroxyl group, A, R⁰, m1, and n2 are as defined in the formula (1C), and at least one R⁰ is a hydroxyl group, an alkoxy group having 1 to 40 carbon atoms and optionally having a substituent, or an amino group having 0 to 40 carbon atoms and optionally having a substituent.

<8> The polymer according to <4>, wherein the compound represented by the formula (1D) is a compound represented by the following formula (1D-1):

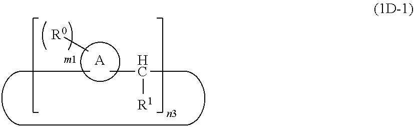

wherein each R¹ is independently a hydrogen atom, an alkyl group having 1 to 40 carbon atoms and optionally having a substituent, an aryl group having 6 to 40 carbon atoms and optionally having a substituent, an alkenyl group having 2 to 40 carbon atoms and optionally having a substituent, an alkynyl group having 2 to 40 carbon atoms, an alkoxy group having 1 to 40 carbon atoms and optionally having a substituent, a halogen atom, a thiol group, an amino group, a nitro group, a carboxyl group, or a hydroxyl group, A, R⁰, m1, and n3 are as defined in the formula (1D), and at least one R⁰ is a hydroxyl group, an alkoxy group having 1 to 40 carbon atoms and optionally having a substituent, or an amino group having 0 to 40 carbon atoms and optionally having a substituent.

<9> The polymer according to <4>, wherein the heteroatom-containing aromatic monomer comprises a heterocyclic aromatic compound.

<10> A composition comprising the polymer according to any one of <1> to <9>.

<11> The composition according to <10>, further comprising a solvent.

<12> The composition according to <11>, wherein the solvent comprises at least one selected from the group consisting of propylene glycol monomethyl ether, propylene glycol monomethyl ether acetate, cyclohexanone, cyclopentanone, ethyl lactate, and methyl hydroxyisobutyrate.

<13> The composition according to <11> or <12>, wherein a content of impurity metal is less than 500 ppb for each metal species.

<14> The composition according to <13>, wherein the impurity metal comprises at least one selected from the group consisting of copper, manganese, iron, cobalt, ruthenium, chromium, nickel, tin, lead, silver, and palladium.

<15> The composition according to <13> or <14>, wherein the content of the impurity metal is 1 ppb or less.

<16> A method for producing the polymer according to any one of <1> to <9>, comprising the step of:
polymerizing one or more monomers represented by the formula (0) in the presence of an oxidizing agent.

<17> A method for producing the polymer according to <16>, comprising the step of:
polymerizing one or more monomers represented by the formula (0) and an other copolymerizable compound that is copolymerizable with the monomer represented by the formula (0) in the presence of an oxidizing agent.

<18> The method for producing the polymer according to <16> or <17>, wherein the oxidizing agent is a metal salt or metal complex containing at least one selected from the group consisting of copper, manganese, iron, cobalt, ruthenium, chromium, nickel, tin, lead, silver, and palladium.

<19> A composition for film formation comprising the polymer according to any one of <1> to <9>.

<20> A resist composition comprising the composition for film formation according to <19>.

<21> The resist composition according to <20>, further comprising at least one selected from the group consisting of a solvent, an acid generating agent, a base generating agent, and an acid diffusion controlling agent.

<22> A resist pattern formation method, comprising the steps of:
forming a resist film on a substrate using the resist composition according to <20> or <21>;
exposing at least a portion of the formed resist film; and
developing the exposed resist film, thereby forming a resist pattern.

<23> A radiation-sensitive composition comprising the composition for film formation according to <19>, an optically active diazonaphthoquinone compound, and a solvent,
wherein a content of the solvent is 20 to 99 parts by mass based on 100 parts by mass in total of the radiation-sensitive composition, and
a content of a solid content except for the solvent is 1 to 80 parts by mass based on 100 parts by mass in total of the radiation-sensitive composition.

<24> A resist pattern formation method, comprising the steps of:
forming a resist film on a substrate using the radiation-sensitive composition according to <23>;
exposing at least a portion of the formed resist film; and
developing the exposed resist film, thereby forming a resist pattern.

<25> A composition for underlayer film formation for lithography comprising the composition for film formation according to <19>.

<26> The composition for underlayer film formation for lithography according to <25>, further comprising at least one selected from the group consisting of a solvent, an acid generating agent, a base generating agent, and a crosslinking agent.

<27> A method for producing an underlayer film for lithography, comprising the step of:
forming an underlayer film on a substrate using the composition for underlayer film formation for lithography according to <25> or <26>.

<28> A resist pattern formation method, comprising the steps of:
forming an underlayer film on a substrate using the composition for underlayer film formation for lithography according to <25> or <26>;
forming at least one photoresist layer on the underlayer film; and
irradiating a predetermined region of the photoresist layer with radiation for development, thereby forming a resist pattern.

<29> A circuit pattern formation method, comprising the steps of:
forming an underlayer film on a substrate using the composition for underlayer film formation for lithography according to <25> or <26>;
forming an intermediate layer film on the underlayer film using a resist intermediate layer film material containing a silicon atom;
forming at least one photoresist layer on the intermediate layer film;
irradiating a predetermined region of the photoresist layer with radiation for development, thereby forming a resist pattern;
etching the intermediate layer film with the resist pattern as a mask, thereby forming an intermediate layer film pattern;
etching the underlayer film with the intermediate layer film pattern as an etching mask, thereby forming an underlayer film pattern; and
etching the substrate with the underlayer film pattern as an etching mask, thereby forming a pattern on the substrate.

<30> A composition for optical member formation comprising the composition for film formation according to <19>.

<31> The composition for optical member formation according to <30>, further comprising at least one selected from the group consisting of a solvent, an acid generating agent, a base generating agent, and a crosslinking agent.

<32> A purification method comprising the steps of:
obtaining a solution (S) by dissolving the polymer according to any one of claims 1 to 9 in a solvent; and
extracting impurities in the polymer by bringing the obtained solution (S) into contact with an acidic aqueous solution (a first extraction step),
wherein the solvent used in the step of obtaining the solution (S) contains an organic solvent that does not inadvertently mix with water.

### Advantageous Effects of Invention

According to the present invention, it is possible to provide a polymer excellent in heat resistance and etching resistance, a composition, a method for producing a polymer, a composition for film formation, a resist composition, a resist pattern formation method, a radiation-sensitive composition, a composition for underlayer film formation for lithography, a method for producing an underlayer film for lithography, a circuit pattern formation method, and a composition for optical member formation.

### DESCRIPTION OF EMBODIMENTS

A mode for carrying out the present invention (hereinafter referred to as “present embodiment”) will be described in detail below, but the present invention is not limited to this, and various modifications can be made without departing from the spirit thereof.

### [Polymer]

A polymer of the present embodiment is a polymer having a constituent unit derived from a monomer represented by the formula (0), wherein the polymer has sites in which the constituent units are linked by direct bonding between aromatic rings of the monomer represented by the formula (0). Since the polymer of the present embodiment is configured as described above, it has superior performance in terms of performance such as heat resistance and etching resistance.

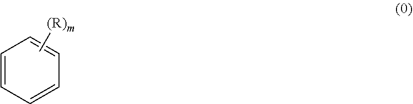

In the formula (0), R is a monovalent group, and m is an integer of 1 to 5, wherein at least one R is a hydroxyl group, an alkoxy group having 1 to 40 carbon atoms and optionally having a substituent, or an amino group having 0 to 40 carbon atoms and optionally having a substituent.

The polymer according to the present embodiment typically has the following characteristics (1) to (4), but is not limited thereto.

(1) The polymer of the present embodiment has excellent solubility in an organic solvent (particularly, a safe solvent). Therefore, for example, when the polymer of the present embodiment is used as a film forming material for lithography, films for lithography can be formed by a wet process such as spin coating or screen printing.

(2) In the polymer of the present embodiment, the carbon concentration is relatively high and the oxygen concentration is relatively low. In addition, since the polymer of the present embodiment has a reaction active site in the molecule, it is useful for formation of a cured product through the reaction with a curing agent, but it can also form a cured product on its own through the crosslinking reaction of the reaction active site upon baking at a high temperature. Due to the above, the polymer of the present embodiment can exhibit high heat resistance, and when used as a film forming material for lithography, degradation of the film upon baking at a high temperature is suppressed and a film for lithography excellent in etching resistance to oxygen plasma etching and the like can be formed.

(3) The polymer of the present embodiment can exhibit high heat resistance and etching resistance, as described above, and also has excellent adhesiveness to a resist layer and a resist intermediate layer film material. Therefore, when the polymer of the present embodiment is used as a film forming material for lithography, films for lithography excellent in resist pattern formability can be formed. The term “resist pattern formability” herein refers to a property in which there are no major defects in the resist pattern shape and both resolution and sensitivity are excellent.

(4) The polymer of the present embodiment has a high refractive index due to its high aromatic ring density, and even after a heat treatment, coloration is suppressed and transparency is excellent. Therefore, the polymer of the present embodiment is also useful as a composition for optical member formation.

A composition of the present embodiment contains the polymer of the present embodiment, and thus the above-mentioned characteristics are also imparted to the composition. In particular, since the aromatic ring density is higher than that of a resin crosslinked with a divalent organic group, an oxygen atom, or the like, and the carbon-carbon atoms of the aromatic rings are directly linked by a direct bond, even if the molecular weight is relatively low, the polymer is considered to have superior performance in terms of performance such as heat resistance and etching resistance.

It is also possible to further improve the storage stability of the composition of the present embodiment by reducing the content of the impurity metal by purification.

The polymer of the present embodiment can be preferably applied as a film forming material for lithography due to the above-mentioned characteristics. That is, the composition of the present embodiment containing the polymer can be used for various applications such as a composition for film formation, a resist composition, a radiation-sensitive composition, a composition for underlayer film formation for lithography, and a composition for optical member formation.

Furthermore, according to a resist pattern formation method, a method for producing an underlayer film for lithography, and a circuit pattern formation method using the composition of the present embodiment, in addition to the heat resistance and etching resistance of the pattern, excellent resist pattern formability such as reactivity of the resist pattern to electron beam irradiation; embedding properties of the underlayer film; resolution, sensitivity, resist pattern shape after development; optical characteristics such as refractive index, extinction coefficient, and transparency; and reduction in the number of defects of the film can be exhibited.

Hereinafter, the above formula (0) will be described in detail.

In the present embodiment, the “substituted” means, unless otherwise defined, that at least one of hydrogen atoms bonded to carbon atoms constituting an aromatic ring and hydrogen atoms in a certain functional group is substituted with a substituent.

Unless otherwise defined, examples of the “substituent” include a halogen atom, a hydroxy group, a carboxyl group, a cyano group, a nitro group, a thiol group, or a heterocyclic group, an alkyl group having 1 to 30 carbon atoms, an aryl group having 6 to 20 carbon atoms, an alkoxyl group having 1 to 30 carbon atoms, an alkenyl group having 2 to 30 carbon atoms, an alkynyl group having 2 to 30 carbon atoms, an acyl group having 1 to 30 carbon atoms, and an amino group having 0 to 30 carbon atoms.

In the present embodiment, the “alkyl group” also includes, unless otherwise defined, linear aliphatic hydrocarbon groups, branched aliphatic hydrocarbon groups, and cyclic aliphatic hydrocarbon groups.

In the formula (0), R is a monovalent group and each independently, for example, a hydrogen atom, an alkyl group having 1 to 40 carbon atoms and optionally having a substituent, an aryl group having 6 to 40 carbon atoms and optionally having a substituent, an alkenyl group having 2 to 40 carbon atoms and optionally having a substituent, an alkynyl group having 2 to 40 carbon atoms, an alkoxy group having 1 to 40 carbon atoms and optionally having a substituent, an amino group having 0 to 40 carbon atoms, a halogen atom, a thiol group, a nitro group, a carboxyl group or a hydroxy group. Herein, the alkyl group may be either linear, branched or cyclic. Further, at least one R is a hydroxyl group, an alkoxy group having 1 to 40 carbon atoms and optionally having a substituent, or an amino group having 0 to 40 carbon atoms and optionally having a substituent (herein, the amino group having 0 carbon atoms means “—NH₂”).

In the formula (0), each R is independently:
preferably, i) a hydroxyl group, an alkoxy group having 1 to 40 carbon atoms and optionally having a substituent, an amino group having 0 to 40 carbon atoms and optionally having a substituent, an alkyl group having 1 to 40 carbon atoms and optionally having a substituent, or an aryl group having 6 to 40 carbon atoms and optionally having a substituent, and at least one R is a hydroxyl group, an alkoxy group having 1 to 40 carbon atoms and optionally having a substituent, or an amino group having 0 to 40 carbon atoms and optionally having a substituent;
still more preferably, ii) a hydroxyl group, an alkoxy group having 1 to 40 carbon atoms and optionally having a substituent, an amino group having 0 to 40 carbon atoms and optionally having a substituent, or an alkyl group having 1 to 6 carbon atoms, or an aryl group having 6 to 12 carbon atoms and optionally having a hydroxyl group, an alkoxy group having 1 to 40 carbon atoms, an amino group having 0 to 40 carbon atoms, or an alkyl group having 1 to 6 carbon atoms, and at least one R is a hydroxyl group, an alkoxy group having 1 to 40 carbon atoms and optionally having a substituent, or an amino group having 0 to 40 carbon atoms and optionally having a substituent; and
particularly preferably, iii) a hydroxyl group, an alkoxy group having 1 to 40 carbon atoms and optionally having a substituent, an amino group having 0 to 40 carbon atoms and optionally having a substituent, a methyl group, or a phenyl group and optionally having a hydroxyl group, a methyl group, or an amino group, and at least one R is a hydroxyl group or an amino group having 0 to 40 carbon atoms and optionally having a substituent.

Further, in the formula (0), m is an integer of 1 to 5, preferably 1 to 3, and more preferably 1 to 2.

Examples of the alkyl group having 1 to 40 carbon atoms include, but are not limited to, a methyl group, an ethyl group, a n-propyl group, an i-propyl group, a n-butyl group, an i-butyl group, a t-butyl group, a n-pentyl group, a n-hexyl group, a n-dodecyl group, and a barrel group.

Examples of the aryl group having 6 to 40 carbon atoms include, but are not limited to, a phenyl group, a naphthalene group, a biphenyl group, an anthracyl group, a pyrenyl group, and a perylene group.

Examples of the alkenyl group having 2 to 40 carbon atoms include, but are not limited to, an ethynyl group, a propenyl group, a butynyl group, and a pentynyl group.

Examples of the alkynyl group having 2 to 40 carbon atoms include, but are not limited to, an acetylene group, an ethynyl group.

Examples of the alkoxy group having 1 to 40 carbon atoms include, but are not limited to, a methoxy group, an ethoxy group, a propoxy group, a butoxy group, and a pentoxy group.

Examples of the amino group having 0 to 40 carbon atoms include, but are not limited to, an amino group, a methylamino group, a dimethylamino group, an ethylamino group, a diethylamino group, and a diphenylamino group.

The compound represented the by formula (0) is not limited, and examples thereof include the following compounds, among which, the compound having a hydroxyl group is preferably benzenediol optionally having an alkyl group, still more preferably resorcinol, catechol, and 3,3′-dimethyl-4,4′-dihydroxybiphenyl, and particularly preferably resorcinol.

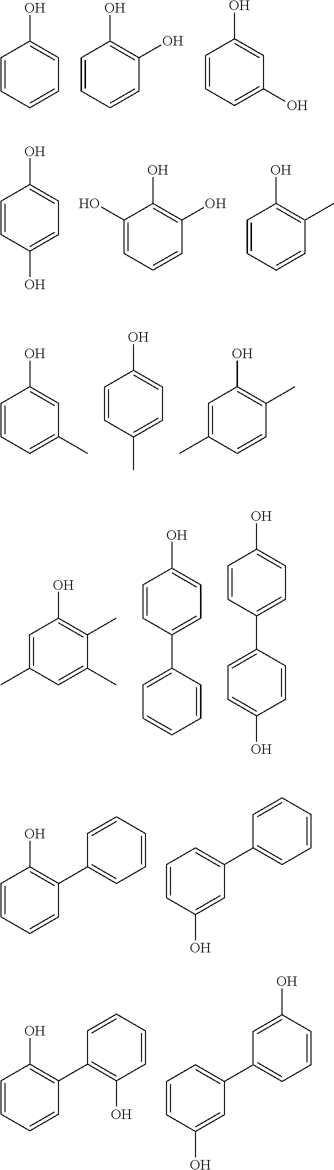

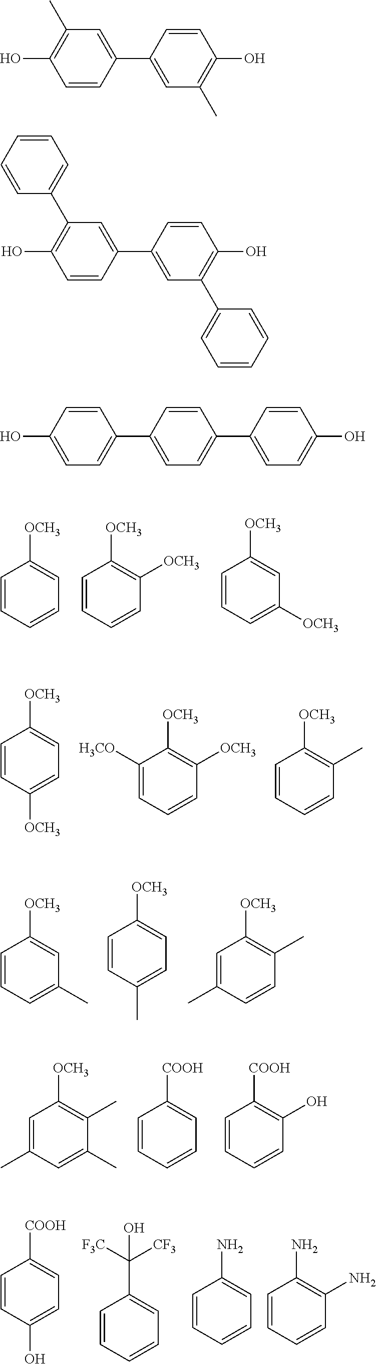

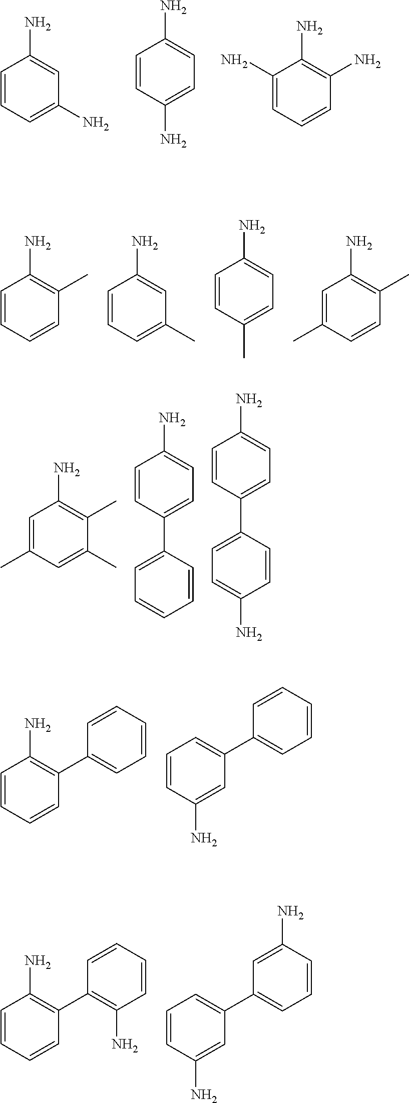

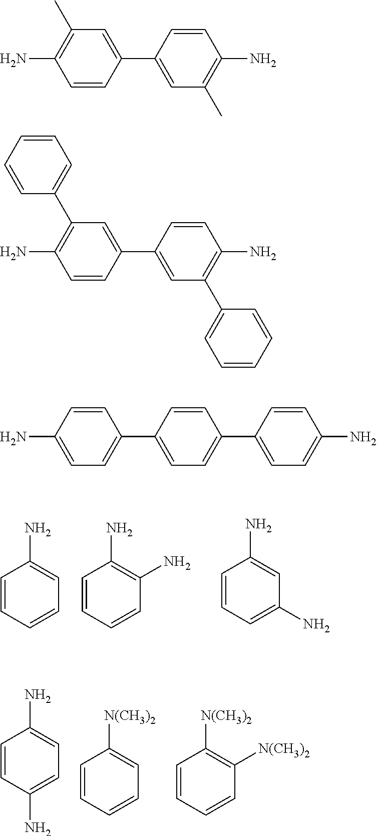

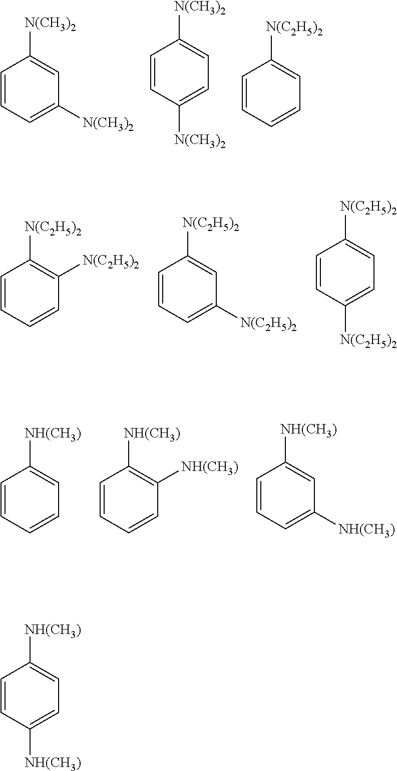

From the viewpoint of achieving solubility, heat resistance, and etching resistance at the same time, it is preferable to use a monomer represented by the formula (0) in which m is 2 or more and at least two R are a hydroxyl group, an alkoxy group having 1 to 40 carbon atoms and optionally having a substituent, or an amino group having 0 to 40 carbon atoms and optionally having a substituent, more preferably two or three R are a hydroxyl group, an alkoxy group having 1 to 40 carbon atoms and optionally having a substituent, or an amino group having 0 to 40 carbon atoms and optionally having a substituent, still more preferably two R are a hydroxyl group, an alkoxy group having 1 to 40 carbon atoms and optionally having a substituent, or an amino group having 0 to 40 carbon atoms and optionally having a substituent, and particularly preferably a hydroxyl group, an alkoxy group having 1 to 40 carbon atoms and optionally having a substituent, or an amino group having 0 to 4 carbon atoms and optionally having a substituent (for example, —NH₂, —NH(CH₃), —N(CH₃)₂, or —N(CH₂CH₃)₂)

From the viewpoint of coatability, preferred is a hydroxyl group or an alkoxy group having 1 to 40 carbon atoms and optionally having a substituent. From the viewpoint of etching resistance when an oxygen gas is used in combination, preferred is an amino group or an amino group having 1 to 40 carbon atoms and optionally having a substituent.

From the viewpoint of further improving heat resistance and etching resistance, the polymer of the present embodiment preferably further contains a constituent unit derived from an other copolymerizable compound that is copolymerizable with the monomer represented by the formula (0). The molar ratio (x:y) of the constituent unit (x) derived from the monomer represented by the formula (0) to the constituent unit derived from an other copolymerizable compound (y) is more preferably 19:81 to 99:1, still more preferably 49:51 to 99:1, and particularly preferably 79:21 to 91:19. The constitutional unit derived from the monomer represented by the formula (0) and the other copolymerizable compound are preferably directly bonded to each other through aromatic rings.

The polymer is preferably a polymer in which the other copolymerizable compound is selected from the group consisting of monomers represented by the formulas (1A) to (1D), and a heteroatom-containing aromatic monomer:

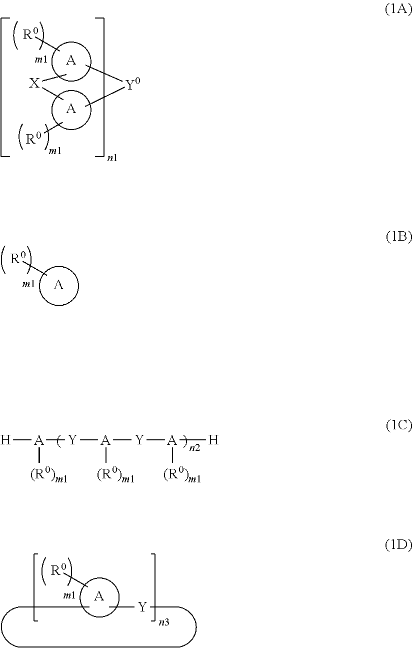

### (Formula (1A))

In the formula (1A), each X independently represents an oxygen atom, a sulfur atom, a single bond or not a crosslink, Y⁰ is a 2n-valent group having 1 to 60 carbon atoms or a single bond, wherein when X is not a crosslink, Y⁰ is the 2n-valent group, each A is independently benzene, biphenyl, terphenyl, diphenylmethylene, or a fused ring, each R⁰ is independently a hydrogen atom, an alkyl group having 1 to 40 carbon atoms and optionally having a substituent, an aryl group having 6 to 40 carbon atoms and optionally having a substituent, an alkenyl group having 2 to 40 carbon atoms and optionally having a substituent, an alkynyl group having 2 to 40 carbon atoms, an alkoxy group having 1 to 40 carbon atoms and optionally having a substituent, a halogen atom, a thiol group, an amino group, a nitro group, a carboxyl group, or a hydroxyl group, wherein at least one R⁰ is a hydroxyl group, an alkoxy group having 1 to 40 carbon atoms and optionally having a substituent, or an amino group having 0 to 40 carbon atoms and optionally having a substituent, each m1 is independently an integer of 1 or more, and n1 is an integer of 1 to 4. The upper limit value of m1 is not particularly limited and varies depending on the number of sites to which R⁰ can be bonded in the ring structure represented by A. Therefore, the range of m1 is not particularly limited, but for example, each m1 may independently be an integer of 1 to 9.

In the formula (1A), each A independently represents benzene, biphenyl, terphenyl, diphenylmethylene, or a fused ring. Examples of the fused product include naphthalene, anthracene, naphthacene, pentacene, benzopyrene, chrysene, pyrene, triphenylene, coronylene, coronene, ovalene, and fluorene, and from the viewpoint of having both heat resistance and solubility, A is preferably naphthalene, anthracene, pyrene, or fluorene. From the viewpoint of higher solubility, benzene is preferred.

X represents an oxygen atom, a sulfur atom, a single bond or not a crosslink. X is preferably an oxygen atom from the viewpoint of heat resistance. Further, from the viewpoint of solubility and etching resistance, X is preferably not a crosslink.

Y⁰ is a 2n1-valent group having 1 to 60 carbon atoms, or a single bond, wherein when X is not a crosslink, Y⁰ is the 2n1-valent group. The 2n-valent group having 1 to 60 carbon atoms refers to, for example, a 2n-valent hydrocarbon group, and the hydrocarbon group may have various functional groups described later as substituents. Further, the 2n-valent hydrocarbon group refers to an alkylene group having 1 to 60 carbon atoms when n is 1, an alkanetetrayl group having 1 to 60 carbon atoms when n is 2, an alkanehexayl group having 2 to 60 carbon atoms when n is 3, and an alkaneoctayl group having 3 to 60 carbon atoms when n is 4. Examples of the 2n-valent hydrocarbon group include a group in which a 2n+1 valent hydrocarbon group is bonded to a linear hydrocarbon group, a branched hydrocarbon group, or an alicyclic hydrocarbon group. Herein, the alicyclic hydrocarbon group also includes a bridged alicyclic hydrocarbon group.

Examples of the 2n+1-valent hydrocarbon group include, but are not limited to, a 3-valent methine group and an ethyne group.

Further, the 2n-valent hydrocarbon group may have a double bond, a triple bond, a heteroatom, and/or an aryl group having 6 to 59 carbon atoms. Y⁰ may include a group derived from a compound having a fluorene skeleton such as fluorene or benzofluorene.

In the present embodiment, the 2n-valent group may contain a halogen group, a nitro group, an amino group, a hydroxy group, an alkoxy group, a thiol group, or an aryl group having 6 to 40 carbon atoms. Furthermore, the 2n-valent group may contain an ether bond, a ketone bond, an ester bond, or a double bond.

In the present embodiment, from the viewpoint of heat resistance, the 2n-valent group preferably includes a branched hydrocarbon group or an alicyclic hydrocarbon group rather than a linear hydrocarbon group, and more preferably includes an alicyclic hydrocarbon group. Further, in the present embodiment, it is particularly preferable that the 2n-valent group has an aryl group having 6 to 60 carbon atoms.

Examples of the linear hydrocarbon group and the branched hydrocarbon group which may be contained in the 2n-valent group as a substituent include, but are not particularly limited to, an unsubstituted methyl group, an ethyl group, a n-propyl group, an i-propyl group, a n-butyl group, an i-butyl group, a t-butyl group, a n-pentyl group, a n-hexyl group, a n-dodecyl group, and a barrel group.

Examples of an alicyclic hydrocarbon group and an aromatic group having 6 to 60 carbon atoms which may be contained in the 2n-valent group as a substituent include, but are not particularly limited to, an unsubstituted phenyl group, a naphthalene group, a biphenyl group, an anthracyl group, a pyrenyl group, a cyclohexyl group, a cyclododecyl group, a dicyclopentyl group, a tricyclodecyl group, an adamantyl group, a phenylene group, a naphthalenediyl group, a biphenyldiyl group, an anthracenediyl group, a pyrendiyl group, a cyclohexanediyl group, a cyclododecanediyl group, a dicyclopentanediyl group, a tricyclodecanediyl group, an adamantanediyl group, a benzenetriyl group, a naphthalenetriyl group, a biphenyltriyl group, an anthracenetriyl group, a pyrenetriyl group, a cyclohexanetriyl group, a cyclododecanetriyl group, a dicyclopentanetriyl group, a tricyclodecanetriyl group, an adamantanetriyl group, a benzenetetrayl group, a naphthalenetetrayl group, a biphenyltetrayl group, an anthracenetetrayl group, a pyrenetetrayl group, a cyclohexanetetrayl group, a cyclododecanetetrayl group, a dicyclopentanetetrayl group, a tricyclodecantetrayl group, and an adamantanetetrayl group.

In the formula (1A), R⁰ is a monovalent group and each independently an alkyl group having 1 to 40 carbon atoms and optionally having a substituent, an aryl group having 6 to 40 carbon atoms and optionally having a substituent, an alkenyl group having 2 to 40 carbon atoms and optionally having a substituent, an alkynyl group having 2 to 40 carbon atoms, an alkoxy group having 1 to 40 carbon atoms and optionally having a substituent, an amino group having 0 to 40 carbon atoms, a halogen atom, a thiol group, a nitro group, a carboxyl group or a hydroxy group. Herein, the alkyl group may be either linear, branched or cyclic. Herein, at least one R⁰ is a hydroxyl group, an alkoxy group having 1 to 40 carbon atoms and optionally having a substituent, or an amino group having 0 to 40 carbon atoms and optionally having a substituent.

Examples of the alkyl group having 1 to 40 carbon atoms include, but are not limited to, a methyl group, an ethyl group, a n-propyl group, an i-propyl group, a n-butyl group, an i-butyl group, a t-butyl group, a n-pentyl group, a n-hexyl group, a n-dodecyl group, a barrel group, a benzyl group, and a phenethyl group. Preferred are a methyl group, an ethyl group, a benzyl group, and a phenethyl group, and more preferred are a methyl group and a benzyl group.

Examples of the aryl group having 6 to 40 carbon atoms include, but are not limited to, a phenyl group, a naphthalene group, a biphenyl group, an anthracyl group, a pyrenyl group, and a perylene group. Preferred is a phenyl group.

Examples of the alkenyl group having 2 to 40 carbon atoms include, but are not limited to, an ethynyl group, a propenyl group, a butynyl group, and a pentynyl group. Preferred is an ethynyl group.

Examples of the alkynyl group having 2 to 40 carbon atoms include, but are not limited to, an acetylene group, an ethynyl group. Preferred is an ethynyl group.

Examples of the alkoxy group having 1 to 40 carbon atoms include, but are not limited to, a methoxy group, an ethoxy group, a propoxy group, a butoxy group, and a pentoxy group. Preferred are a methoxy group and an ethoxy group.

Examples of the amino group having 0 to 40 carbon atoms include, but are not limited to, an amino group, a methylamino group, a dimethylamino group, an ethylamino group, a diethylamino group, and a diphenylamino group. Preferred are an amino group, a methylamino group, and a dimethylamino group.

Each m1 is independently an integer of 1 to 9. From the viewpoint of solubility, m1 is preferably 1 to 6, more preferably 1 to 4, and from the viewpoint of availability of raw materials, still more preferably 1 to 2.

n1 is an integer of 1 to 4. From the viewpoint of solubility, n1 is preferably 1 to 2 and from the viewpoint of availability of raw materials, still more preferably 1.

### (Formula (1B))

In the formula (1B), A, R⁰, and m1 are as defined in the formula (1A). Further, in the formula (1B), at least one R⁰ is a hydroxyl group, an alkoxy group having 1 to 40 carbon atoms and optionally having a substituent, or an amino group having 0 to 40 carbon atoms and optionally having a substituent. In the formula (1B), A is preferably a fused ring.

### (Formula (1C))

In the formula (1C), Y is a 2n valent group having 1 to 60 carbon atoms, n2 is an integer of 1 to 500, and A, R⁰, and m1 are as defined in the formula (1A). Further, in the formula (1C), at least one R⁰ is a hydroxyl group, an alkoxy group having 1 to 40 carbon atoms and optionally having a substituent, or an amino group having 0 to 40 carbon atoms and optionally having a substituent.

In the formula (1C), Y is a divalent group having 1 to 60 carbon atoms or a single bond. The divalent group having 1 to 60 carbon atoms refers to, for example, a divalent hydrocarbon group, and the hydrocarbon group may have various functional groups described later as substituents. Further, the divalent hydrocarbon group refers to an alkylene group having 1 to 60 carbon atoms. Examples of the divalent hydrocarbon group include a group in which a divalent hydrocarbon group is bonded to a linear hydrocarbon group, a branched hydrocarbon group, or an alicyclic hydrocarbon group. Herein, the alicyclic hydrocarbon group also includes a bridged alicyclic hydrocarbon group.

Examples of the divalent hydrocarbon group include, but are not limited to, a 3-valent methine group and an ethyne group.

Further, the divalent hydrocarbon group may have a double bond, a triple bond, a heteroatom, and/or an aryl group having 6 to 59 carbon atoms. Y may include a group derived from a compound having a fluorene skeleton such as fluorene or benzofluorene.

In the present embodiment, the divalent group may contain a halogen group, a nitro group, an amino group, a hydroxy group, an alkoxy group, a thiol group, or an aryl group having 6 to 40 carbon atoms. Furthermore, the divalent group may contain an ether bond, a ketone bond, an ester bond, or a double bond.

In the present embodiment, from the viewpoint of heat resistance, the divalent group preferably includes a branched hydrocarbon group or an alicyclic hydrocarbon group rather than a linear hydrocarbon group, and more preferably includes an alicyclic hydrocarbon group. Further, in the present embodiment, it is particularly preferable that the divalent group has an aryl group having 6 to 60 carbon atoms.

Examples of the linear hydrocarbon group and the branched hydrocarbon group which may be contained in the divalent group as a substituent include, but are not particularly limited to, an unsubstituted methyl group, an ethyl group, a n-propyl group, an i-propyl group, a n-butyl group, an i-butyl group, a t-butyl group, a n-pentyl group, a n-hexyl group, a n-dodecyl group, and a barrel group.

Examples of an alicyclic hydrocarbon group and an aromatic group having 6 to 60 carbon atoms which may be contained in the divalent group as a substituent include, but are not particularly limited to, an unsubstituted phenyl group, a naphthalene group, a biphenyl group, an anthracyl group, a pyrenyl group, a cyclohexyl group, a cyclododecyl group, a dicyclopentyl group, a tricyclodecyl group, an adamantyl group, a phenylene group, a naphthalenediyl group, a biphenyldiyl group, an anthracenediyl group, a pyrendiyl group, a cyclohexanediyl group, a cyclododecanediyl group, a dicyclopentanediyl group, a tricyclodecanediyl group, an adamantanediyl group, a benzenetriyl group, a naphthalenetriyl group, a biphenyltriyl group, an anthracenetriyl group, a pyrenetriyl group, a cyclohexanetriyl group, a cyclododecanetriyl group, a dicyclopentanetriyl group, a tricyclodecanetriyl group, an adamantanetriyl group, a benzenetetrayl group, a naphthalenetetrayl group, a biphenyltetrayl group, an anthracenetetrayl group, a pyrenetetrayl group, a cyclohexanetetrayl group, a cyclododecanetetrayl group, a dicyclopentanetetrayl group, a tricyclodecantetrayl group, and an adamantanetetrayl group.

### (Formula (1D))

In the formula (1D), n3 is an integer of 1 to 10, Y is as defined in the formula (1C), and A, R⁰, and m1 are as defined in the formula (1A). Further, in the formula (1D), at least one R⁰ is a hydroxyl group, an alkoxy group having 1 to 40 carbon atoms and optionally having a substituent, or an amino group having 0 to 40 carbon atoms and optionally having a substituent.

From the viewpoint of achieving solubility, heat resistance, and etching resistance at the same time, a polymer in which the compound represented by the formula (1A) is a compound represented by the following formula (1A-1) is preferred.

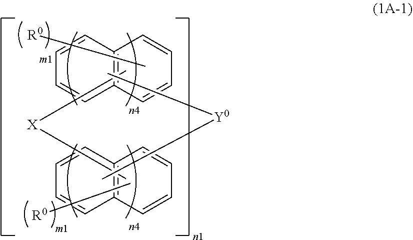

In the formula (1A-1), each n4 is independently an integer of 0 to 3, and X, Y⁰, R⁰, m1, and n1 are as defined in the formula (1A).

From the viewpoint of further improving heat resistance and etching resistance, a polymer in which the compound represented by the formula (1A-1) is a compound represented by the following formula (1A-2a) is more preferred.

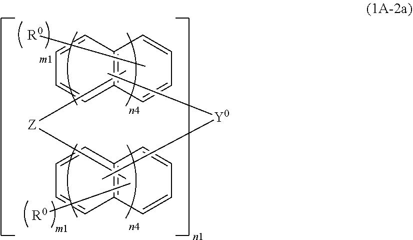

In the formula (1A-2a), each Z is independently an oxygen or a sulfur atom, and Y⁰, R⁰, m1, n1, and n4 are as defined in the formula (1A-1).

From the viewpoint of further improving heat resistance and etching resistance, a polymer in which the compound represented by the formula (1A-2a) is a compound represented by the following formula (1A-2a-1) is more preferred.

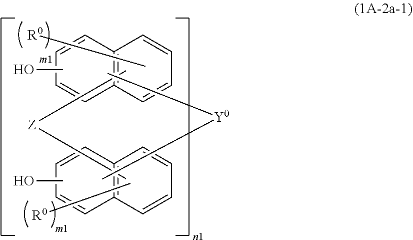

In the formula (1A-2a-1), Z, Y⁰, R⁰, m1, and n1 are as defined in the formula (1A-2a).

From the viewpoint of further improving solubility, a polymer in which the compound represented by the formula (1A-1) is a compound represented by the following formula (1A-2b) is more preferred.

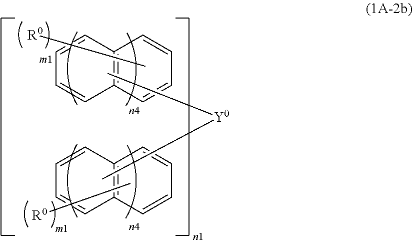

In the formula (1A-2b), Y⁰, R⁰, m1, n1, and n4 are as defined in the formula (1A-1).

A polymer in which the compound represented by the formula (1A-2b) is a compound represented by the following formula (1A-2b-1) is more preferred.

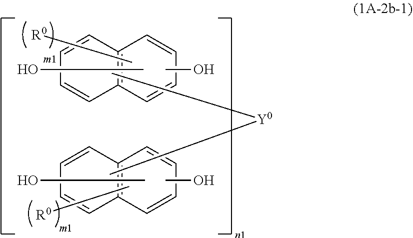

In the formula (1A-2b-1), Y⁰, R⁰, m1, and n1 are as defined in the formula (1A-2b).

From the viewpoint of further improving solubility, heat resistance and etching resistance, a polymer in which the compound represented by the formula (1A-1) is at least one compound represented by the following formula (1A-2c) is more preferred.

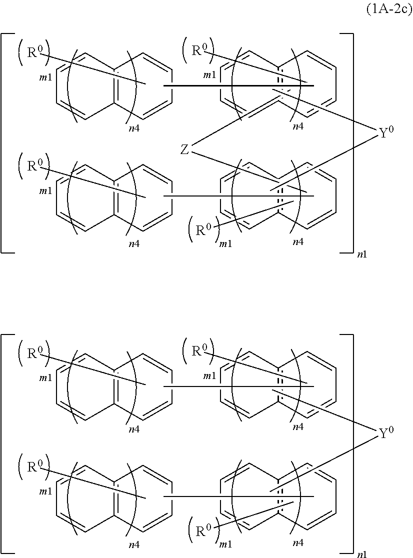

In the formula (1A-2c), each Z is independently an oxygen or a sulfur atom, and Y⁰, R⁰, m1, n1, and n4 are as defined in the formula (1A-1)

A polymer in which the compound represented by the formula (1A-2c) is at least one compound represented by the following formula (1A-2c-1) is more preferred.

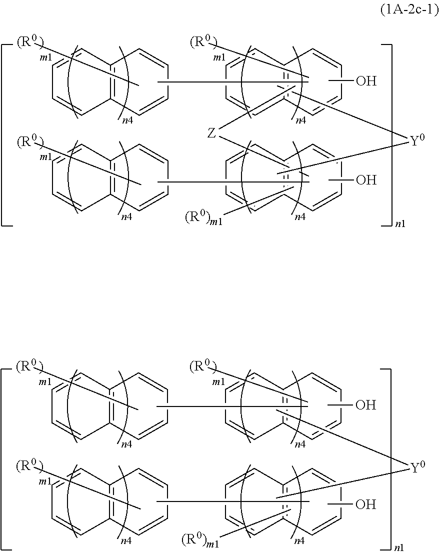

In the formula (1A-2c-1), Z, Y⁰, R⁰, m1, n1, and n4 are as defined in the formula (1A-2c-1).

A polymer in which the compound represented by the formula (1A-2c-1) is at least one compound represented by the following formula (1A-2c-1a) is still more preferred.

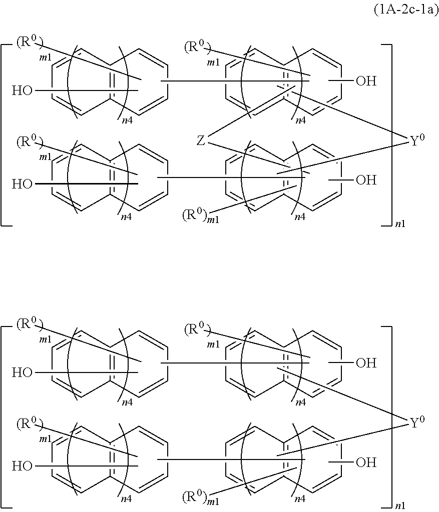

In the formula (1A-2c-1a), Z, Y⁰, R⁰, m1, n1, and n4 are as defined in the formula (1A-2c-1).

A polymer in which the compound represented by the formula (1A-2a-1) is at least one compound represented by the following formula (1A-3a) is still more preferred.

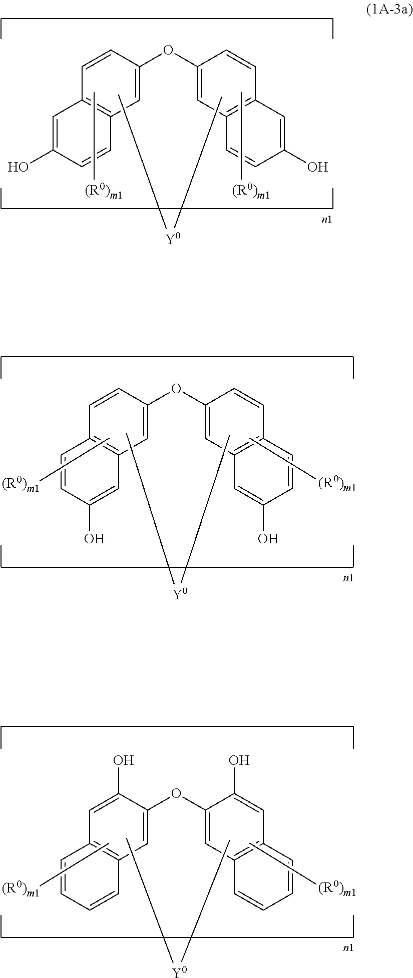

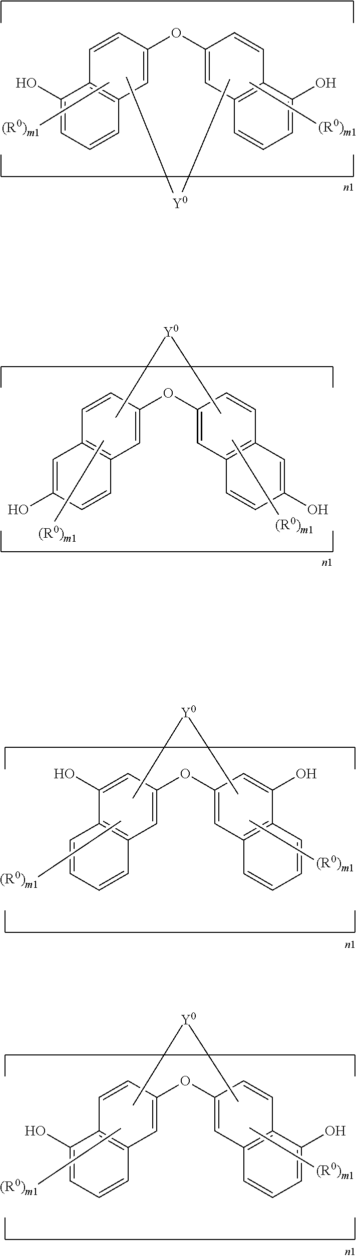

In the formula (1A-3a), Y⁰, R⁰, m1, and n1 are as defined in the formula (1A-2a).

A polymer in which the compound represented by the formula (1A-2b-1) is at least one compound represented by the following formula (1A-3b) is still more preferred.

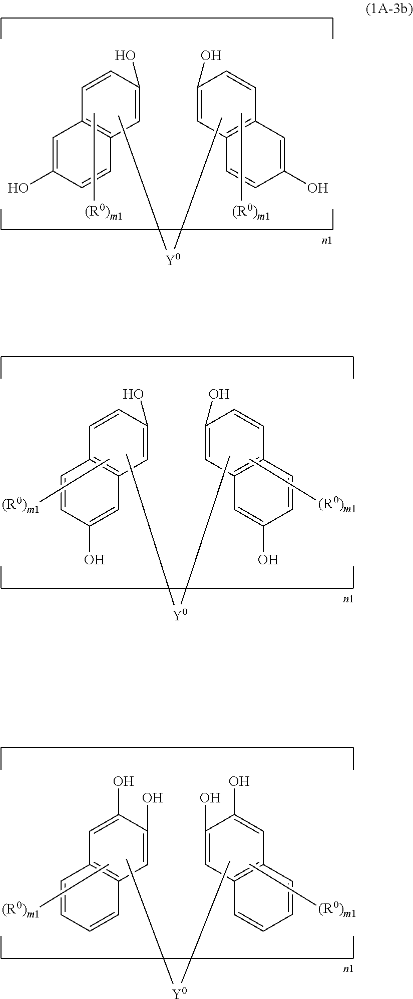

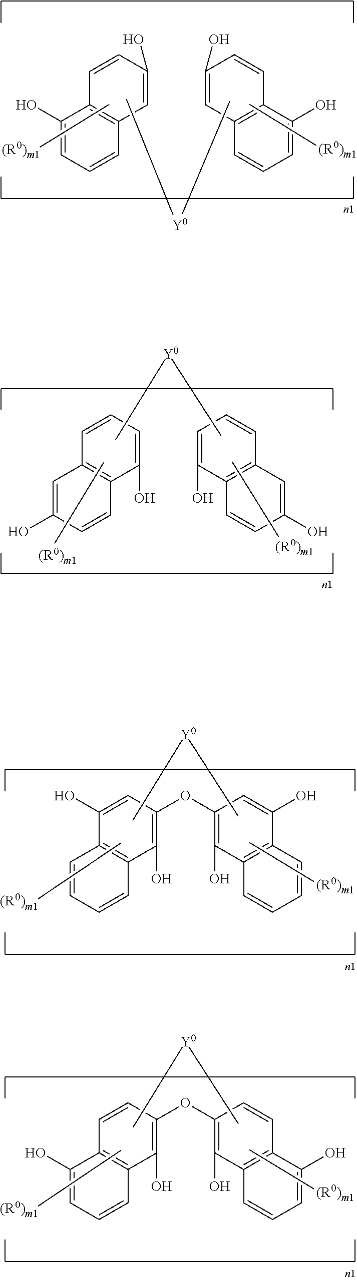

In the formula (1A-3b), Y⁰, R⁰, m1, and n1 are as defined in the formula (1A-2a-1).

A polymer in which the compound represented by the formula (1A-2c-1) is at least one compound represented by the following formula (1A-3c) is still more preferred.

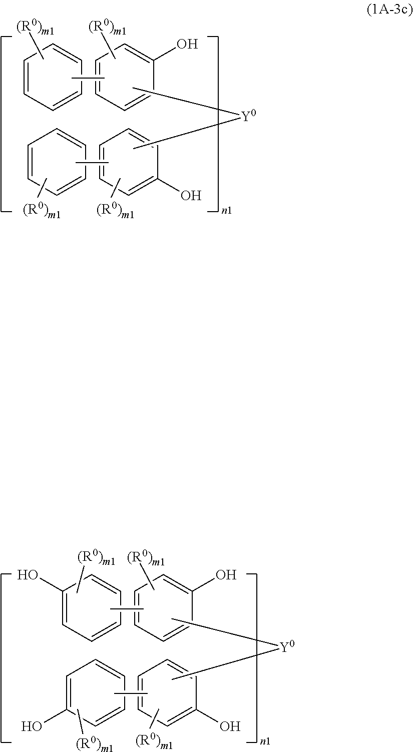

In the formula (1A-3c), Y⁰, R⁰, m1, and n1 are as defined in the formula (1A-2a-1).

From the viewpoint of further improving solubility, heat resistance and etching resistance, in the above formulas, Y⁰ is preferably a group represented by “R^{A}-R^{B}”. Herein, R^{A} is preferably a methine group, and R^{B} is preferably an aryl group having 6 to 40 carbon atoms and optionally having a substituent.

From the viewpoint of the surface flattening properties, in the above formulas, n1 is preferably 1 to 2, and more preferably 1.

The compound represented by the formula (1A) is not particularly limited, and examples thereof include the following compounds.

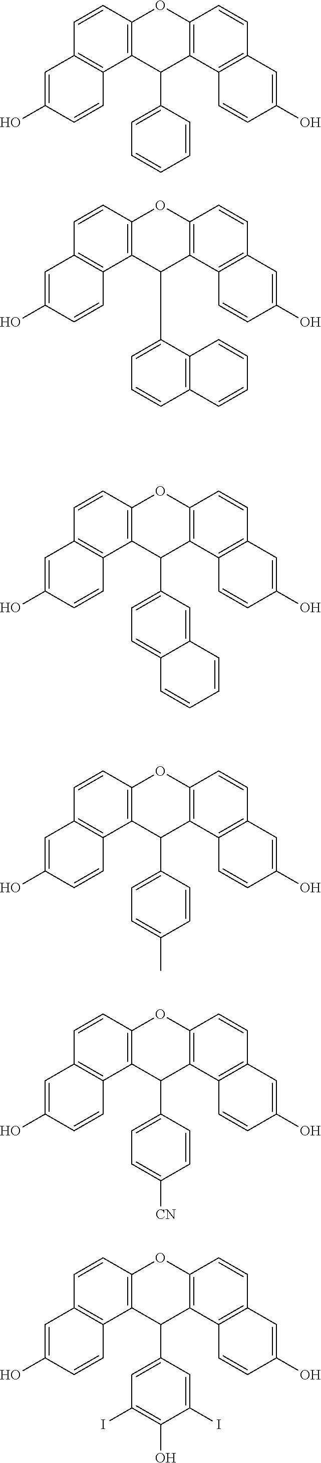

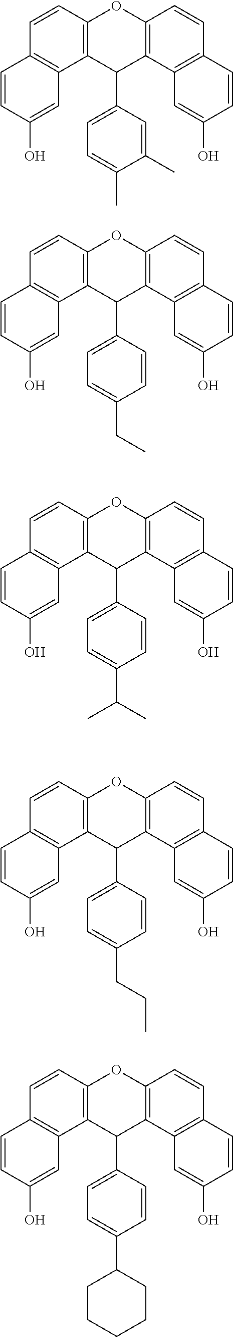

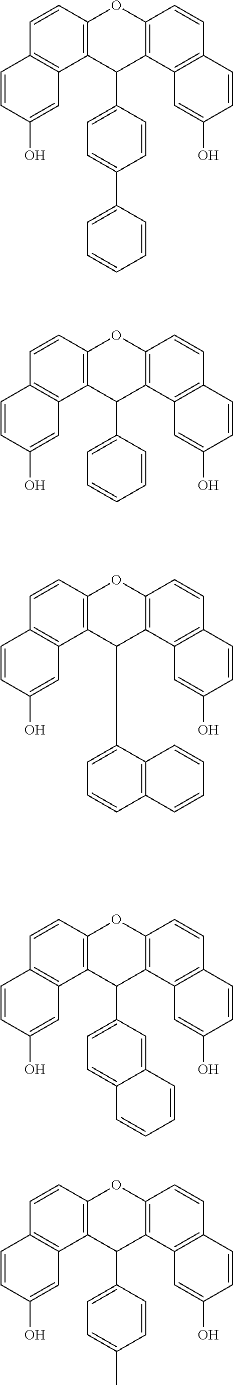 [SMILES: Oc1ccc2ccc3c(c2c1)C(c1ccc(-c2ccccc2)cc1)c1c(ccc2ccc(O)cc12)O3 ; Oc1ccc2ccc3c(c2c1)C(c1ccccc1)c1c(ccc2ccc(O)cc12)O3 ; Oc1ccc2ccc3c(c2c1)C(c1cccc2ccccc12)c1c(ccc2ccc(O)cc12)O3 ; Oc1ccc2ccc3c(c2c1)C(c1ccc2ccccc2c1)c1c(ccc2ccc(O)cc12)O3 ; Cc1ccc(C2c3c(ccc4ccc(O)cc34)Oc3ccc4ccc(O)cc4c32)cc1]

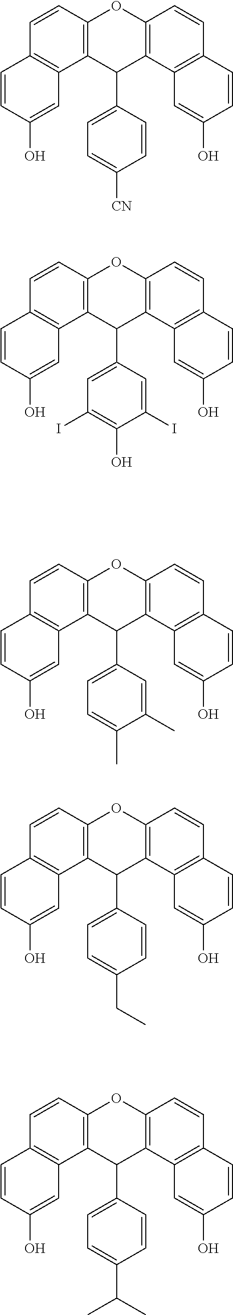

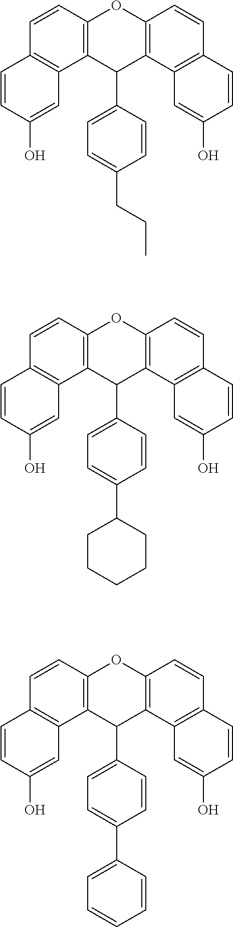 [SMILES: CCCc1ccc(C2c3c(ccc4ccc(O)cc34)Oc3ccc4ccc(O)cc4c32)cc1 ; Oc1ccc2ccc3c(c2c1)C(c1ccc(C2CCCCC2)cc1)c1c(ccc2ccc(O)cc12)O3 ; Oc1ccc2ccc3c(c2c1)C(c1ccc(-c2ccccc2)cc1)c1c(ccc2ccc(O)cc12)O3]

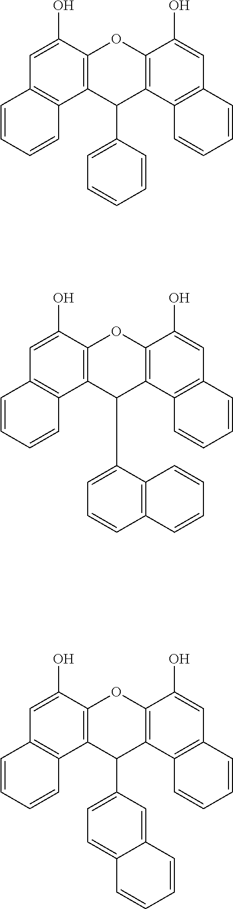 [SMILES: Oc1cc2ccccc2c2c1Oc1c(O)cc3ccccc3c1C2c1ccccc1 ; Oc1cc2ccccc2c2c1Oc1c(O)cc3ccccc3c1C2c1cccc2ccccc12 ; Oc1cc2ccccc2c2c1Oc1c(O)cc3ccccc3c1C2c1ccc2ccccc2c1]

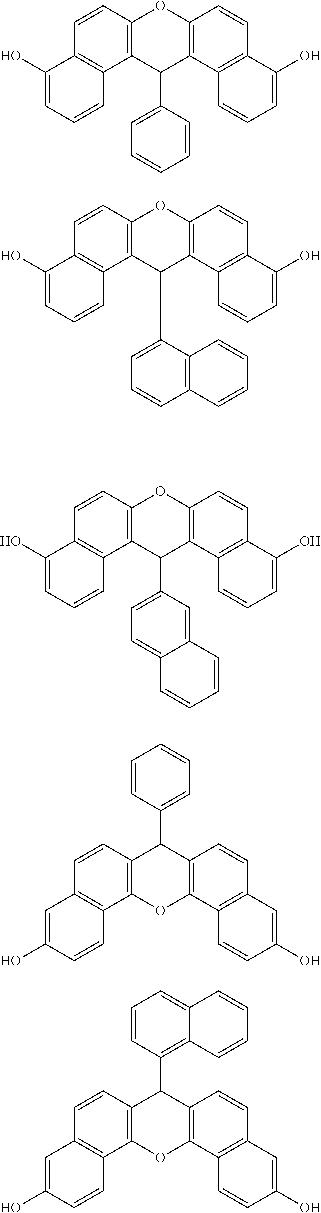

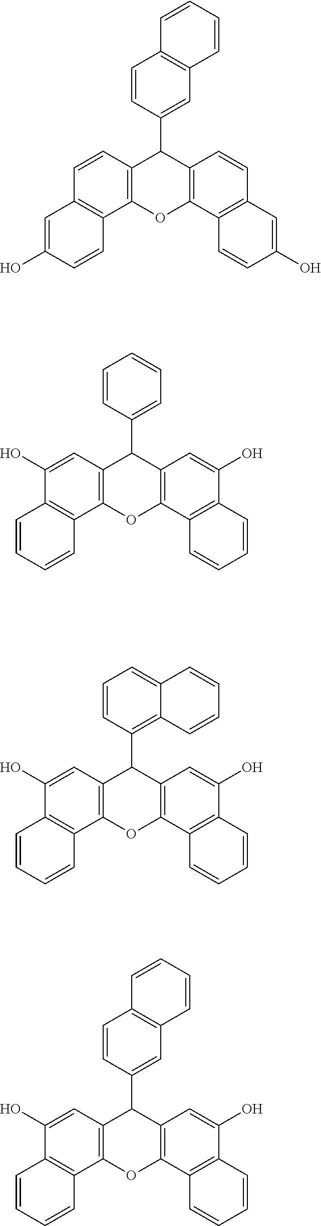 [SMILES: Oc1ccc2c3c(ccc2c1)C(c1ccc2ccccc2c1)c1ccc2cc(O)ccc2c1O3 ; Oc1cc2c(c3ccccc13)Oc1c(cc(O)c3ccccc13)C2c1ccccc1 ; Oc1cc2c(c3ccccc13)Oc1c(cc(O)c3ccccc13)C2c1cccc2ccccc12 ; Oc1cc2c(c3ccccc13)Oc1c(cc(O)c3ccccc13)C2c1ccc2ccccc2c1]

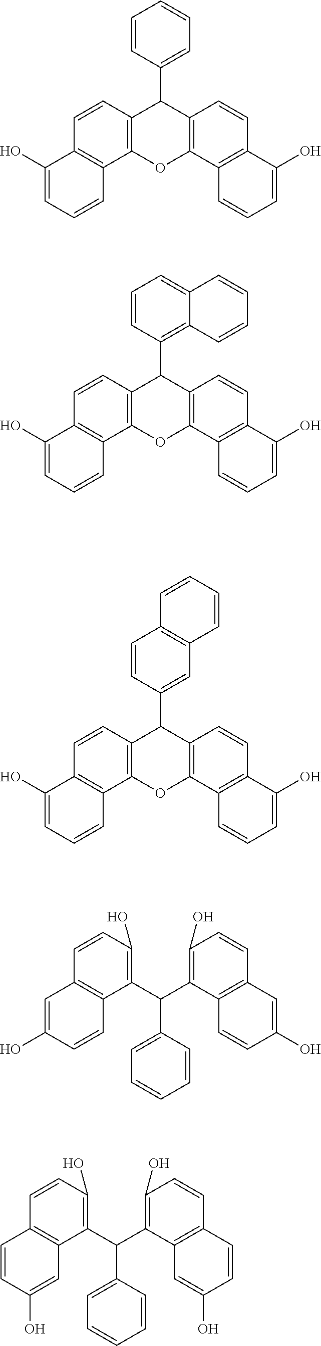 [SMILES: Oc1cccc2c3c(ccc12)C(c1ccccc1)c1ccc2c(O)cccc2c1O3 ; Oc1cccc2c3c(ccc12)C(c1cccc2ccccc12)c1ccc2c(O)cccc2c1O3 ; Oc1cccc2c3c(ccc12)C(c1ccc2ccccc2c1)c1ccc2c(O)cccc2c1O3 ; Oc1ccc2c(C(c3ccccc3)c3c(O)ccc4cc(O)ccc34)c(O)ccc2c1 ; Oc1ccc2ccc(O)c(C(c3ccccc3)c3c(O)ccc4ccc(O)cc34)c2c1]

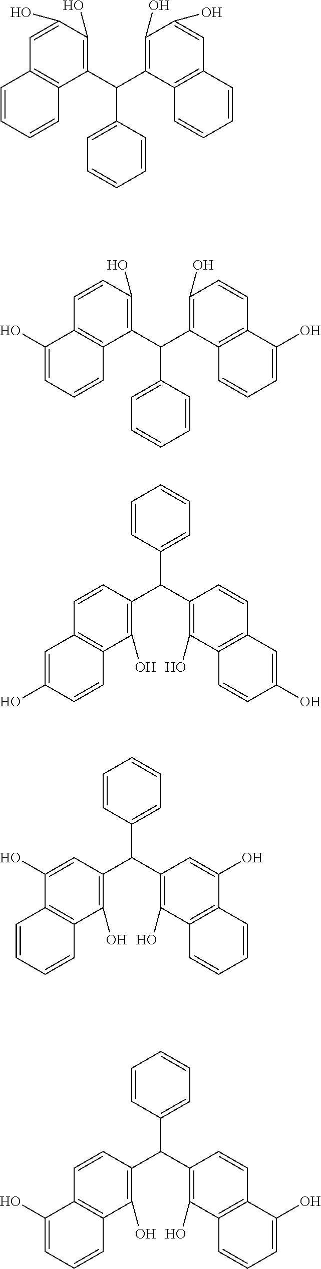

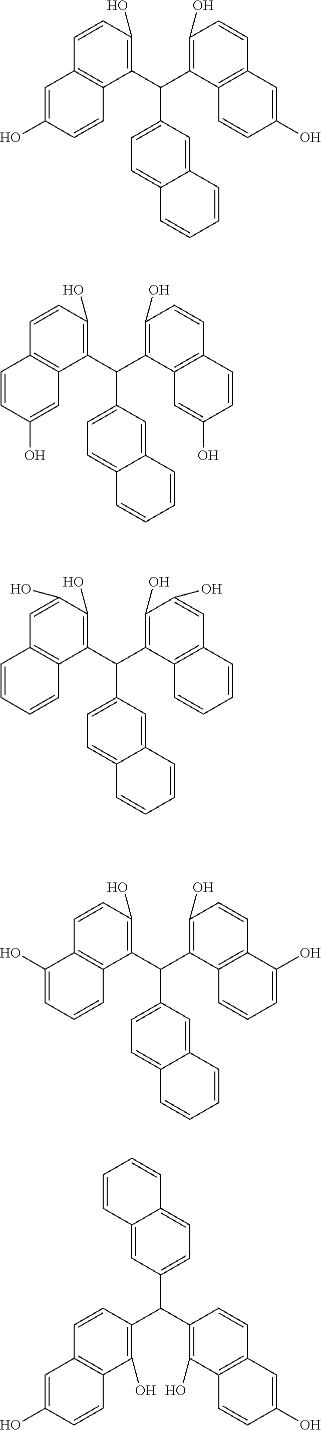 [SMILES: Oc1ccc2c(C(c3ccc4ccccc4c3)c3c(O)ccc4cc(O)ccc34)c(O)ccc2c1 ; Oc1ccc2ccc(O)c(C(c3ccc4ccccc4c3)c3c(O)ccc4ccc(O)cc34)c2c1 ; Oc1cc2ccccc2c(C(c2ccc3ccccc3c2)c2c(O)c(O)cc3ccccc23)c1O ; Oc1ccc2c(O)cccc2c1C(c1ccc2ccccc2c1)c1c(O)ccc2c(O)cccc12 ; Oc1ccc2c(O)c(C(c3ccc4ccccc4c3)c3ccc4cc(O)ccc4c3O)ccc2c1]

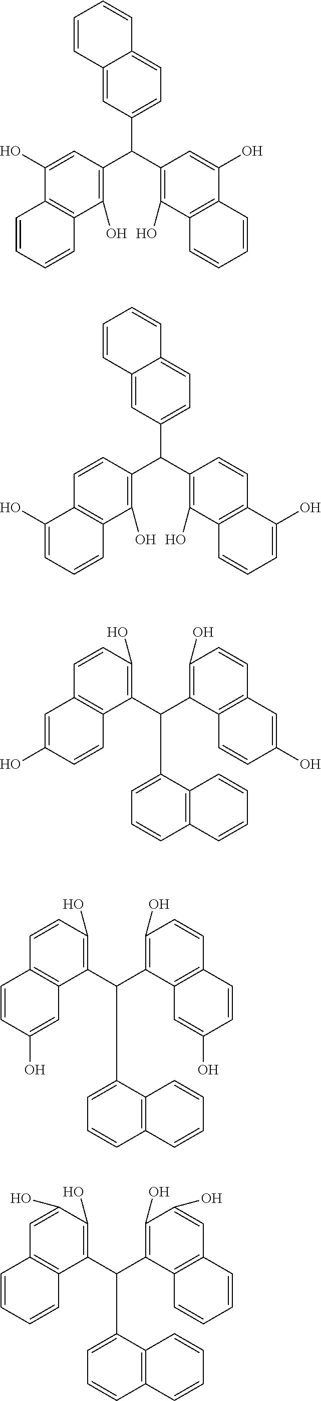 [SMILES: Oc1cc(C(c2ccc3ccccc3c2)c2cc(O)c3ccccc3c2O)c(O)c2ccccc12 ; Oc1cccc2c(O)c(C(c3ccc4ccccc4c3)c3ccc4c(O)cccc4c3O)ccc12 ; Oc1ccc2c(C(c3cccc4ccccc34)c3c(O)ccc4cc(O)ccc34)c(O)ccc2c1 ; Oc1ccc2ccc(O)c(C(c3cccc4ccccc34)c3c(O)ccc4ccc(O)cc34)c2c1 ; Oc1cc2ccccc2c(C(c2cccc3ccccc23)c2c(O)c(O)cc3ccccc23)c1O]

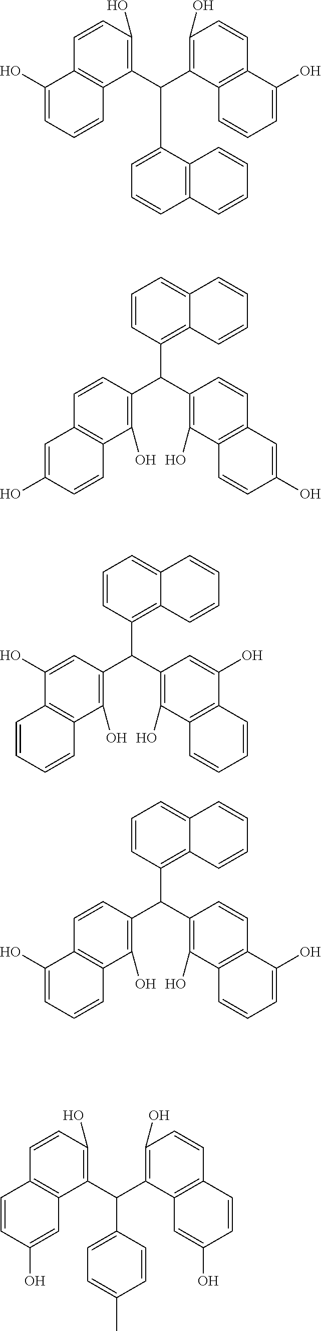

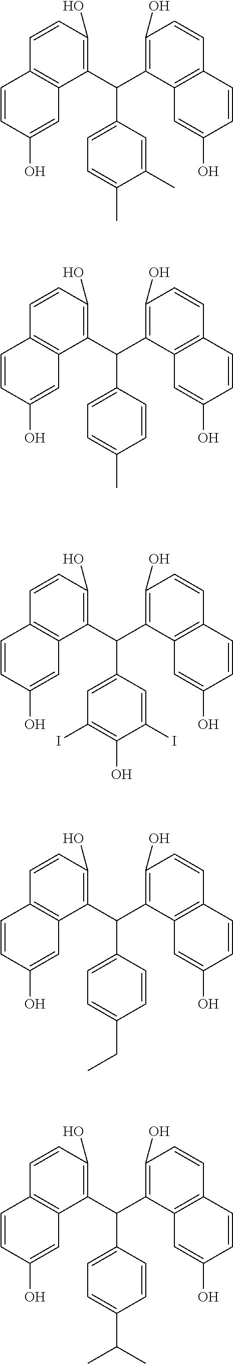 [SMILES: Cc1ccc(C(c2c(O)ccc3ccc(O)cc23)c2c(O)ccc3ccc(O)cc23)cc1C ; Cc1ccc(C(c2c(O)ccc3ccc(O)cc23)c2c(O)ccc3ccc(O)cc23)cc1 ; Oc1ccc2ccc(O)c(C(c3cc(I)c(O)c(I)c3)c3c(O)ccc4ccc(O)cc34)c2c1 ; CCc1ccc(C(c2c(O)ccc3ccc(O)cc23)c2c(O)ccc3ccc(O)cc23)cc1 ; CC(C)c1ccc(C(c2c(O)ccc3ccc(O)cc23)c2c(O)ccc3ccc(O)cc23)cc1]

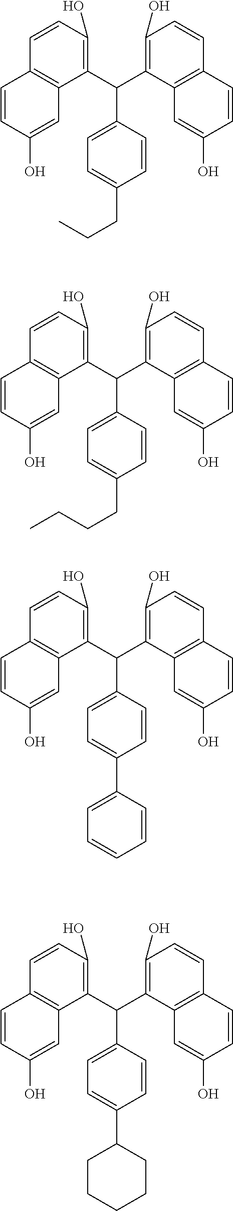 [SMILES: CCCc1ccc(C(c2c(O)ccc3ccc(O)cc23)c2c(O)ccc3ccc(O)cc23)cc1 ; CCCCc1ccc(C(c2c(O)ccc3ccc(O)cc23)c2c(O)ccc3ccc(O)cc23)cc1 ; Oc1ccc2ccc(O)c(C(c3ccc(-c4ccccc4)cc3)c3c(O)ccc4ccc(O)cc34)c2c1 ; Oc1ccc2ccc(O)c(C(c3ccc(C4CCCCC4)cc3)c3c(O)ccc4ccc(O)cc34)c2c1]

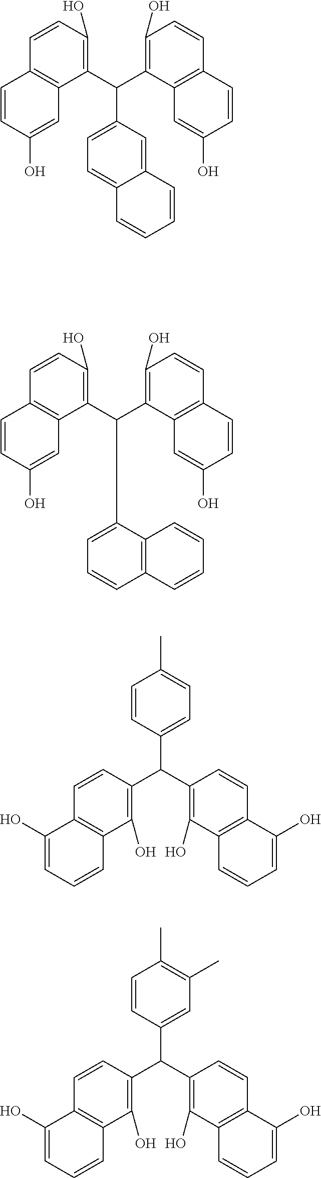 [SMILES: Oc1ccc2ccc(O)c(C(c3ccc4ccccc4c3)c3c(O)ccc4ccc(O)cc34)c2c1 ; Oc1ccc2ccc(O)c(C(c3cccc4ccccc34)c3c(O)ccc4ccc(O)cc34)c2c1 ; Cc1ccc(C(c2ccc3c(O)cccc3c2O)c2ccc3c(O)cccc3c2O)cc1 ; Cc1ccc(C(c2ccc3c(O)cccc3c2O)c2ccc3c(O)cccc3c2O)cc1C]

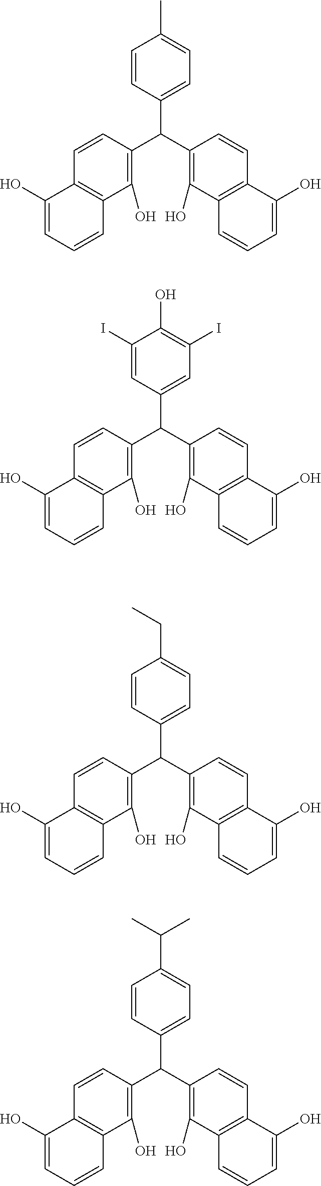 [SMILES: Cc1ccc(C(c2ccc3c(O)cccc3c2O)c2ccc3c(O)cccc3c2O)cc1 ; Oc1c(I)cc(C(c2ccc3c(O)cccc3c2O)c2ccc3c(O)cccc3c2O)cc1I ; CCc1ccc(C(c2ccc3c(O)cccc3c2O)c2ccc3c(O)cccc3c2O)cc1 ; CC(C)c1ccc(C(c2ccc3c(O)cccc3c2O)c2ccc3c(O)cccc3c2O)cc1]

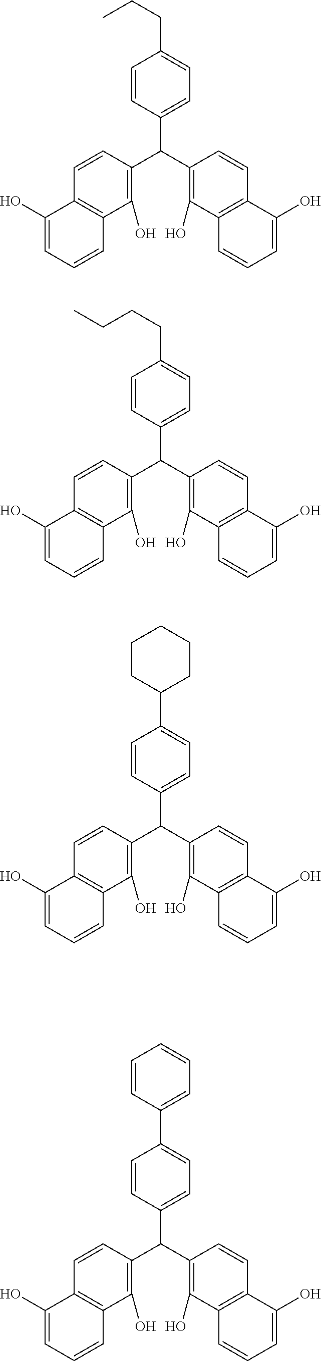

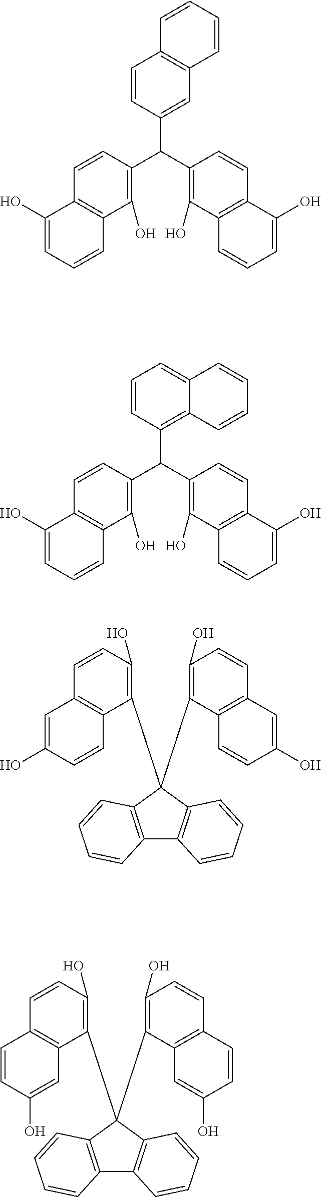 [SMILES: Oc1cccc2c(O)c(C(c3ccc4ccccc4c3)c3ccc4c(O)cccc4c3O)ccc12 ; Oc1cccc2c(O)c(C(c3ccc4c(O)cccc4c3O)c3cccc4ccccc34)ccc12 ; Oc1ccc2c(C3(c4c(O)ccc5cc(O)ccc45)c4ccccc4-c4ccccc43)c(O)ccc2c1 ; Oc1ccc2ccc(O)c(C3(c4c(O)ccc5ccc(O)cc45)c4ccccc4-c4ccccc43)c2c1]

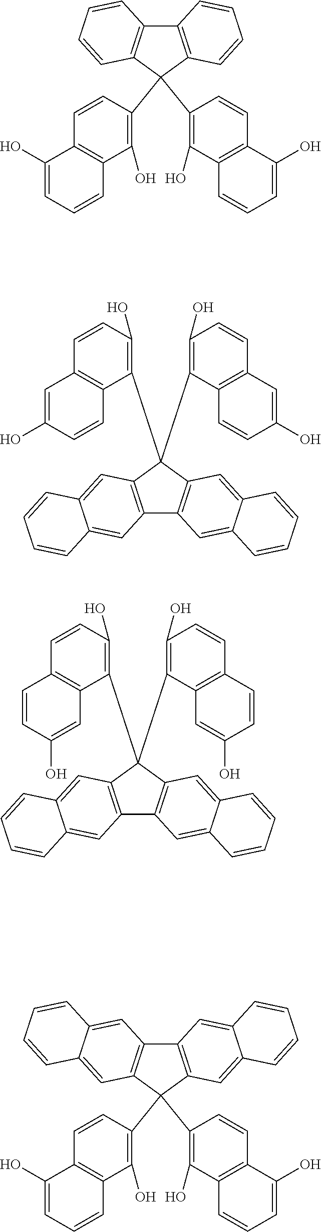 [SMILES: Oc1cccc2c(O)c(C3(c4ccc5c(O)cccc5c4O)c4ccccc4-c4ccccc43)ccc12 ; Oc1ccc2c(C3(c4c(O)ccc5cc(O)ccc45)c4cc5ccccc5cc4-c4cc5ccccc5cc43)c(O)ccc2c1 ; Oc1ccc2ccc(O)c(C3(c4c(O)ccc5ccc(O)cc45)c4cc5ccccc5cc4-c4cc5ccccc5cc43)c2c1 ; Oc1cccc2c(O)c(C3(c4ccc5c(O)cccc5c4O)c4cc5ccccc5cc4-c4cc5ccccc5cc43)ccc12]

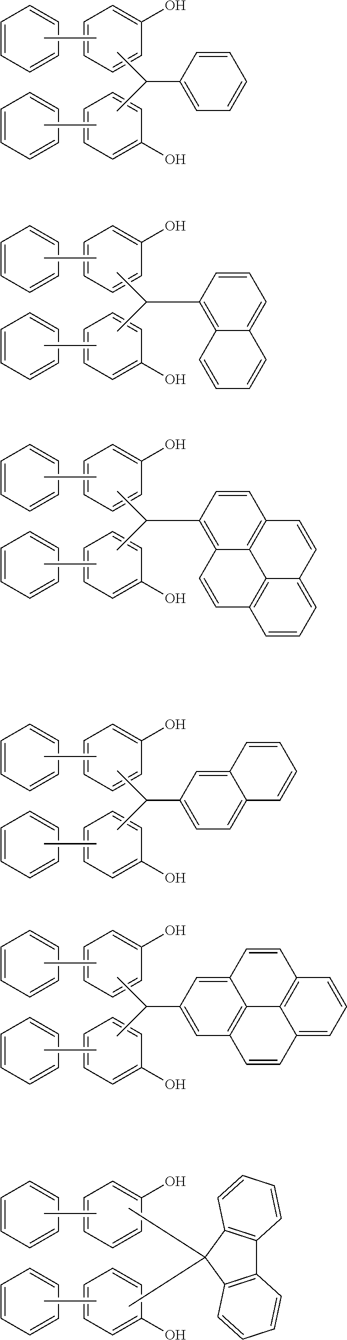

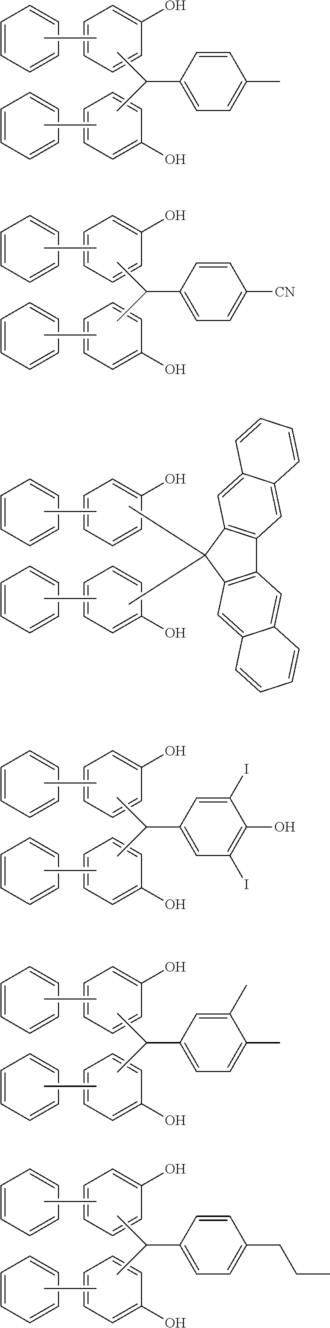

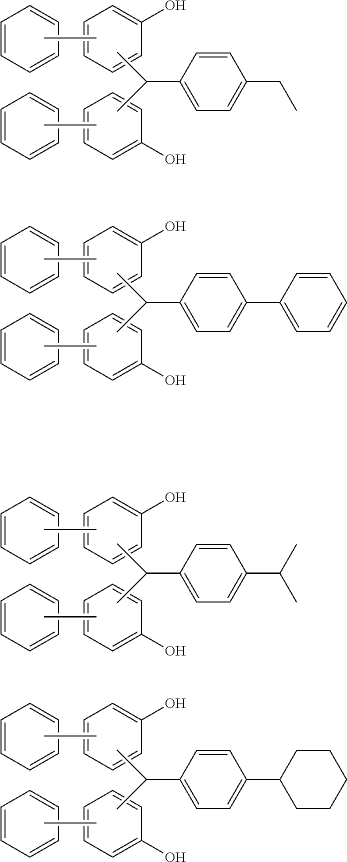

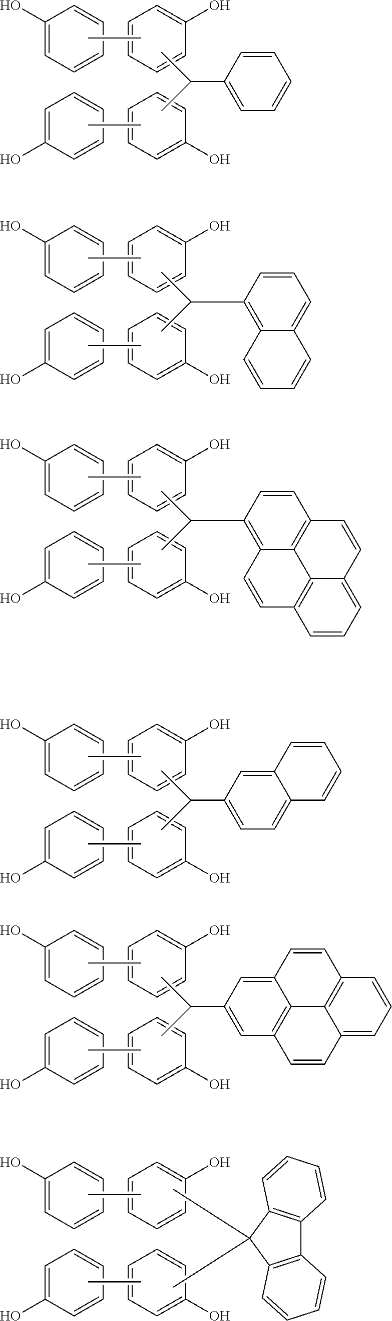

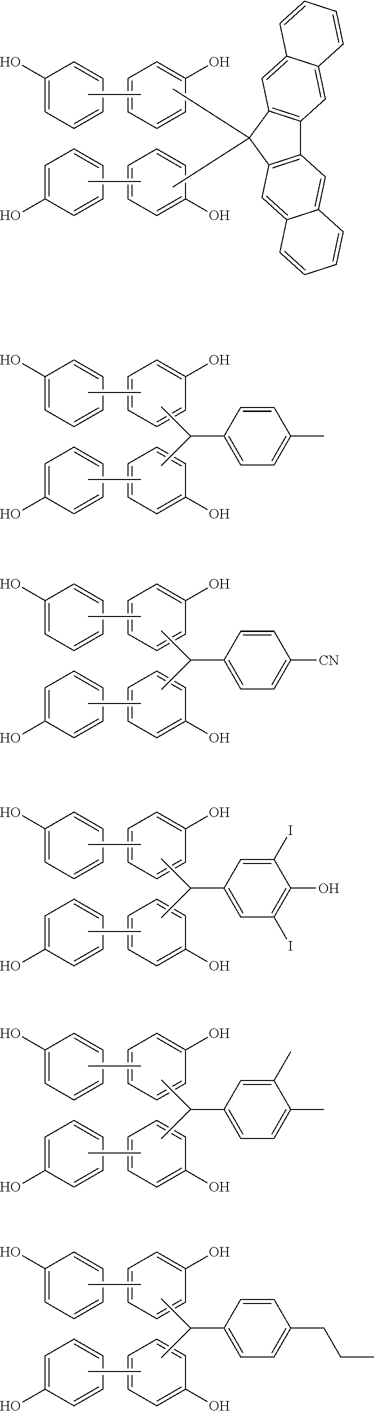

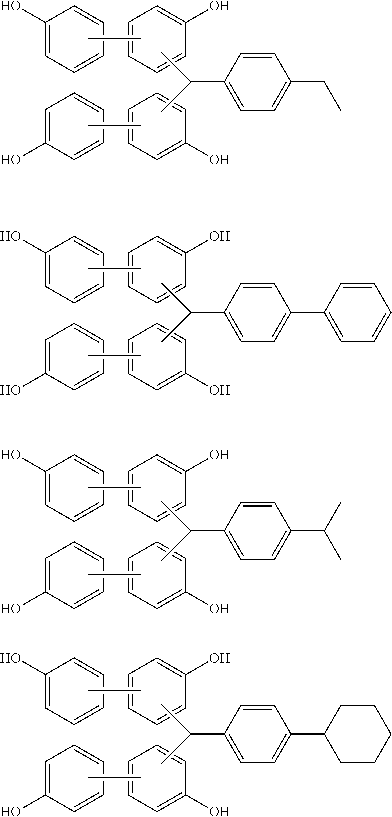

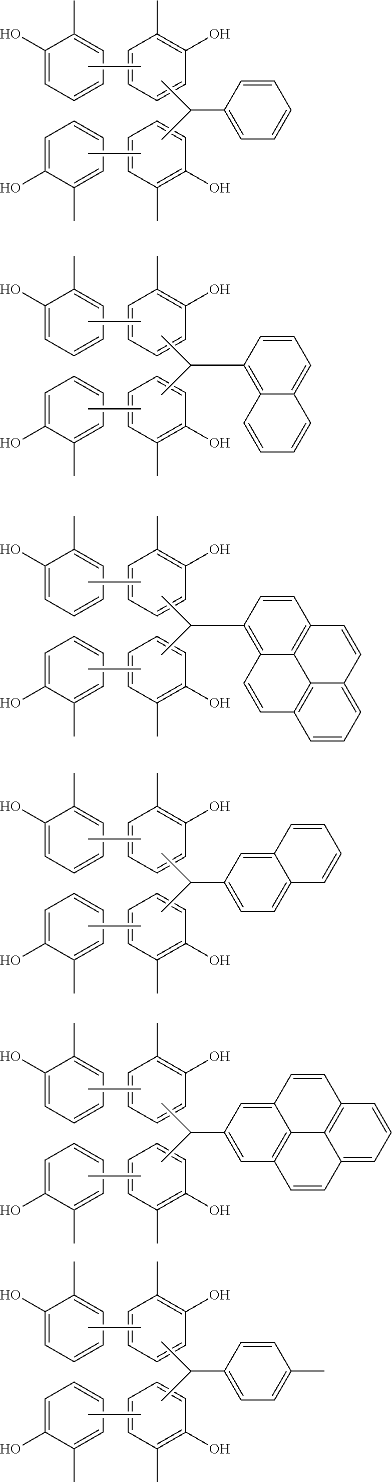

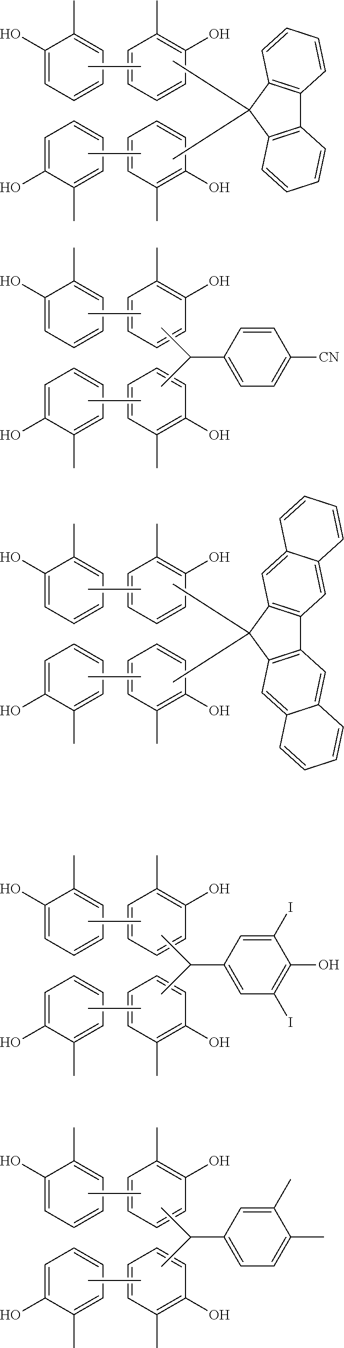

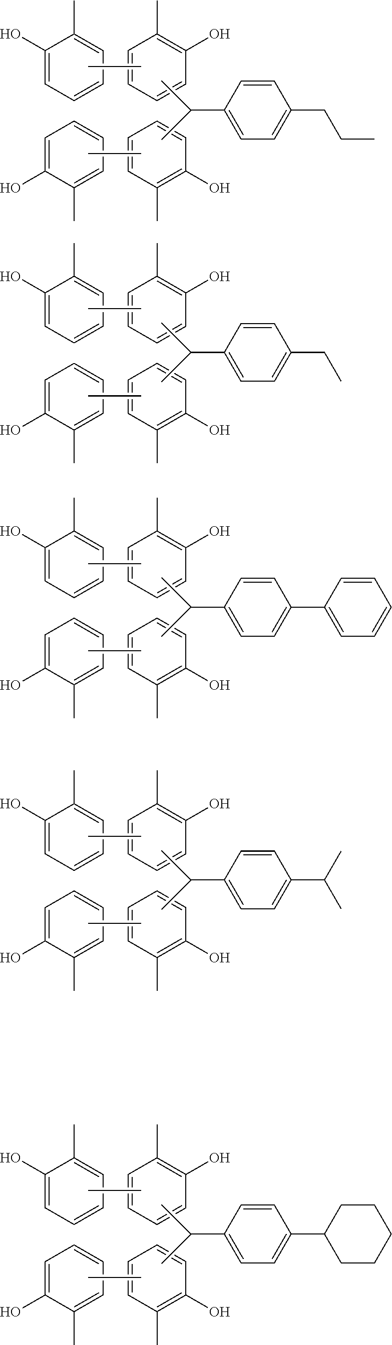

The compound represented by the formula (1B) is not particularly limited, and examples thereof include the following compounds.

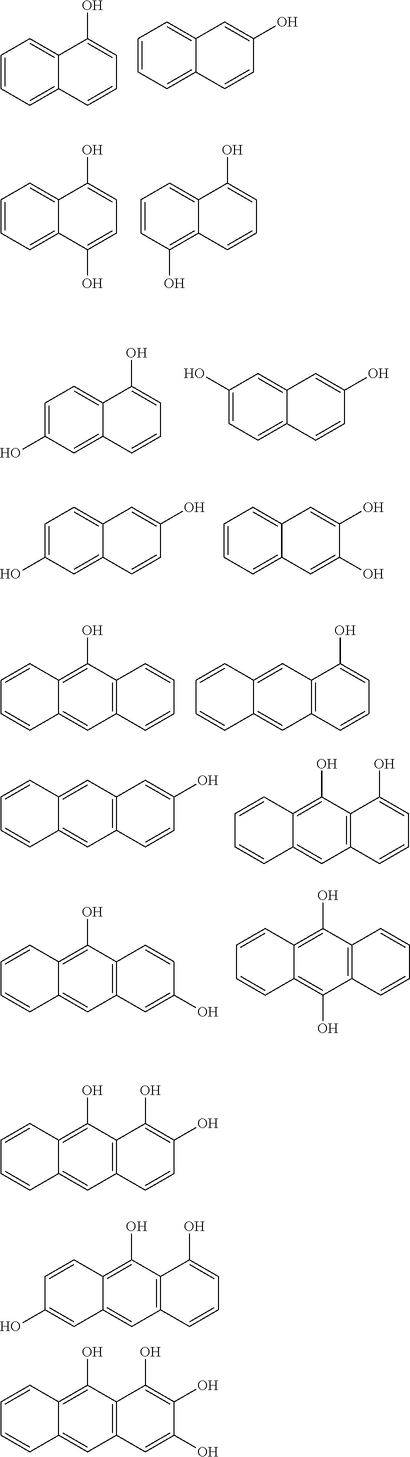

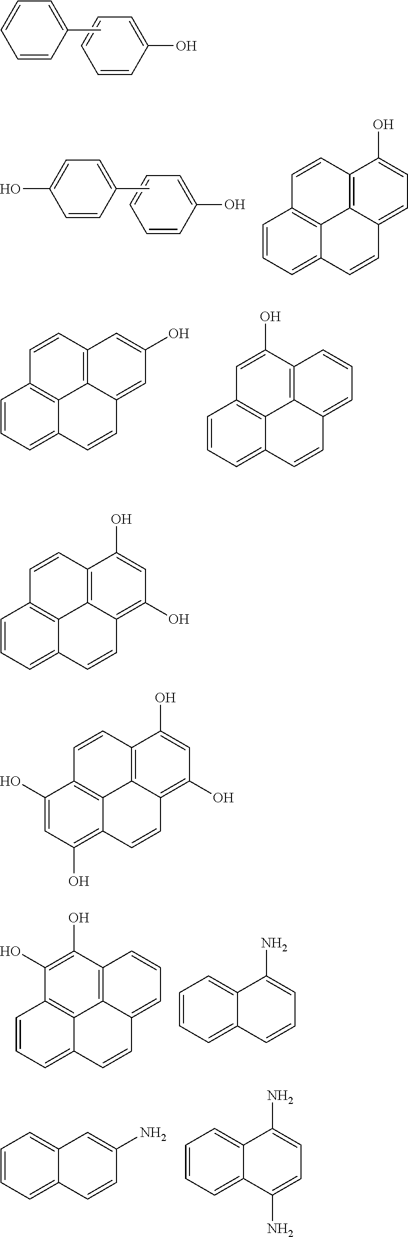

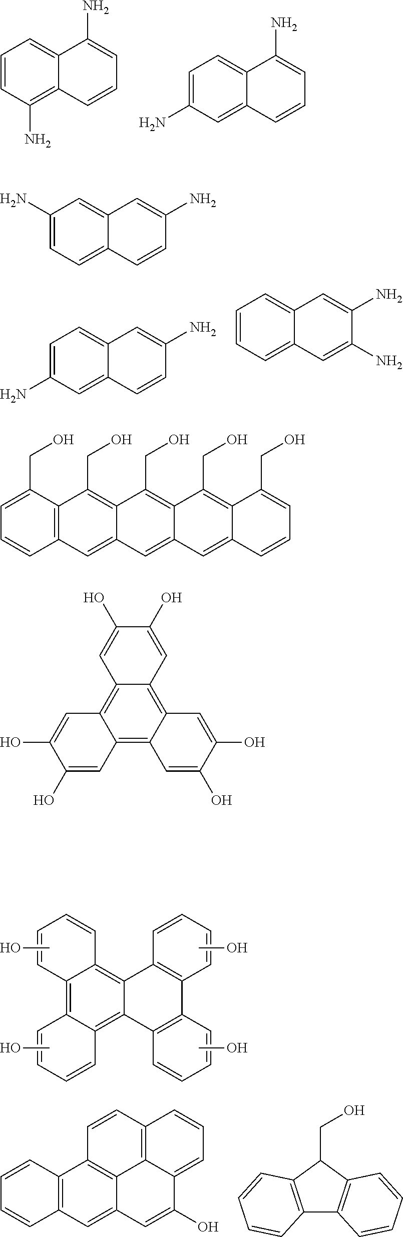

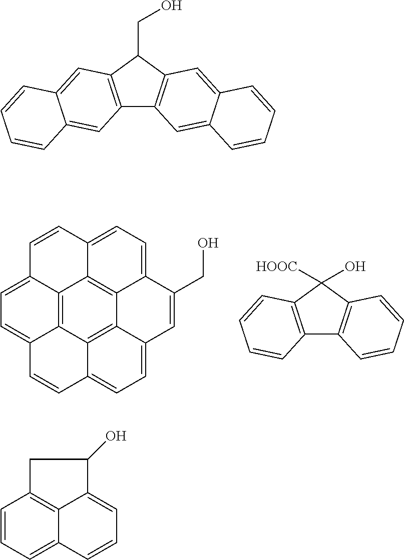

From the viewpoint of achieving solubility, heat resistance, and etching resistance at the same time, a polymer in which the compound represented by the formula (1C) is a compound represented by the following formula (1C-1) is preferred.

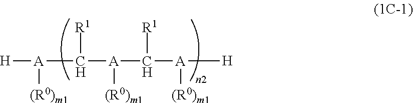

wherein each R¹ is independently a hydrogen atom, an alkyl group having 1 to 40 carbon atoms and optionally having a substituent, an aryl group having 6 to 40 carbon atoms and optionally having a substituent, an alkenyl group having 2 to 40 carbon atoms and optionally having a substituent, an alkynyl group having 2 to 40 carbon atoms, an alkoxy group having 1 to 40 carbon atoms and optionally having a substituent, a halogen atom, a thiol group, an amino group, a nitro group, a carboxyl group, or a hydroxyl group, A, R⁰, m1, and n2 are as defined in the formula (1C), and at least one R⁰ is a hydroxyl group, an alkoxy group having 1 to 40 carbon atoms and optionally having a substituent, or an amino group having 0 to 40 carbon atoms and optionally having a substituent.

From the viewpoint of achieving solubility, heat resistance, and etching resistance at the same time, a polymer in which the compound represented by the formula (1C-1) is a compound represented by the following formula (1C-2) is preferred.

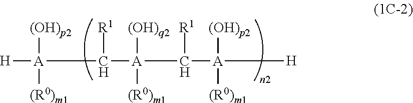

wherein each p2 is independently an integer of 1 to 4, each q2 is independently an integer of 0 to 4, R¹, A, R⁰, m1, and n2 are as defined in the formula (1C-1), and at least one R⁰ is a hydroxyl group, an alkoxy group having 1 to 40 carbon atoms and optionally having a substituent, or an amino group having 0 to 40 carbon atoms and optionally having a substituent.

From the viewpoint of further achieving both heat resistance and etching resistance, a polymer in which the compound represented by the formula (1C-2) is a compound represented by the following formula (1C-3) is preferred.

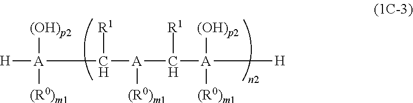

wherein R¹, A, R⁰, m1, n2, and p2 are as defined in the formula (1C-2), and at least one R⁰ is a hydroxyl group, an alkoxy group having 1 to 40 carbon atoms and optionally having a substituent, or an amino group having 0 to 40 carbon atoms and optionally having a substituent.

From the viewpoint of further achieving both heat resistance and etching resistance, a polymer in which the compound represented by the formula (1C-3) is at least one compound represented by the following formula (1C-4) is preferred.

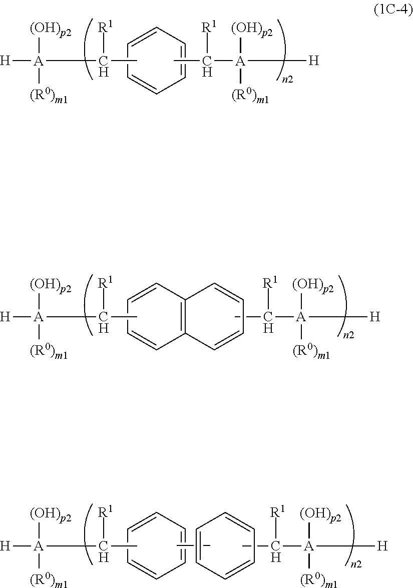

wherein R¹, A, R⁰, m1, and n2 are as defined in the formula (1C-3), and at least one R⁰ is a hydroxyl group, an alkoxy group having 1 to 40 carbon atoms and optionally having a substituent, or an amino group having 0 to 40 carbon atoms and optionally having a substituent.

From the viewpoint of further achieving solubility, heat resistance, and etching resistance at the same time, in the formula (1C), A is preferably a benzene ring or a naphthalene ring, and A is more preferably a benzene ring.

From the viewpoint of further achieving solubility, heat resistance, and etching resistance at the same time, R¹ is preferably a hydrogen atom.

The compound represented by the formula (1C) is not particularly limited, and examples thereof include the following compounds.

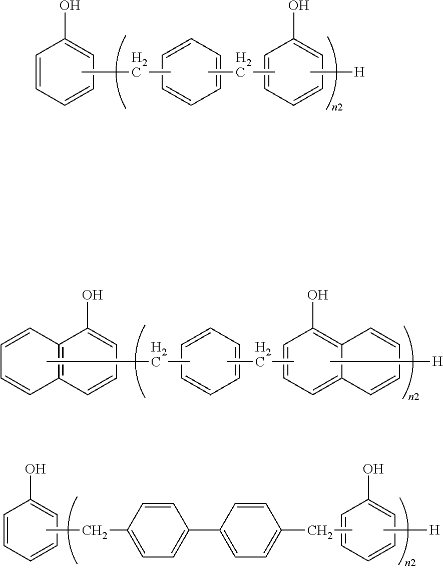

wherein n2 is as defined in the formula (1C).

From the viewpoint of achieving solubility, heat resistance, and etching resistance at the same time, a polymer in which the compound represented by the formula (1D) is a compound represented by the following formula (1D-1) is preferred.

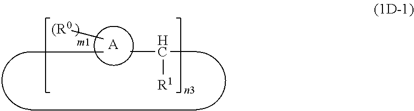

wherein each R¹ is independently a hydrogen atom, an alkyl group having 1 to 40 carbon atoms and optionally having a substituent, an aryl group having 6 to 40 carbon atoms and optionally having a substituent, an alkenyl group having 2 to 40 carbon atoms and optionally having a substituent, an alkynyl group having 2 to 40 carbon atoms, an alkoxy group having 1 to 40 carbon atoms and optionally having a substituent, a halogen atom, a thiol group, an amino group, a nitro group, a carboxyl group, or a hydroxyl group, A, R⁰, m1, and n3 are as defined in the formula (1D), and at least one R⁰ is a hydroxyl group, an alkoxy group having 1 to 40 carbon atoms and optionally having a substituent, or an amino group having 0 to 40 carbon atoms and optionally having a substituent.

From the viewpoint of achieving solubility, heat resistance, and etching resistance at the same time, a polymer in which at least one compound represented by the formula (1D) is a compound represented by the following formula (1D-2) is preferred.

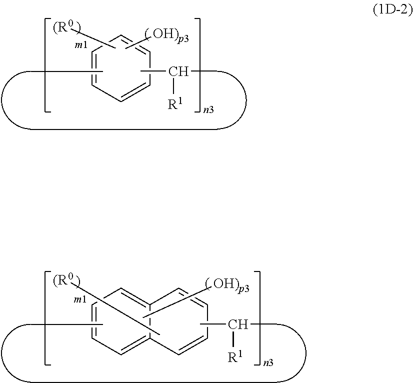

In the formula (1D-2), each p3 is independently an integer of 1 to 3, and R⁰, R¹, m1, and n3 are as defined in the formula (1D).

From the viewpoint of achieving solubility, heat resistance, and etching resistance at the same time, a polymer in which the compound represented by the formula (1D-1) is at least one compound represented by the following formula (1D-3) is preferred.

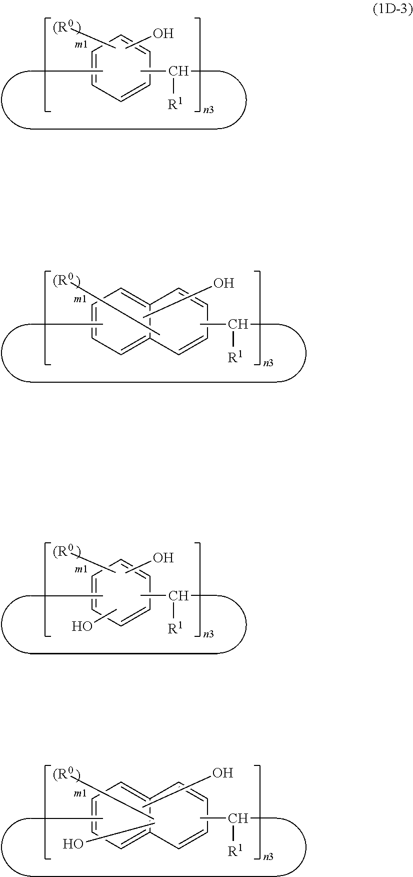

wherein each is independently an integer of 1 to 3, and R⁰, R¹, m1, and n3 are as defined in the formula (1D).

From the viewpoint of achieving solubility, heat resistance, and etching resistance at the same time, the polymer is preferably a polymer in which A of the compound represented by the formula (1B), (1C), or (1D) is benzene, biphenyl, terphenyl, diphenylmethylene, naphthalene, anthracene, naphthacene, pentacene, benzopyrene, chrysene, pyrene, triphenylene, corannulene, coronene, ovalene, or fluorene, more preferably, benzene, biphenyl, terphenyl, naphthalene, anthracene, naphthacene, pentacene, benzopyrene, chrysene, pyrene, triphenylene, corannulene, coronene, ovalene, or fluorene, still more preferably, biphenyl, terphenyl, naphthalene, anthracene, naphthacene, pentacene, benzopyrene, chrysene, pyrene, triphenylene, corannulene, coronene, ovalene, or fluorene, and particularly preferably, biphenyl, naphthalene, anthracene, and fluorene, from the viewpoint of etching resistance.

The compound represented by the formula (1D) is not particularly limited, and examples thereof include the following compounds.

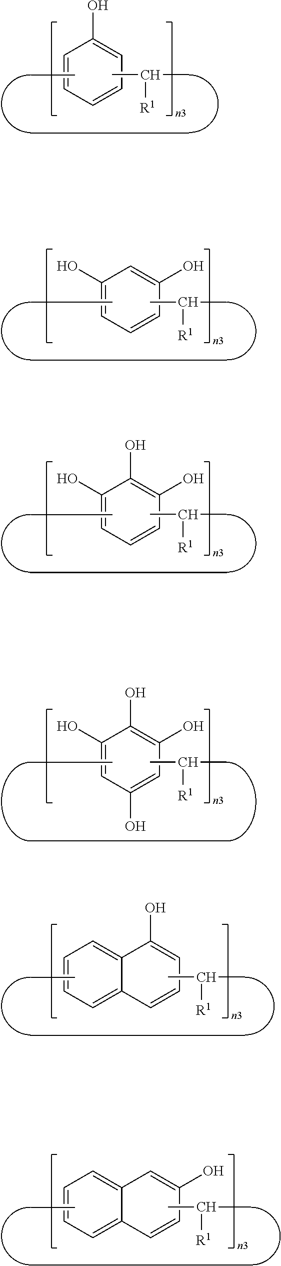

wherein R¹ and n3 are as defined in the formula (1D).

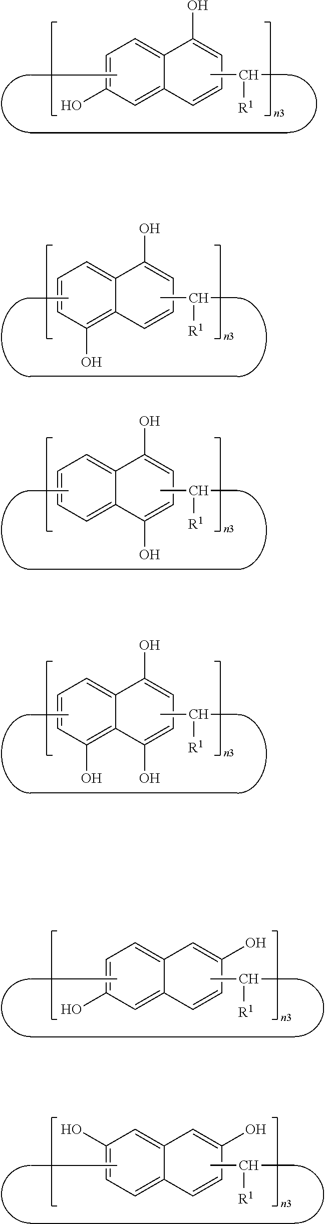

wherein R¹ and n3 are as defined in the formula (1D).

Further, R¹ in each formula is more preferably a hydrogen atom or a structure selected from the group consisting of the following structures:

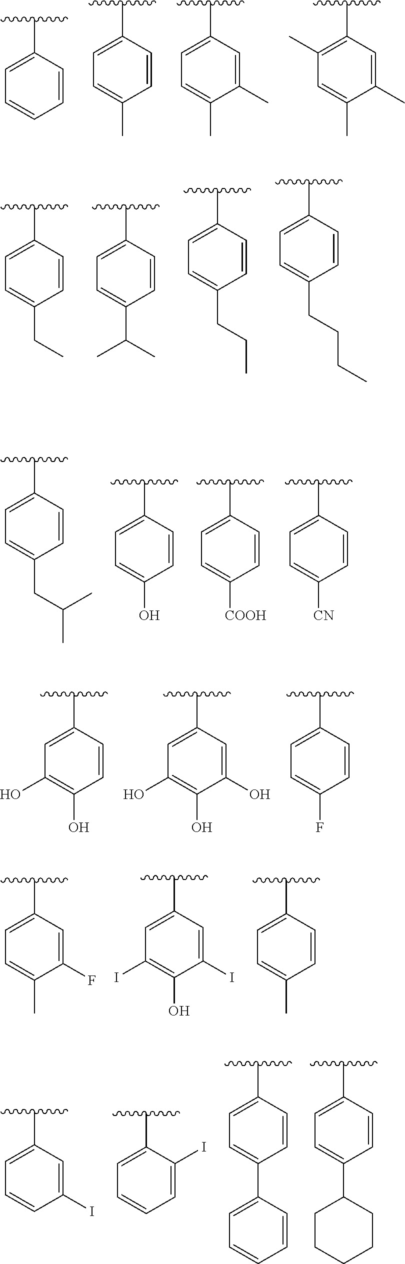

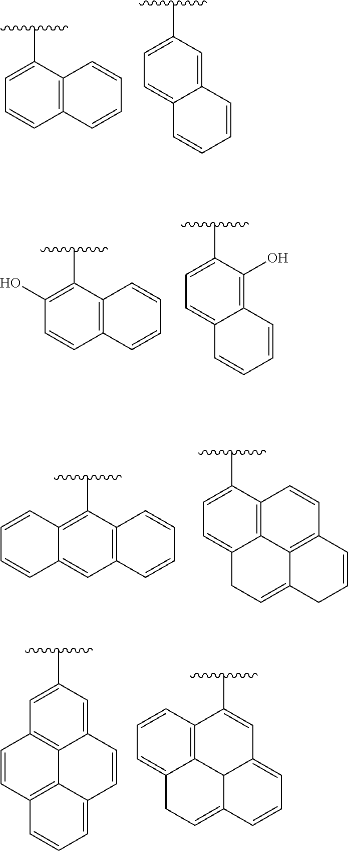

In the present embodiment, the position of the heteroatom in the heteroatom-containing aromatic monomer is not particularly limited, but it is preferable that the heteroatom constitutes an aromatic ring from the viewpoint of achieving heat resistance, solubility, and etching resistance at the same time. That is, the heteroatom-containing aromatic monomer preferably contains a heterocyclic aromatic compound.

In the present embodiment, the heteroatom in the heteroatom-containing aromatic monomer is not particularly limited, and examples thereof include an oxygen atom, a nitrogen atom, a phosphorus atom, and a sulfur atom. In the present embodiment, from the viewpoint of etching resistance, the heteroatom-containing aromatic monomer preferably contains a nitrogen atom, a phosphorus atom, or a sulfur atom as a heteroatom rather than an oxygen atom. That is, the heteroatom in the heteroatom-containing aromatic monomer preferably contains at least one selected from the group consisting of a nitrogen atom, a phosphorus atom, and a sulfur atom.

From the viewpoint of achieving both heat resistance and etching resistance, the heteroatom-containing aromatic monomer preferably includes a substituted or unsubstituted monomer represented by the following formula (1E-1) or a substituted or unsubstituted monomer represented by the following formula (1E-2).

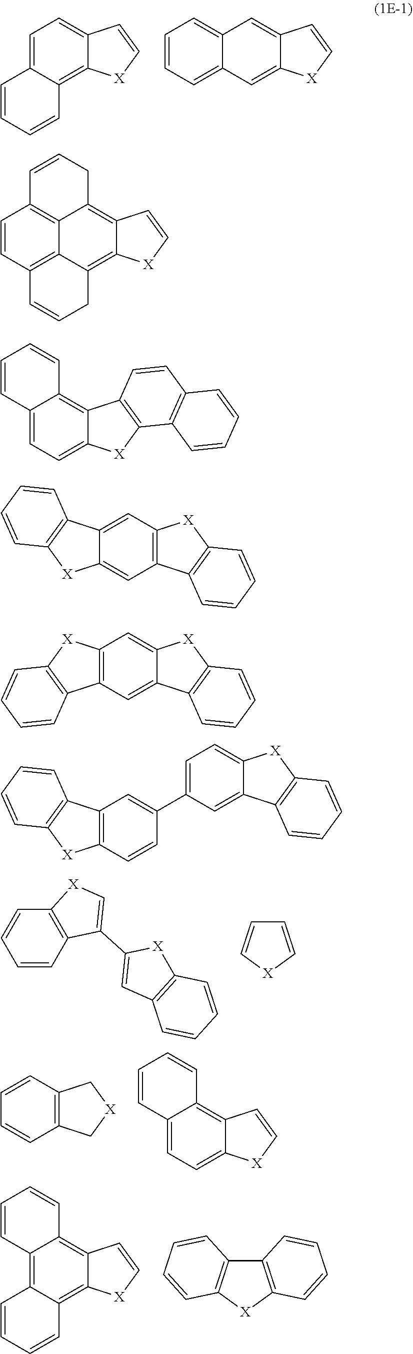

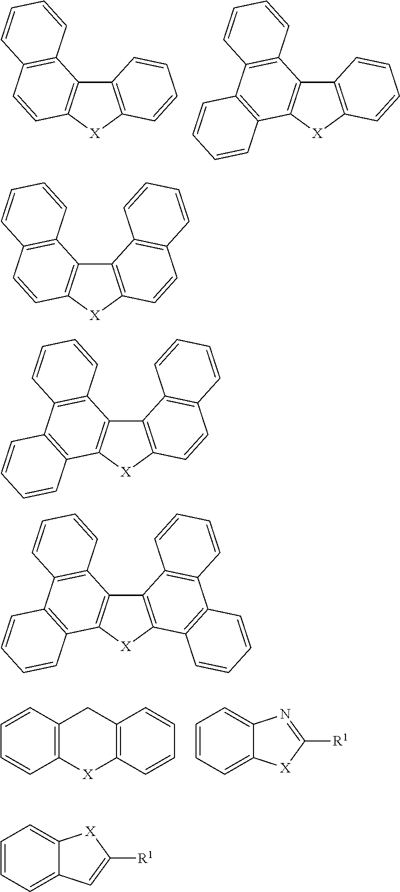

wherein each X is independently a group represented by NR⁰, a sulfur atom, an oxygen atom, or a group represented by PR⁰, and R⁰ and R¹ are each independently a hydrogen atom, a hydroxy group, a substituted or unsubstituted alkoxy group having 1 to 30 carbon atoms, a halogen atom, a substituted or unsubstituted alkyl group having 1 to 30 carbon atoms, or a substituted or unsubstituted aryl group having 6 to 30 carbon atoms, and

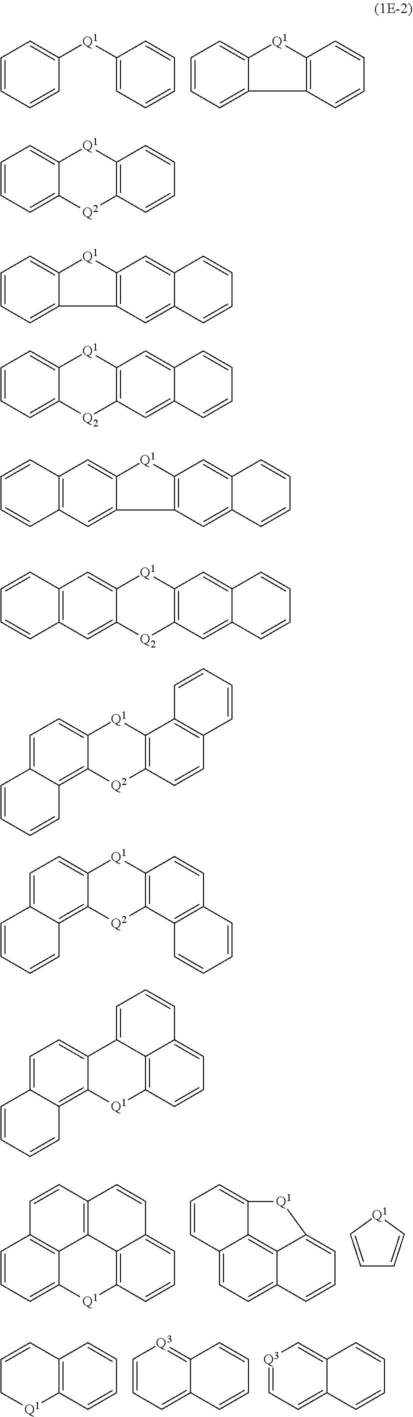

wherein
Q¹ and Q² are a single bond, a substituted or unsubstituted alkylene group having 1 to 20 carbon atoms, a substituted or unsubstituted cycloalkylene group having 3 to 20 carbon atoms, a substituted or unsubstituted arylene group having 6 to 20 carbon atoms, a substituted or unsubstituted heteroarylene group having 2 to 20 carbon atoms, a substituted or unsubstituted alkenylene group having 2 to 20 carbon atoms, a substituted or unsubstituted alkynylene group having 2 to 20 carbon atoms, a carbonyl group, a group represented by NR^{a}, an oxygen atom, a sulfur atom, or a group represented by PR^{a}, each R^{a} is independently a hydrogen atom, a substituted or unsubstituted alkyl group having 1 to 10 carbon atoms, or a halogen atom, wherein when both Q¹ and Q² are present in the monomer, at least one selected from Q¹ and Q² contains a heteroatom, and when only Q¹ is present in the monomer, Q¹ contains a heteroatom; Q³ is a nitrogen atom, a phosphorus atom or a group represented by CR^{b}, wherein Q³ contains a heteroatom in the monomer; and R^{a} and R^{b} are each independently a hydrogen atom, a substituted or unsubstituted alkyl group having 1 to 10 carbon atoms, or a halogen atom.

Hereinafter, the above formulas (1E-1) and (1E-2) will be described in detail.

In the formula (1E-1), each X is independently a group represented by NR⁰, a sulfur atom, an oxygen atom, or a group represented by PR⁰, and R⁰ and R¹ are each independently a hydrogen atom, a hydroxy group, a substituted or unsubstituted alkoxy group having 1 to 30 carbon atoms, a halogen atom, a substituted or unsubstituted alkyl group having 1 to 30 carbon atoms, or a substituted or unsubstituted aryl group having 6 to 30 carbon atoms.

In the formula (1E-1), each X is preferably independently a group represented by NR⁰, a sulfur atom, or a group represented by PR⁰.

Examples of the substituted or unsubstituted alkoxy group having 1 to 30 carbon atoms include, but are not limited to, a methoxy group, an ethoxy group, a propoxy group, a butoxy group, pentoxy, hexyloxy, octyloxy, and 2-ethylhexyloxy.

Examples of the halogen atom include, but are not limited to, a fluorine atom, a chlorine atom, a bromine atom, and an iodine atom.

Examples of the substituted or unsubstituted alkyl group having 1 to 30 carbon atoms include, but are not limited to, a methyl group, an ethyl group, an n-propyl group, an i-propyl group, an n-butyl group, an i-butyl group, a t-butyl group, a sec-butyl group, an n-pentyl group, a neopentyl group, an isoamyl group, an n-hexyl group, an n-heptyl group, an n-octyl group, an n-dodecyl group, a barrel group, and 2-ethylhexyl.

Examples of the substituted or unsubstituted aryl group having 6 to 30 carbon atoms include, but are not limited to, a phenyl group, a naphthyl group, a biphenyl group, a fluorenyl group, an anthryl group, a pyrenyl group, an azulenyl group, an acenaphthylenyl group, a terphenyl group, a phenanthryl group, and a perylene group.

In the present embodiment, R¹ in the formula (1E-1) is preferably a substituted or unsubstituted phenyl group from the viewpoint of achieving both solubility and etching resistance.

In the formula (1E-2), Q¹ and Q² are a single bond, a substituted or unsubstituted alkylene group having 1 to 20 carbon atoms, a substituted or unsubstituted cycloalkylene group having 3 to 20 carbon atoms, a substituted or unsubstituted arylene group having 6 to 20 carbon atoms, a substituted or unsubstituted heteroarylene group having 2 to 20 carbon atoms, a substituted or unsubstituted alkenylene group having 2 to 20 carbon atoms, a substituted or unsubstituted alkynylene group having 2 to 20 carbon atoms, a carbonyl group, a group represented by NR^{a}, an oxygen atom, a sulfur atom, or a group represented by PR^{a}, each R^{a} is independently a hydrogen atom, a substituted or unsubstituted alkyl group having 1 to 10 carbon atoms, or a halogen atom, wherein when both Q¹ and Q² are present in the monomer, at least one selected from Q¹ and Q² contains a heteroatom, and when only Q¹ is present in the monomer, Q¹ contains a hetero atom.

In the formula (1E-2), Q³ is a nitrogen atom, a phosphorus atom or a group represented by CR^{b}, wherein Q³ contains a hetero atom in the monomer.

R^{a} and R^{b} are each independently a hydrogen atom, a substituted or unsubstituted alkyl group having 1 to 10 carbon atoms, or a halogen atom.

Examples of the substituted or unsubstituted alkylene group having 1 to 20 carbon atoms include, but are not limited to, a methylene group, an ethylene group, an n-propylene group, an i-propylene group, an n-butylene group, an i-butylene group, a t-butylene group, an n-pentylene group, an n-hexylene group, an n-dodecylene group, a valerene group, a methylmethylene group, a dimethylmethylene group, and a methylethylene group.

Examples of the substituted or unsubstituted cycloalkylene group having 3 to 20 carbon atoms include, but are not limited to, a cyclopropylene group, a cyclobutylene group, a cyclopentylene group, a cyclohexylene group, a cyclododecylene group, and a cyclovalerene group.

Examples of the substituted or unsubstituted arylene group having 6 to 20 carbon atoms include, but are not limited to, a phenylene group, a naphthylene group, an anthrylene group, a phenanthrenylene group, a pyrenylene group, a perylenylene group, a fluorenylene group, and a biphenylene group.

Examples of the substituted or unsubstituted heteroarylene group having 2 to 20 carbon atoms include, but are not limited to, a thienylene group, a pyridinylene group, and a furylene group.

Examples of the substituted or unsubstituted alkenylene group having 2 to 20 carbon atoms include a vinylene group, a propenylene group, and a butenylene group.

Examples of the substituted or unsubstituted alkynylene group having 2 to 20 carbon atoms include an ethynylene group, a propynylene group, and a butynylene group.

Examples of the substituted or unsubstituted alkyl group having 1 to 10 carbon atoms include, but are not limited to, a methyl group, an ethyl group, a n-propyl group, an i-propyl group, a n-butyl group, an i-butyl group, a t-butyl group, a n-pentyl group, a n-hexyl group, a n-dodecyl group, and a barrel group.

Examples of the halogen atom include a fluorine atom, a chlorine atom, a bromine atom, and an iodine atom.

When the polymer of the present embodiment has a constituent unit derived from a heteroatom-containing aromatic monomer, the heat resistance can be improved by direct bonding of the aromatic monomer having a heteroatom. Further, by containing a heteroatom such as P, N, O or S in the structural unit, etching resistance of the polymer can be secured, and solvent solubility can be improved by increasing polarity of the polymer by the heteroatom. Furthermore, an organic film using a polymer in which an aromatic monomer having the heteroatom in the structural unit is directly bonded can secure an excellent film density, and processing accuracy by etching can be improved.

From the above viewpoint, in the present embodiment, the heteroatom-containing aromatic monomer is preferably a substituted or unsubstituted monomer represented by the following formula (1E-1), and more preferably contains at least one selected from the group consisting of indole, 2-phenylbenzoxazole, 2-phenylbenzothiazole, carbazole and dibenzothiophene.

The polymer of the present embodiment preferably further has a constituent unit derived from a monomer represented by the following formula (1E-3) from the viewpoint of achieving higher heat resistance, etching resistance and solubility at the same time.

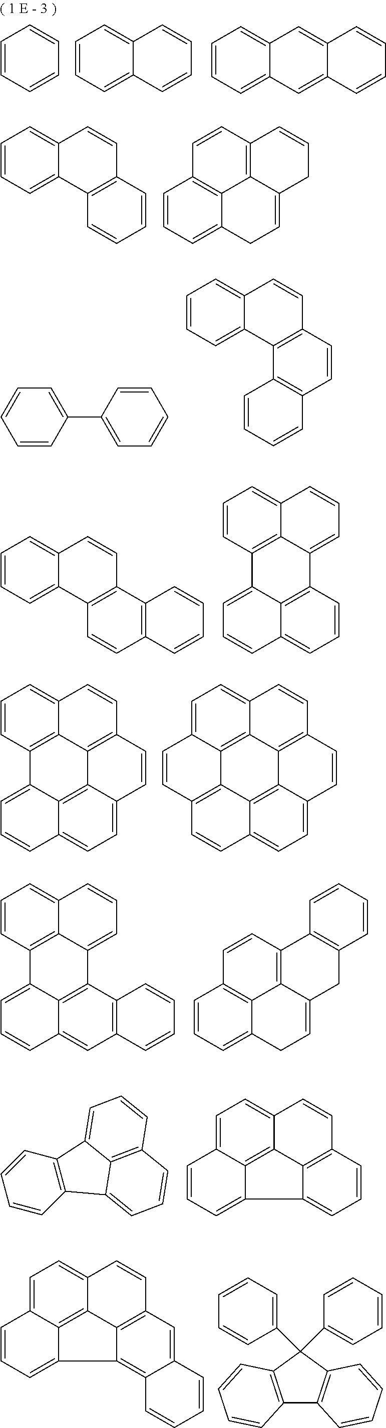

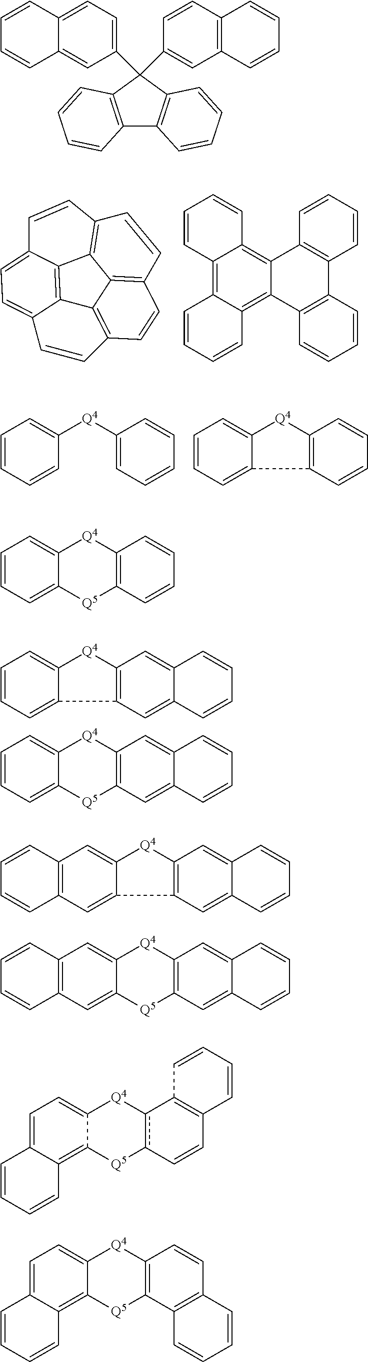

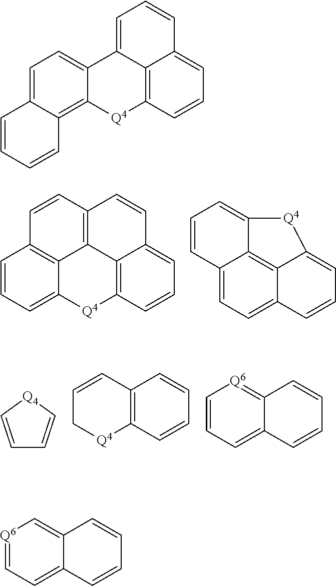

In the formula (1E-3), Q⁴ and Q⁵ are a single bond, a substituted or unsubstituted alkylene group having 1 to 20 carbon atoms, a substituted or unsubstituted cycloalkylene group having 3 to 20 carbon atoms, a substituted or unsubstituted arylene group having 6 to 20 carbon atoms, a substituted or unsubstituted alkenylene group having 2 to 20 carbon atoms, and a substituted or unsubstituted alkynylene group having 2 to 20 carbon atoms.

Q⁶ is a group represented by CR^{b}′, and R^{b}′ is a hydrogen atom or a substituted or unsubstituted alkyl group having 1 to 10 carbon atoms.

The substituted or unsubstituted alkylene group having 1 to 20 carbon atoms, the substituted or unsubstituted cycloalkylene group having 3 to 20 carbon atoms, the substituted or unsubstituted arylene group having 6 to 20 carbon atoms, the substituted or unsubstituted alkenylene group having 2 to 20 carbon atoms, and the substituted or unsubstituted alkynylene group having 2 to 20 carbon atoms are the same as defined in the formula (1E-2).

In the polymer of the present embodiment, the number and ratio of the respective constituent units are not particularly limited, but are preferably appropriately regulated in consideration of the application and the following values of molecular weight. Further, the polymer of the present embodiment may be constituted only by the formula (0) or may be constituted by copolymerization with the other copolymerizable component described above, but may also contain other constituent units within a range that does not impair the performance according to the application. Examples of the other constituent unit include a constituent unit having an ether bond formed by condensation of a phenolic hydroxy group and a constituent unit having a ketone structure. As described above, these other constituent units may also be directly bonded to the constituent unit derived from the monomer represented by the formula (0) through aromatic rings.

The weight-average molecular weight of the polymer of the present embodiment is not particularly limited, but is preferably in the range of 400 to 100,000, more preferably 500 to 20,000, and still more preferably 1,000 to 15,000 in terms of both heat resistance and solubility.

The range of the ratio of the weight-average molecular weight (Mw) to the number-average molecular weight (Mn) (Mw/Mn) is not particularly limited because the ratio required varies depending on the application, but as those having a more homogeneous molecular weight, for example, those having a ratio in the range of 3.0 or less are preferable, those having a ratio in the range of 1.05 or more and 3.0 or less are more preferable, those having a ratio in the range of 1.05 or more and less than 2.0 are particularly preferable, and those having a ratio in the range of 1.05 or more and less than 1.5 are yet still further preferable from the viewpoint of heat resistance.

The bonding order of the constituent unit included in the polymer of the present embodiment is not particularly limited. For example, only one unit derived from one monomer represented by the formula (0) may be contained as two or more constituent units, or a plurality of units derived from two or more monomers represented by the formula (0) may be contained as one or more constituent units. The order may be either block copolymerization or random copolymerization.

In the polymer of the present embodiment, examples of “the polymer has sites in which the constituent units are linked by direct bonding between aromatic rings” include an aspect where the polymer has sites in which the constituent units derived from a monomer represented by the formula (0) in the polymer (hereinafter, may be simply referred to as “constituent unit (0)”) are bonded by a single bond between a carbon atom on a benzene ring of one constituent unit (0) and a carbon atom on a benzene ring of the other constituent units (0), that is, directly bonded without any other atom such as a carbon atom, an oxygen atom or a sulfur atom. In this case, when the polymer of the present embodiment contains a constituent unit having an aromatic ring and derived from an other copolymerizable compound, the aspect where “the polymer has sites in which the constituent units are linked by direct bonding between aromatic rings” includes an aspect where the polymer has sites in which a benzene ring of the constituent unit (0) and an aromatic ring in the constituent unit derived from an other copolymerizable compound are bonded by a single bond, that is, directly bonded without any other atom such as a carbon atom, an oxygen atom or a sulfur atom.

The position at which the constituent units are directly bonded in the polymer of the present embodiment is not particularly limited, and any one carbon atom to which a substituent is not bonded is involved in the direct bonding between the monomers.

From the viewpoint of heat resistance, any one carbon atom of the monomer is preferably involved in direct bonding between aromatic rings. In other words, when the constituent unit (0) or the constituent unit derived from an other copolymerizable compound has two or more aromatic rings, and when two constituent units are bonded to one constituent unit, each of two or more aryl structures in each constituent unit is preferably bonded to the other constituent unit. When each of the two or more aromatic rings is bonded to the other constituent unit, the positions of the carbon atoms bonded to the other constituent unit in each aromatic ring may be different from each other, or may be the corresponding positions (for example, each is bonded to the 4-position).

Further, in the polymer of the present embodiment, all the constituent units (0) are preferably bonded to the other constituent unit (0) or the constituent unit derived from an other copolymerizable compound having aromatic rings by direct bonding between aromatic rings, but a constituent unit (0) bonded to another constituent unit via another atom such as oxygen or carbon may also be contained. Although not particularly limited, from the viewpoint of sufficiently exhibiting the effects of the present embodiment such as heat resistance and etching resistance, it is preferable that 45% or more, more preferably 65% or more, still more preferably 85% or more, particularly preferably 90% or more of the constituent units (0) on a bonding basis are bonded to other constituent units (0) by direct bonding between aromatic rings in all the constituent unit (0) in the polymer of the present embodiment. Furthermore, it is preferable that the polymer of the present embodiment has sites in which the constituent units (0) are linked by direct bonding between aromatic rings from the viewpoint of heat resistance.

The polymer of the present embodiment preferably has high solubility in a solvent from the viewpoint of easier application to a wet process, etc. More specifically, the polymer of the present embodiment preferably has a solubility of 1% by mass or more in one or more selected from the group consisting of propylene glycol monomethyl ether (PGME), propylene glycol monomethyl ether acetate (PGMEA), cyclohexanone (CHN), cyclopentanone (CPN), ethyl lactate (EL), and methyl hydroxyisobutyrate (HBM). Specifically, the solubility in the solvent at 23° C. is preferably 1% by mass or more, more preferably 5% by mass or more, still more preferably 10% by mass or more, particularly preferably 20% by mass or more, and particularly preferably 30% by mass or more. Here, the solubility in PGME, PGMEA, CHN, CPN, EL and/or HBM is defined as “mass of polymer+(mass of polymer+mass of solvent)×100 (% by mass)”. For example, 10 g of the polymer is evaluated as being dissolved in 90 g of PGMEA when the solubility of the polymer in the PGMEA is “10% by mass or more”; 10 g of the polymer is evaluated as being not dissolved in 90 g of PGMEA when the solubility is “less than 10% by mass”.

The polymer of the present embodiment may further have a modified portion derived from a crosslinking compound. That is, the polymer of the present embodiment having the structure described above may have a modified portion obtained by reaction with the crosslinking compound. Such a (modified) polymer is also excellent in heat resistance and etching resistance, and can be used as a coating agent for semiconductors, a material for resists, and a semiconductor underlayer film forming material.

Examples of the crosslinking compound include, but are not limited to, aldehydes, ketones, carboxylic acids, carboxylic acid halides, a halogen containing compound, an amino compound, an imino compound, an isocyanate compound, and an unsaturated hydrocarbon group containing compound. These can be used alone or in combination as appropriate.

In the present embodiment, the crosslinking compound is preferably an aldehyde or a ketone. More specifically, it is preferably a polymer obtained by subjecting the polymer of the present embodiment having the structure described above to a polycondensation reaction with an aldehyde or a ketone in the presence of a catalyst. For example, a novolac type of polymer can be obtained by subjecting an aldehyde or a ketone corresponding to a desired structure to a further polycondensation reaction under normal pressure and optionally pressurized conditions under a catalyst.

Examples of the aldehyde include, but are not particularly limited to, formaldehyde, paraformaldehyde, trioxane, benzaldehyde, methylbenzaldehyde, dimethylbenzaldehyde, trimethylbenzaldehyde, ethylbenzaldehyde, propylbenzaldehyde, butylbenzaldehyde, pentabenzaldehyde, butylmethylbenzaldehyde, hydroxybenzaldehyde, dihydroxybenzaldehyde, and fluoromethylbenzaldehyde. These aldehydes can be used alone as one kind or can be used in combination of two or more kinds. Among them, benzaldehyde, methylbenzaldehyde, dimethylbenzaldehyde, trimethylbenzaldehyde, ethylbenzaldehyde, propylbenzaldehyde, butylbenzaldehyde, pentabenzaldehyde, butylmethylbenzaldehyde, or the like is preferably used from the viewpoint of imparting high heat resistance.

Examples of the ketone include, but are not particularly limited to, acetophenone, acetylmethylbenzene, acetyldimethylbenzene, acetyltrimethylbenzene, acetylethylbenzene, acetylpropylbenzene, acetylbutylbenzene, acetylpentabenzene, acetylbutylmethylbenzene, acetylhydroxybenzene, acetyldihydroxybenzene, and acetylfluoromethylbenzene. These ketones can be used alone as one kind or can be used in combination of two or more kinds. Among them, acetophenone, acetylmethylbenzene, acetyldimethylbenzene, acetyltrimethylbenzene, acetylethylbenzene, acetylpropylbenzene, acetylbutylbenzene, acetylpentabenzene, or acetylbutylmethylbenzene is preferably used from the viewpoint of imparting high heat resistance.

The catalyst used in the above reaction can be appropriately selected for use from publicly known catalysts and is not particularly limited. An acid catalyst or a base catalyst is suitably used as the catalyst. As these base catalyst, acid catalysts and base catalysts described in PCT/JP2021/26669 can be used.

The catalysts can be used alone as one kind or can be used in combination of two or more kinds. Further, the amount of the catalyst used can be appropriately set according to, the kind of the raw materials used and the catalyst used and moreover the reaction conditions and is not particularly limited, but is preferably 0.001 to 100 parts by mass based on 100 parts by mass of the reaction raw materials.

Upon the above reaction, a reaction solvent may be used. The reaction solvent is not particularly limited as long as the reaction of the aldehyde or the ketone used with the polymer proceeds, and can be arbitrarily selected and used from publicly known solvents. Examples include water, methanol, ethanol, propanol, butanol, tetrahydrofuran, dioxane, ethylene glycol dimethyl ether, ethylene glycol diethyl ether, and a mixed solvent thereof. The solvents can be used alone as one kind or can be used in combination of two or more kinds. Further, the amount of these solvents used can be appropriately set according to the kind of the raw materials used and the acid catalyst used and moreover the reaction conditions. The amount of the above solvent used is not particularly limited, but is preferably in the range of 0 to 2000 parts by mass based on 100 parts by mass of the reaction raw materials. Furthermore, the reaction temperature in the above reaction can be appropriately selected according to the reactivity of the reaction raw materials. The above reaction temperature is not particularly limited, but is usually preferably within the range of 10 to 200° C. The reaction method can be arbitrarily selected and used from publicly known approaches and is not particularly limited, and there are a method of charging the polymer of the present embodiment, the aldehyde or the ketone, and the acid catalyst in one portion, and a method of dropping the aldehyde or the ketone in the presence of the acid catalyst. After the polycondensation reaction terminates, isolation of the obtained compound can be performed according to a conventional method, and is not particularly limited. For example, by adopting a commonly used approach in which the temperature of the reaction vessel is elevated to 130 to 230° C. in order to remove unreacted raw materials, acid catalyst, etc. present in the system, and volatile portions are removed at about 1 to 50 mmHg, the compound which is the target compound can be obtained.

### [Method for Producing Polymer]

Examples of the method for producing the polymer of the present embodiment include, but are not limited to, a method including a step of polymerizing one or more of the monomers in the presence of an oxidizing agent. Specifically, the method includes a step of polymerizing one or more monomers represented by the formula (0) in the presence of an oxidizing agent. Further, when the polymer of the present embodiment contains the constituent unit derived from an other copolymerizable compound described above, the production method may include the step of polymerizing one or more monomers represented by the formula (0) and an other copolymerizable compound that is copolymerizable with the monomer represented by the formula (0) in the presence of an oxidizing agent.

In carrying out such a step, the contents of K. Matsumoto, Y. Shibasaki, S. Ando and M. Ueda, Polymer, 47, 3043 (2006) can be referred to as appropriate. That is, in the oxidative polymerization of the β-naphthol type monomer, the C—C coupling at the α-position is selectively caused by an oxidative coupling reaction in which a radical subjected to one-electron oxidation due to the monomer is coupled, and for example, regioselective polymerization can be performed by using a copper/diamine type catalyst.

The oxidizing agent according to the present embodiment is not particularly limited as long as it causes an oxidative coupling reaction, and examples thereof include metal salts containing copper, manganese, iron, cobalt, ruthenium, chromium, nickel, tin, lead, silver, palladium, or the like; peroxides such as hydrogen peroxide or perchloric acids; and organic peroxides. Among these, a metal salt or metal complex containing at least one selected from the group consisting of copper, manganese, iron, cobalt, ruthenium, chromium, nickel, tin, lead, silver, and palladium can be preferably used.

Metals such as copper, manganese, iron, cobalt, ruthenium, lead, nickel, silver, tin, chromium or palladium can also be used as oxidizing agents by reduction in the reaction system. These are included in metal salts.

For example, the monomer represented by the formula (0) is dissolved or dispersed in organic solvents, metallic salts containing copper, manganese or cobalt are added thereto, and the mixture is reacted with, for example, oxygen or an oxygen-containing gas to carry out oxidative polymerization, to obtain a desired polymer.

According to the method for producing a polymer by oxidative polymerization as described above, it is relatively easy to control the molecular weight, and since a polymer having a small molecular weight distribution can be obtained without leaving a raw material monomer or a low molecular component accompanying the increase in the molecular weight, it tends to be advantageous from the viewpoint of high heat resistance and low sublimation.

Examples of other production methods include coupling reactions using Grignard reagents and Suzuki-Miyaura coupling reactions.

The metal salts are not limited, and for example, halides such as copper, manganese, cobalt, ruthenium, chromium and palladium, carbonates, acetates, nitrates, phthalate or phosphates can be used.

The metal complex is not particularly limited, and any of known ones can be used. Specific examples thereof include, but are not limited to, complex catalysts containing copper described in Japanese Patent Laid-Open No. 36-18692, Japanese Patent Laid-Open No. 40-13423, Japanese Patent Laid-Open No. 49-490; complex catalysts containing manganese described in Japanese Patent Laid-Open No. 40-30354, Japanese Patent Laid-Open No. 47-5111, Japanese Patent Laid-Open No. 56-32523, Japanese Patent Laid-Open No. 57-44625, Japanese Patent Laid-Open No. 58-19329, Japanese Patent Laid-Open No. 60-83185; and complex catalysts containing cobalt described in Japanese Patent Laid-Open No. 45-23555.

Examples of organic peroxides include, but are not limited to, t-butyl hydroperoxide, di-t-butyl peroxide, cumene hydroperoxide, dicumyl peroxide, peracetic acid, and perbenzoic acid.

The oxidizing agents can be used alone or can be used in combination. The use amount thereof is not particularly limited, but is preferably from 0.002 mol to 10 mol, more preferably from 0.003 mol to 3 mol, and still more preferably from 0.005 mol to 0.3 mol, based on 1 mol of the monomer represented by the formula (0) (when another copolymerizable monomer is used in combination, the total amount of the monomer represented by the formula (0) and the other copolymerizable monomer). That is, the oxidizing agent according to the present embodiment can be used at a low concentration with respect to the monomer.

In the present embodiment, it is preferable to use a base in addition to the oxidizing agent used in the step of oxidative polymerization. The base is not particularly limited, and any of known bases can be used, and specific examples thereof include inorganic bases such as alkali metal hydroxides, alkaline earth metal hydroxides, and alkali metal alkoxides, and organic bases such as primary to tertiary monoamine compounds and diamines. These can be used alone or can be used in combination.

The oxidation method is not particularly limited, and there is a method of directly using oxygen gas or air, but air oxidation is preferable from the viewpoint of safety and cost. In the case of oxidation using air under atmospheric pressure, a method of introducing air by bubbling into a liquid in a reaction solvent is preferable from the viewpoint of improving the rate of oxidative polymerization and increasing the molecular weight of the polymer.

Further, the oxidizing reaction in the present embodiment can also be a reaction under pressurized conditions, and 2 kg/cm² to 15 kg/cm² are preferable from the viewpoint of accelerating reaction, and 3 kg/cm² to 10 kg/cm² are more preferable from the viewpoint of safety and controllability.

In the present embodiment, the oxidation reaction of the monomer can be performed even in the absence of a reaction solvent, but it is generally preferable to perform the reaction in the presence of a solvent. As the solvent, as long as there is no problem in obtaining the polymer of the present embodiment, various known solvents can be used as long as it dissolves the catalyst to some extent. Generally, alcohols such as methanol, ethanol, propanol, and butanol; ethers such as dioxane, tetrahydrofuran, or ethylene glycol dimethyl ether; solvents such as amides or nitriles; ketones such as acetone, methyl ethyl ketone, methyl isobutyl ketone, cyclohexanone, and cyclopentanone; or mixtures thereof with water are used. Further, the reaction can also be carried out with hydrocarbons such as benzene, toluene or hexane which are not immiscible with water or in a two phase system of those and water.

The reaction conditions may be appropriately adjusted according to the substrate concentration, the type and concentration of the oxidizing agent, but the reaction temperature can be set to a relatively low temperature, preferably 5 to 150° C., and more preferably 20 to 120° C. The reaction time is preferably 30 minutes to 24 hours, more preferably 1 hour to 20 hours. The stirring method during the reaction is not particularly limited, and may be any of shaking and stirring using a rotator or a stirring blade. This step may be carried out in a solvent or in an air stream as long as the stirring conditions satisfy the above conditions.

### [Composition]

The polymer of the present embodiment can be used as a composition assuming the various applications. That is, a composition of the present embodiment includes the polymer of the present embodiment. The composition of the present embodiment preferably further contains a solvent from the viewpoint of facilitating film formation by the application of a wet process, or the like.

Specific examples of the solvent include, but not particularly limited to: ketone-based solvents such as acetone, methyl ethyl ketone, methyl isobutyl ketone, and cyclohexanone; cellosolve-based solvents such as propylene glycol monomethyl ether and propylene glycol monomethyl ether acetate; ester-based solvents such as ethyl lactate, methyl acetate, ethyl acetate, butyl acetate, isoamyl acetate, methyl methoxypropionate, and methyl hydroxyisobutyrate; alcohol-based solvents such as methanol, ethanol, isopropanol, and 1-ethoxy-2-propanol; and aromatic hydrocarbons such as toluene, xylene, and anisole. These solvents can be used alone as one kind or can be used in combination of two or more kinds.

Among the above solvents, at least one selected from the group consisting of propylene glycol monomethyl ether, propylene glycol monomethyl ether acetate, cyclohexanone, cyclopentanone, ethyl lactate, and methyl hydroxyisobutyrate is particularly preferable from the viewpoint of safety.

The content of the solvent in the composition of the present embodiment is not particularly limited and is preferably 100 to 10,000 parts by mass based on 100 parts by mass of the polymer according to the present embodiment, more preferably 200 to 5,000 parts by mass, and still more preferably 200 to 1,000 parts by mass, from the viewpoint of solubility and film formation.

The polymer according to the present embodiment is preferably obtained as a crude product by the above oxidation reaction, and then further purified to remove the residual oxidizing agent. Specifically, from the viewpoint of prevention of degradation of the polymer over time and storage stability, it is preferable to avoid residues of metal salts or metal complexes containing copper, manganese, iron, or cobalt mainly used as metal oxidizing agents derived from the oxidizing agent. That is, in the composition of the present embodiment, the content of impurity metals is preferably less than 500 ppb for each metal species, and more preferably 1 ppb or less. Examples of the impurity metal include, but are not particularly limited to, at least one selected from the group consisting of copper, manganese, iron, cobalt, ruthenium, chromium, nickel, tin, lead, silver, and palladium.

When the amount of residual metal derived from the oxidizing agent (content of impurity metals) is less than 500 ppb, there is a tendency that the composition can be used without impairing storage stability even in the form of solutions.

Examples of the purification method include, but is not particularly limited to, the steps of: obtaining a solution (S) by dissolving the polymer in a solvent; and extracting impurities in the polymer by bringing the obtained solution (S) into contact with an acidic aqueous solution (a first extraction step), wherein the solvent used in the step of obtaining the solution (S) contains an organic solvent that does not inadvertently mix with water.

According to the purification method, the contents of various metals that may be contained as impurities in the polymer can be reduced.

More specifically, the polymer is dissolved in an organic solvent that does not inadvertently mix with water to obtain the solution (S), and further, extraction treatment can be performed by bringing the solution (S) into contact with an acidic aqueous solution. Thereby, metal components contained in the solution (S) are transferred to the aqueous phase, then the organic phase and the aqueous phase are separated, and thus a polymer having a reduced metal content can be obtained.

The solvent that does not inadvertently mix with water used in the purification method is not particularly limited, but is preferably an organic solvent that is safely applicable to semiconductor production processes, and specifically it is an organic solvent having a solubility in water at room temperature of less than 30%, and more preferably is an organic solvent having a solubility of less than 20% and particularly preferably less than 10%. The amount of the organic solvent used is preferably 1 to 100 times the total mass of the polymer to be used.

Specific examples of the solvent that does not inadvertently mix with water include, but are not limited to, ethers such as diethyl ether and diisopropyl ether, esters such as ethyl acetate, n-butyl acetate, and isoamyl acetate; ketones such as methyl ethyl ketone, methyl isobutyl ketone, ethyl isobutyl ketone, cyclohexanone, cyclopentanone, 2-heptanone, and 2-pentanone; glycol ether acetates such as ethylene glycol monoethyl ether acetate, ethylene glycol monobutyl ether acetate, propylene glycol monomethyl ether acetate (PGMEA), and propylene glycol monoethyl ether acetate; aliphatic hydrocarbons such as n-hexane and n-heptane; aromatic hydrocarbons such as toluene and xylene; and halogenated hydrocarbons such as methylene chloride and chloroform. Among these, toluene, 2-heptanone, cyclohexanone, cyclopentanone, methyl isobutyl ketone, propylene glycol monomethyl ether acetate, ethyl acetate, and the like are preferable, methyl isobutyl ketone, ethyl acetate, cyclohexanone, and propylene glycol monomethyl ether acetate are more preferable, and methyl isobutyl ketone and ethyl acetate are still more preferable. Methyl isobutyl ketone, ethyl acetate and the like have relatively high saturation solubility for the polymer and a relatively low boiling point, and it is thus possible to reduce the load in the case of industrially distilling off the solvent and in the step of removing the solvent by drying. These solvents can be each used alone, or can also be used as a mixture of two or more kinds.

The acidic aqueous solution used in the purification method is appropriately selected from aqueous solutions in which organic compounds or inorganic compounds are dissolved in water, generally known as acidic aqueous solutions. Examples of the acidic aqueous solution include, but are not limited to, aqueous solutions of mineral acid in which mineral acids such as hydrochloric acid, sulfuric acid, nitric acid, and phosphoric acid are dissolved in water, or aqueous solutions of organic acid in which organic acids such as acetic acid, propionic acid, oxalic acid, malonic acid, succinic acid, fumaric acid, maleic acid, tartaric acid, citric acid, methanesulfonic acid, phenolsulfonic acid, p-toluenesulfonic acid, and trifluoroacetic acid are dissolved in water. These acidic aqueous solutions can be each used alone, and can be also used as a combination of two or more kinds. Among these acidic aqueous solutions, aqueous solutions of one or more mineral acids selected from the group consisting of hydrochloric acid, sulfuric acid, nitric acid and phosphoric acid, or aqueous solutions of one or more organic acids selected from the group consisting of acetic acid, propionic acid, oxalic acid, malonic acid, succinic acid, fumaric acid, maleic acid, tartaric acid, citric acid, methanesulfonic acid, phenolsulfonic acid, p-toluenesulfonic acid and trifluoroacetic acid are preferable, aqueous solutions of sulfuric acid, nitric acid, and carboxylic acids such as acetic acid, oxalic acid, tartaric acid and citric acid are more preferable, aqueous solutions of sulfuric acid, oxalic acid, tartaric acid and citric acid are still more preferable, and an aqueous solution of oxalic acid is even more preferable. It is considered that polyvalent carboxylic acids such as oxalic acid, tartaric acid and citric acid coordinate with metal ions and provide a chelating effect, and thus tend to be capable of more effectively removing metals. Also, as for water used herein, it is preferable to use water, the metal content of which is small, such as ion exchanged water, according to the purpose of the purification method according to the present embodiment.

The pH of the acidic aqueous solution used in the purification method is not particularly limited, but it is preferable to regulate the acidity of the aqueous solution in consideration of an influence on the polymer. Normally, the pH range is about 0 to 5, and is preferably about pH 0 to 3.

The use amount of the acidic aqueous solution used in the purification method is not particularly limited, but it is preferable to regulate the amount from the viewpoint of reducing the number of extraction operations for removing metals and from the viewpoint of ensuring operability in consideration of the overall amount of fluid. From the above viewpoints, the amount of the acidic aqueous solution used is preferably 10 to 200 parts by mass, and more preferably 20 to 100 parts by mass, based on 100 parts by mass of the solution (S).

In the purification method, by bringing the acidic aqueous solution as described above into contact with the solution (S), metal components can be extracted from the polymer in the solution (S).

In the purification method, the solution (S) may further contain an organic solvent that inadvertently mixes with water. When the solution (S) contains an organic solvent that inadvertently mixes with water, there is a tendency that the amount of the polymer charged can be increased, also the fluid separability is improved, and purification can be performed at a high reaction vessel efficiency. The method for adding the organic solvent that inadvertently mixes with water is not particularly limited. For example, any of a method involving adding it to the organic solvent-containing solution in advance, a method involving adding it to water or the acidic aqueous solution in advance, and a method involving adding it after bringing the organic solvent-containing solution into contact with water or the acidic aqueous solution may be employed. Among these, the method involving adding it to the organic solvent-containing solution in advance is preferable in terms of the workability of operations and the ease of managing the amount to be charged.

The organic solvent that inadvertently mixes with water used in the purification method is not particularly limited, but is preferably an organic solvent that is safely applicable to semiconductor production processes. The amount of the organic solvent used that inadvertently mixes with water is not particularly limited as long as the solution phase and the aqueous phase separate, but is preferably 0.1 to 100 times, more preferably 0.1 to 50 times, and still more preferably 0.1 to 20 times the total mass of the polymer to be used.

Specific examples of the organic solvent used in the purification method that inadvertently mixes with water include, but are not limited to, ethers such as tetrahydrofuran and 1,3-dioxolane; alcohols such as methanol, ethanol, and isopropanol; ketones such as acetone and N-methylpyrrolidone; aliphatic hydrocarbons such as glycol ethers such as ethylene glycol monoethyl ether, ethylene glycol monobutyl ether, propylene glycol monomethyl ether, and propylene glycol monoethyl ether. Among these, N-methylpyrrolidone, propylene glycol monomethyl ether and the like are preferable, and N-methylpyrrolidone and propylene glycol monomethyl ether are more preferable. These solvents can be each used alone, or can also be used as a mixture of two or more kinds.

The temperature when extraction treatment is performed is usually in the range of 20 to 90° C., and preferably 30 to 80° C. The extraction operation is performed, for example, by thoroughly mixing by stirring or the like and then leaving the obtained mixed solution to stand still. Thereby, metal components contained in the solution (S) are transferred to the aqueous phase. Also, by this operation, the acidity of the solution is lowered, and the degradation of the polymer can be suppressed.

By being left to stand still, the mixed solution is separated into a solution phase containing the polymer and the solvents and an aqueous phase, and thus the solution phase is recovered by decantation and the like. The time for leaving the mixed solution to stand still is not particularly limited, but it is preferable to regulate the time for leaving the mixed solution to stand still from the viewpoint of attaining good separation of the solution phase containing the solvents and the aqueous phase. Normally, the time for leaving the mixed solution to stand still is 1 minute or longer, preferably 10 minutes or longer, and still more preferably 30 minutes or longer. While the extraction treatment may be carried out only once, it is also effective to repeat mixing, leaving-to-stand-still, and separating operations multiple times.

It is preferable that the purification method includes the step of extracting impurities in the polymer by further bringing the solution phase containing the polymer into contact with water after the first extraction step (the second extraction step).

Specifically, for example, it is preferable that after the above extraction treatment is performed using an acidic aqueous solution, the solution phase that is extracted and recovered from the aqueous solution and that contains the polymer and the solvents is further subjected to extraction treatment with water. The extraction treatment with water is not particularly limited, and can be performed, for example, by thoroughly mixing the solution phase and water by stirring or the like and then leaving the obtained mixed solution to stand still. The mixed solution after being left to stand still is separated into a solution phase containing the polymer and the solvents and an aqueous phase, and thus the solution phase can be recovered by decantation and the like.

Water used herein is preferably water, the metal content of which is small, such as ion exchanged water, according to the purpose of the present embodiment. While the extraction treatment may be performed once, it is effective to repeat mixing, leaving-to-stand-still, and separating operations multiple times. In addition, the proportions of both used in the extraction treatment, and temperature, time and other conditions are not particularly limited, and may be the same as those of the previous contact treatment with the acidic aqueous solution.

Water that is possibly present in the thus-obtained solution containing the polymer and the solvents can be easily removed by performing vacuum distillation operation or the like. Also, if required, the concentration of the polymer can be regulated to be any concentration by adding a solvent to the solution.

The method for purifying the polymer according to the present embodiment can also be performed by passing a solution obtained by dissolving the polymer in a solvent through a filter.

According to the method for purifying the polymer according to the present embodiment, the content of various metal components in the polymer can be effectively and significantly reduced. The amounts of these metal components can be measured by the method described in Examples below.

Herein, the term “passed through” of the present embodiment means that the above-described solution is passed from the outside of the filter through the inside of the filter and is allowed to move out of the filter again. For example, an aspect in which the solution is simply brought into contact with the surface of the filter and an aspect in which the solution is brought into contact on the surface while being allowed to move outside an ion-exchange resin (that is, an aspect in which the solution is simply brought into contact) are excluded.

### [Filtering Purification Step (Passing Step)]

In the step of passing a liquid through a filter according to the present embodiment, a filter commercially available for liquid filtration can usually be used as the filter used for removing the metal component in the solution containing the polymer and the solvent. The filtration accuracy of the filter is not particularly limited, but the nominal pore size of the filter is preferably 0.2 μm or less, more preferably less than 0.2 μm, still more preferably 0.1 μm or less, even more preferably less than 0.1 μm, and still further preferably 0.05 μm or less. The lower limit of the nominal pore size of the filter is not particularly limited, but is usually 0.005 μm. As used herein, the term “nominal pore size” refers to the pore size nominally used to indicate the separation performance of the filter, which is determined, for example, by any method specified by the filter manufacturer, such as a bubble point test, a mercury intrusion test or a standard particle trapping test. When using a commercially available product, the nominal pore size is a value described in the manufacturer's catalog data. The nominal pore size of 0.2 μm or less makes it possible to effectively reduce the contents of the metal components after passing the solution through the filter once. In the present embodiment, the step of passing a liquid through a filter may be performed twice or more to reduce the more content of each metal component in the solution.

Forms of the filter to be used can include a hollow fiber membrane filter, a membrane filter, a pleated membrane filter, and a filter filled with a filter medium such as a non-woven fabric, cellulose or diatomaceous earth. Among the above, the filter is preferably one or more selected from the group consisting of a hollow fiber membrane filter, a membrane filter and a pleated membrane filter. Further, it is particularly preferable to use a hollow fiber membrane filter, in particular due to its high precision filtration accuracy and its higher filtration area than other forms.

Examples of a material for the filter can include a polyolefin such as polyethylene and polypropylene; a polyethylene-based resin having a functional group having an ion exchange capacity provided by graft polymerization; a polar group-containing resin such as polyamide, polyester and polyacrylonitrile; and a fluorine-containing resin such as fluorinated polyethylene (PTFE). Among the above, the filter is preferably made of one or more filter media selected from the group consisting of a polyamide, a polyolefin resin and a fluororesin. Further, a polyamide medium is particularly preferable from the viewpoint of the reduction effect of heavy metals such as chromium. From the viewpoint of avoiding metal elution from the filter medium, it is preferable to use a filter other than the sintered metal material.

Examples of the polyamide-based filter can include (hereinafter, registered trademark), but are not limited to: Polyfix nylon series manufactured by KITZ MICROFILTER CORPORATION; Ultipleat P-Nylon 66 and Ultipor N66 manufactured by Nihon Pall Ltd.; and LifeASSURE PSN series and LifeASSURE EF series manufactured by 3M Company.

Examples of polyolefin-based filter can include, but are not limited to: Ultipleat PE Clean and Ion Clean manufactured by Nihon Pall Ltd.; Protego series, Microgard Plus HC10 and Optimizer D manufactured by Entegris Japan Co., Ltd.

Examples of the polyester-based filter can include, but are not limited to: Geraflow DFE manufactured by Central Filter Mfg. Co., Ltd.; and a pleated type PMC manufactured by Nihon Filter Co., Ltd.

Examples of the polyacrylonitrile-based filter can include, but are not limited to: Ultrafilters AIP-0013D, ACP-0013D and ACP-0053D manufactured by Advantec Toyo Kaisha, Ltd.

Examples of the fluororesin-based filter can include, but are not limited to: Emflon HTPFR manufactured by Nihon Pall Ltd.; and LifeASSURE FA series manufactured by 3M Company.

These filters can be used alone or can be used in combination of two or more thereof.

The filter may also contain an ion exchanger such as a cation-exchange resin, or a cation charge controlling agent and the like that causes a zeta potential in an organic solvent solution to be filtered.

Examples of the filter containing an ion exchanger can include, but are not limited to: Protego series manufactured by Entegris Japan Co., Ltd.; and KURANGRAFT manufactured by Kurashiki Textile Manufacturing Co., Ltd.

Examples of the filter containing a material having a positive zeta potential such as a cationic polyamidepolyamine-epichlorohydrin resin include (hereinafter, registered trademark), but are not limited to: Zeta Plus 40QSH and Zeta Plus 020GN and LifeASSURE EF series manufactured by 3M company.

The method for isolating the polymer from the obtained solution containing the polymer and the solvents is not particularly limited, and publicly known methods can be performed, such as reduced-pressure removal, separation by reprecipitation, and a combination thereof. Publicly known treatments such as concentration operation, filtration operation, centrifugation operation, and drying operation can be performed if required.

### [Composition for Film Formation]

The composition of the present embodiment can be used for film formation. That is, since the composition for film formation of the present embodiment contains the polymer of the present embodiment, it can exhibit excellent heat resistance and etching resistance.

The “film” as used herein refers to a film that can be applied to, for example, a film for lithography, an optical member, and the like (but not limited thereto), and the size and shape thereof are not particularly limited, and typically, the film has a general form as a film for lithography or an optical member. That is, the “composition for film formation” refers to a precursor of such a film, and is clearly distinguished from the “film” in its form and/or composition. Further, the “lithography film” is a concept that broadly includes a film for lithography applications such as a permanent film for resist and an underlayer film for lithography.

### [Application of Composition for Film Formation]

The composition for film formation of the present embodiment contains the above polymer, but may have various compositions depending on the specific application thereof, and hereinafter, the composition for film formation may be referred to as a “resist composition”, a “radiation-sensitive composition”, or a “composition for underlayer film formation for lithography” depending on the application or composition thereof.

### [Resist Composition]

A resist composition of the present embodiment comprises the composition for film formation of the present embodiment. That is, the resist composition of the present embodiment contains the polymer according to the present embodiment as an essential component, and may further contain any of various optional components in consideration of use as a resist material. Specifically, the resist composition of the present embodiment preferably further contains at least one selected from the group consisting of a solvent, an acid generating agent, a base generating agent, and an acid diffusion controlling agent.

### (Solvent)

Further, the solvent that the resist composition of the present embodiment may contain is not particularly limited, and any of various known organic solvents can be used. For example, those described in International Publication No. WO 2013/024778 can be used. These solvents can be used alone or can be used in combination of two or more kinds.

The solvent used in the present embodiment is preferably a safe solvent, more preferably at least one selected from propylene glycol monomethyl ether acetate (PGMEA), propylene glycol monomethyl ether (PGME), cyclohexanone (CHN), cyclopentanone (CPN), 2-heptanone, anisole, butyl acetate, ethyl propionate, and ethyl lactate, and still more preferably at least one selected from PGMEA, PGME, and CHN.

The amount of the solid component (component other than the solvent in the resist composition of the present embodiment) and the amount of the solvent in the present embodiment is not particularly limited, but preferably the solid component is 1 to 80 parts by mass and the solvent is 20 to 99 parts by mass, more preferably the solid component is 1 to 50 parts by mass and the solvent is 50 to 99 parts by mass, still more preferably the solid component is 2 to 40 parts by mass and the solvent is 60 to 98 parts by mass, and particularly preferably the solid component is 2 to 10 parts by mass and the solvent is 90 to 98 parts by mass, based on 100 parts by mass of the total mass of the amount of the solid component and the solvent.

### (Acid Generating Agent (C))

The resist composition of the present embodiment preferably contains one or more acid generating agents (C) generating an acid directly or indirectly by irradiation of any radiation selected from visible light, ultraviolet, excimer laser, electron beam, extreme ultraviolet (EUV), X-ray, and ion beam. The acid generating agent (C) is not particularly limited, and, for example, an acid generating agent described in International Publication No. WO 2013/024778 can be used. The acid generating agent (C) can be used alone or can be used in combination of two or more kinds.

The amount of the acid generating agent (C) used is preferably 0.001 to 49% by mass of the total mass of the solid component, more preferably 1 to 40% by mass, still more preferably 3 to 30% by mass, and particularly preferably 10 to 25% by mass. By using the acid generating agent (C) within the above range, a pattern profile with high sensitivity and low edge roughness is obtained. In the present embodiment, the acid generation method is not limited as long as an acid is generated in the system. By using excimer laser instead of ultraviolet such as g-ray and i-ray, finer processing is possible, and also by using electron beam, extreme ultraviolet, X-ray or ion beam as a high energy ray, further finer processing is possible.

### (Base Generating Agent (B))

The case where the base generating agent (B) is a photobase generating agent will be described.

The photobase generating agent generates a base upon exposure and does not exhibit activity under normal conditions at normal temperature and pressure, but is not particularly limited as long as the photobase generating agent generates a base (basic substance) upon irradiation with an electromagnetic wave and heating as an external stimulus.

The photobase generating agent which can be used in the present invention is not particularly limited, and a publicly known one can be used, and examples thereof include, for example, a carbamate derivative, an amide derivative, an imide derivative, an a-cobalt complex, an imidazole derivative, a cinnamic acid amide derivative, and an oxime derivative.

The basic substance generated from the photobase generating agent is not particularly limited, and examples thereof include compounds having an amino group, particularly monoamines, polyamines such as diamines, and amidines.

The basic substance to be generated is preferably a compound having an amino group with a higher basicity (a higher pKa value of the conjugate acid) from the viewpoint of sensitivity and resolution.

Examples of the photobase generating agent include, for example, photobase generating agents having a cinnamic amide structure as disclosed in Japanese Patent Laid-Open No. 2009/80452 and International Publication NO. WO 2009/123122; base generating agents having a carbamate structure as disclosed in Japanese Patent Laid-Open No. 2006/189591 and Japanese Patent Laid-Open No. 2008/247747; base generating agents having an oxime structure or a carbamoyloxime structure as disclosed in Japanese Patent Laid-Open No. 2007/249013 and Japanese Patent Laid-Open No. 2008/003581; and compounds described in Japanese Patent Laid-Open No. 2010/243773, but these are not limited thereto, and other known structures of base generating agents can be used.

The photobase generating agent can be used alone or in combination of two or more kinds.

The preferred content of the photobase generating agent in actinic ray or radiation sensitive resin composition is similar to the preferred content of the aforementioned photoacid generating agent in actinic ray or radiation sensitive resin composition.

### (Acid Crosslinking Agent (G))

The resist composition in the present embodiment may contain one or more acid crosslinking agents (G). The acid crosslinking agent (G) is a compound capable of intramolecularly or intermolecularly crosslinking the polymer of the present embodiment (component (A)) in the presence of the acid generated from the acid generating agent (C). Examples of such an acid crosslinking agent (G) can include a compound having one or more groups (hereinafter, referred to as a “crosslinkable group”) capable of crosslinking the component (A).

Examples of such a crosslinkable group can include, but are not particularly limited to, (i) a hydroxyalkyl group such as a hydroxy (C1-C6 alkyl group), a C1-C6 alkoxy (C1-C6 alkyl group), and an acetoxy (C1-C6 alkyl group), or a group derived therefrom; (ii) a carbonyl group such as a formyl group and a carboxy (C1-C6 alkyl group), or a group derived therefrom; (iii) a nitrogenous group-containing group such as a dimethylaminomethyl group, a diethylaminomethyl group, a dimethylolaminomethyl group, a diethylolaminomethyl group, and a morpholinomethyl group; (iv) a glycidyl group-containing group such as a glycidyl ether group, a glycidyl ester group, and a glycidylamino group; (v) a group derived from an aromatic group such as a C1-C6 allyloxy (C1-C6 alkyl group) and a C1-C6 aralkyloxy (C1-C6 alkyl group) such as a benzyloxymethyl group and a benzoyloxymethyl group; and (vi) a polymerizable multiple bond-containing group such as a vinyl group and an isopropenyl group. As the crosslinkable group of the acid crosslinking agent (G) according to the present embodiment, a hydroxyalkyl group and an alkoxyalkyl group or the like are preferable, and an alkoxymethyl group is particularly preferable.

The acid crosslinking agent (G) having the above crosslinkable group is not particularly limited, and, for example, an acid crosslinking agent described in International Publication No. WO 2013/024778 can be used. The acid crosslinking agent (G) can be used alone or can be used in combination of two or more kinds.

In the present embodiment, the amount of the acid crosslinking agent (G) used is preferably 0.5 to 49% by mass of the total mass of the solid components, more preferably 0.5 to 40% by mass, still more preferably 1 to 30% by mass, and particularly preferably 2 to 20% by mass. When the content ratio of the acid crosslinking agent (G) is 0.5% by mass or more, the inhibiting effect of the solubility of a resist film in an alkaline developing solution is improved, and a decrease in the film remaining rate, and occurrence of swelling and meandering of a pattern can be inhibited, which is preferable. On the other hand, when the content ratio is 50% by mass or less, a decrease in heat resistance as a resist can be inhibited, which is preferable.

### (Acid Diffusion Controlling Agent (E))

In the present embodiment, the resist composition may contain an acid diffusion controlling agent (E) having a function of controlling diffusion of an acid generated from an acid generating agent by radiation irradiation in a resist film to inhibit any unpreferable chemical reaction in an unexposed region or the like. By using such an acid diffusion controlling agent (E), the storage stability of a resist composition is improved. Also, along with improvement of the resolution, the line width change of a resist pattern due to variation in the post exposure delay time before radiation irradiation and the post exposure delay time after radiation irradiation can be inhibited, making the composition extremely excellent in process stability. Such an acid diffusion controlling agent (E) is not particularly limited, and examples thereof include a radiation degradable basic compound such as a nitrogen atom-containing basic compound, a basic sulfonium compound, and a basic iodonium compound.

The acid diffusion controlling agent (E) is not particularly limited, and, for example, an acid diffusion controlling agent described in International Publication No. WO 2013/024778 can be used. The acid diffusion controlling agent (E) can be used alone or can be used in combination of two or more kinds.

The content of the acid diffusion controlling agent (E) is preferably 0.001 to 49% by mass of the total mass of the solid component, more preferably 0.01 to 10% by mass, still more preferably 0.01 to 5% by mass, and particularly preferably 0.01 to 3% by mass. Within the above range, a decrease in resolution, and deterioration of the pattern shape and the dimension fidelity or the like can be prevented. Moreover, even though the post exposure delay time from electron beam irradiation to heating after radiation irradiation becomes longer, the shape of the pattern upper layer portion does not deteriorate. When the content is 10% by mass or less, a decrease in sensitivity, and developability of the unexposed portion or the like can be prevented. Also, by using such an acid diffusion controlling agent, the storage stability of a resist composition is improved, also along with improvement of the resolution, the line width change of a resist pattern due to variation in the post exposure delay time before radiation irradiation and the post exposure delay time after radiation irradiation can be inhibited, making the composition extremely excellent in process stability.

### (Further Component (F))

To the resist composition of the present embodiment, if required, as the further component (F), one kind or two or more kinds of various additive agents such as a dissolution promoting agent, a dissolution controlling agent, a sensitizing agent, a surfactant, and an organic carboxylic acid or an oxo acid of phosphorus or derivative thereof can be added. Examples of the dissolution promoting agent, the dissolution controlling agent, the sensitizing agent, the surfactant, and organic carboxylic acid or oxo acid of phosphorus, or derivatives thereof include those described in International Publication No. WO 2020/145406.

In the resist composition of the present embodiment, the total content of the optional component (F) is 0 to 99% by mass of the total mass of the solid components, preferably 0 to 49% by mass, more preferably 0 to 10% by mass, still more preferably 0 to 5% by mass, still more preferably 0 to 1% by mass, and particularly preferably 0% by mass.

### [Content Ratio of Each Component in Resist Composition]

In the resist composition of the present embodiment, the content of the polymer according to the present embodiment (the component (A)) is not particularly limited, but is preferably 50 to 99.4% by mass of the total mass of the solid components (summation of solid components including the polymer (A), and optionally used components such as acid generating agent (C) or base generating agent (B), acid crosslinking agent (G), acid diffusion controlling agent (E), and further component (F) (also referred to as “optional component (F)”), hereinafter the same applies to the resist composition.), more preferably 55 to 90% by mass, still more preferably 60 to 80% by mass, and particularly preferably 60 to 70% by mass. In the case of the above content, there is a tendency that resolution is further improved and that line edge roughness (LER) is further decreased.

In the resist composition of the present embodiment, the content ratio of the polymer according to the present embodiment (component (A)), the acid generating agent (C) or the base generating agent (B), the acid crosslinking agent (G), the acid diffusion controlling agent (E), and the optional component (F) (the component (A)/the acid generating agent (C) or the base generating agent (B)/the acid crosslinking agent (G)/the acid diffusion controlling agent (E)/the optional component (F)) is preferably 50 to 99.4% by mass/0.001 to 49% by mass/0.5 to 49% by mass/0.001 to 49% by mass/0 to 49% by mass based on 100% by mass of the solid content of the resist composition, more preferably 55 to 90% by mass/1 to 40% by mass/0.5 to 40% by mass/0.01 to 10% by mass/0 to 5% by mass, still more preferably 60 to 80% by mass/3 to 30% by mass/1 to 30% by mass/0.01 to 5% by mass/0 to 1% by mass, and particularly preferably 60 to 70% by mass/10 to 25% by mass/2 to 20% by mass/0.01 to 3% by mass/0% by mass. The content ratio of each component is selected from each range so that the summation thereof is 100% by mass. Through the above content ratio, there is a tendency that performance such as sensitivity, resolution and developability is excellent. The “solid content” refers to components except for the solvent. “100% by mass of the solid content” refer to 100% by mass of the components except for the solvent.

The resist composition of the present embodiment is usually prepared by dissolving each component in a solvent upon use into a homogeneous solution, and then if required, filtering through a filter or the like with a pore diameter of about 0.2 μm, for example.

The resist composition of the present embodiment can contain an additional resin other than the polymer according to the present embodiment, if required. Examples of the additional resin include, but are not particularly limited to, a novolac resin, a polyvinyl phenol, a polyacrylic acid, a polyvinyl alcohol, a styrene-maleic anhydride resin, and a polymer containing acrylic acid, vinyl alcohol or vinylphenol as a monomeric unit, and derivatives thereof. The content of the additional resin is not particularly limited and is appropriately adjusted according to the kind of the component (A) to be used, and is preferably 30 parts by mass or less based on 100 parts by mass of the component (A), more preferably 10 parts by mass or less, still more preferably 5 parts by mass or less, and particularly preferably 0 parts by mass.

### [Physical Properties and the Like of Resist Composition]

The resist composition of the present embodiment can form an amorphous film by spin coating. Also, the resist composition can be applied to a general semiconductor production process. Any of positive type and negative type resist patterns can be individually prepared depending on the kind of a developing solution to be used.

In the case of a positive type resist pattern, the dissolution rate of the amorphous film formed by spin coating with the resist composition of the present embodiment in a developing solution at 23° C. is preferably 5 angstrom/sec or less, more preferably 0.05 to 5 angstrom/sec, and still more preferably 0.0005 to 5 angstrom/sec. When the dissolution rate is 5 angstrom/sec or less, the above portion is insoluble in a developing solution, and thus the amorphous film can form a resist. When the amorphous film has a dissolution rate of 0.0005 angstrom/sec or more, the resolution may improve. It is presumed that this is because due to the change in the solubility before and after exposure of the component (A), contrast at the interface between the exposed portion being dissolved in a developing solution and the unexposed portion not being dissolved in a developing solution is increased. Also, there are effects of reducing LER and defects.

In the case of a negative type resist pattern, the dissolution rate of the amorphous film formed by spin coating with the resist composition of the present embodiment in a developing solution at 23° C. is preferably 10 angstrom/sec or more. When the dissolution rate is 10 angstrom/sec or more, the amorphous film more easily dissolves in a developing solution, and is more suitable for a resist. When the amorphous film has a dissolution rate of 10 angstrom/sec or more, the resolution may improve. It is presumed that this is because the micro surface portion of the component (A) dissolves, and LER is reduced. Also, there are effects of reducing defects.

The above dissolution rate can be determined by immersing the amorphous film in a developing solution for a predetermined period of time at 23° C. and then measuring the film thickness before and after the immersion by a publicly known method such as visual inspection, ellipsometry, or cross-sectional observation with a scanning electron microscope.

In the case of a positive type resist pattern, the dissolution rate of the portion exposed by radiation such as KrF excimer laser, extreme ultraviolet, electron beam or X-ray, of the amorphous film formed by spin coating with the resist composition of the present embodiment, in a developing solution at 23° C. is preferably 10 angstrom/sec or more. When the dissolution rate is 10 angstrom/sec or more, the amorphous film more easily dissolves in a developing solution, and is more suitable for a resist. When the amorphous film has a dissolution rate of 10 angstrom/sec or more, the resolution may improve. It is presumed that this is because the micro surface portion of the component (A) dissolves, and LER is reduced. Also, there are effects of reducing defects.

In the case of a negative type resist pattern, the dissolution rate of the portion exposed by radiation such as KrF excimer laser, extreme ultraviolet, electron beam or X-ray, of the amorphous film formed by spin coating with the resist composition of the present embodiment, in a developing solution at 23° C. is preferably 5 angstrom/sec or less, more preferably 0.05 to 5 angstrom/sec, and still more preferably 0.0005 to 5 angstrom/sec. When the dissolution rate is 5 angstrom/sec or less, the above portion is insoluble in a developing solution, and thus the amorphous film can form a resist. When the amorphous film has a dissolution rate of 0.0005 angstrom/sec or more, the resolution may improve. It is presumed that this is because due to the change in the solubility before and after exposure of the component (A), contrast at the interface between the unexposed portion being dissolved in a developing solution and the exposed portion not being dissolved in a developing solution is increased. Also, there are effects of reducing LER and defects.

### [Radiation-Sensitive Composition]

A radiation-sensitive composition of the present embodiment contains the composition for film formation of the present embodiment, an optically active diazonaphthoquinone compound (B), and a solvent, wherein the content of the solvent is 20 to 99 parts by mass based on 100 parts by mass in total of the radiation-sensitive composition; and the content of components except for the solvent is 1 to 80 parts by mass based on 100 parts by mass in total of the radiation-sensitive composition. That is, the radiation-sensitive composition of the present embodiment may contain the polymer according to the present embodiment, the optically active diazonaphthoquinone compound (B), and a solvent as essential components, and may further contain any of various optional components in consideration of being radiation-sensitive.

The radiation-sensitive composition of the present embodiment contains the polymer (component (A)) and is used in combination with the optically active diazonaphthoquinone compound (B) and is useful as a base material for positive type resists that becomes a compound easily soluble in a developing solution by irradiation with g-ray, h-ray, i-ray, KrF excimer laser, ArF excimer laser, extreme ultraviolet, electron beam, or X-ray. Although the properties of the component (A) are not largely altered by g-ray, h-ray, i-ray, KrF excimer laser, ArF excimer laser, extreme ultraviolet, electron beam, or X-ray, the optically active diazonaphthoquinone compound (B) poorly soluble in a developing solution is converted to an easily soluble compound so that a resist pattern can be formed in a development step.

The glass transition temperature of the polymer of the present embodiment (component (A)) to be contained in the radiation-sensitive composition of the present embodiment is preferably 100° C. or higher, more preferably 120° C. or higher, still more preferably 140° C. or higher, and particularly preferably 150° C. or higher. The upper limit of the glass transition temperature of the component (A) is not particularly limited and is, for example, 600° C. When the glass transition temperature of the component (A) falls within the above range, there is a tendency that the resulting radiation-sensitive composition has heat resistance capable of maintaining a pattern shape in a semiconductor lithography process, and improves performance such as high resolution.

The heat of crystallization determined by the differential scanning calorimetry of the glass transition temperature of the component (A) to be contained in the radiation-sensitive composition of the present embodiment is preferably less than 20 J/g. Also, (Crystallization temperature)−(Glass transition temperature) is preferably 70° C. or more, more preferably 80° C. or more, still more preferably 100° C. or more, and particularly preferably 130° C. or more. When the heat of crystallization is less than 20 J/g or when (Crystallization temperature)−(Glass transition temperature) falls within the above range, there is a tendency that the radiation-sensitive composition easily forms an amorphous film by spin coating, can maintain film formability necessary for a resist over a long period, and can improve resolution.

In the present embodiment, the above heat of crystallization, crystallization temperature, and glass transition temperature can be determined by differential scanning calorimetry using “DSC/TA-50WS” manufactured by Shimadzu Corp. For example, about 10 mg of a sample is placed in an unsealed container made of aluminum, and the temperature is raised to the melting point or more at a temperature increase rate of 20° C./min in a nitrogen gas stream (50 mL/min). After quenching, again the temperature is raised to the melting point or more at a temperature increase rate of 20° C./min in a nitrogen gas stream (30 mL/min). After further quenching, again the temperature is raised to 400° C. at a temperature increase rate of 20° C./min in a nitrogen gas stream (30 mL/min). The temperature at the middle point (where the specific heat is changed into the half) of steps in the baseline shifted in a step-like pattern is defined as the glass transition temperature (Tg). The temperature of the subsequently appearing exothermic peak is defined as the crystallization temperature. The heat is determined from the area of a region surrounded by the exothermic peak and the baseline and defined as the heat of crystallization.

The component (A) to be contained in the radiation-sensitive composition of the present embodiment is preferably low sublimable at 100 or lower, preferably 120° C. or lower, more preferably 130° C. or lower, still more preferably 140° C. or lower, and particularly preferably 150° C. or lower at normal pressure. The low sublimability means that in thermogravimetry, weight reduction upon keeping at a predetermined temperature for 10 minutes is 10% or less, preferably 5% or less, more preferably 3% or less, still more preferably 1% or less, and particularly preferably 0.1% or less. The low sublimability can prevent an exposure apparatus from being contaminated by outgassing upon exposure. In addition, a good pattern shape with low roughness can be obtained.

The component (A) to be contained in the radiation-sensitive composition of the present embodiment dissolves at preferably 1% by mass or more, more preferably 5% by mass or more, and still more preferably 10% by mass or more at 23° C. in a solvent that is selected from propylene glycol monomethyl ether acetate (PGMEA), propylene glycol monomethyl ether (PGME), cyclohexanone (CHN), cyclopentanone (CPN), 2-heptanone, anisole, butyl acetate, ethyl propionate, and ethyl lactate and exhibits the highest ability to dissolve the component (A). Further preferably, the component (A) dissolves at 20% by mass or more at 23° C. in a solvent that is selected from PGMEA, PGME, and CHN and exhibits the highest ability to dissolve the component (A). Particularly preferably, the component (A) dissolves at 20% by mass or more at 23° C. in PGMEA. When the above conditions are met, the radiation-sensitive composition can be used in a semiconductor production process at a full production scale.

### (Optically Active Diazonaphthoquinone Compound (B))

The optically active diazonaphthoquinone compound (B) to be contained in the radiation-sensitive composition of the present embodiment is a diazonaphthoquinone substance including a polymer or non-polymer optically active diazonaphthoquinone compound and is not particularly limited as long as it is generally used as a photosensitive component (sensitizing agent) in positive type resist compositions. One kind or two or more kinds can be optionally selected and used.

Such a sensitizing agent is preferably a compound obtained by reacting naphthoquinonediazide sulfonic acid chloride, benzoquinonediazide sulfonic acid chloride, or the like with a low molecular weight compound or a high molecular weight compound having a functional group condensable with these acid chlorides. Here, examples of the functional group condensable with the acid chlorides include, but are not particularly limited to, a hydroxy group and an amino group. Particularly, a hydroxy group is suitable. Examples of the compound containing a hydroxy group condensable with the acid chlorides can include, but are not particularly limited to, hydroquinone; resorcin; hydroxybenzophenones such as 2,4-dihydroxybenzophenone, 2,3,4-trihydroxybenzophenone, 2,4,6-trihydroxybenzophenone, 2,4,4′-trihydroxybenzophenone, 2,3,4,4′-tetrahydroxybenzophenone, 2,2′,4,4′-tetrahydroxybenzophenone, and 2,2′,3,4,6′-pentahydroxybenzophenone; hydroxyphenylalkanes such as bis(2,4-dihydroxyphenyl)methane, bis(2,3,4-trihydroxyphenyl)methane, and bis(2,4-dihydroxyphenyl)propane; and hydroxytriphenylmethanes such as 4,4′,3″,4″-tetrahydroxy-3,5,3′,5′-tetramethyltriphenylmethane and 4,4′,2″,3″,4″-pentahydroxy-3,5,3′,5′-tetramethyltriphenylmethane.

Also, preferable examples of the acid chloride such as naphthoquinonediazide sulfonic acid chloride or benzoquinonediazide sulfonic acid chloride include 1,2-naphthoquinonediazide-5-sulfonyl chloride and 1,2-naphthoquinonediazide-4-sulfonyl chloride.

The radiation-sensitive composition of the present embodiment is preferably prepared by, for example, dissolving each component in a solvent upon use into a homogeneous solution, and then if required, filtering through a filter or the like with a pore diameter of about 0.2 μm, for example.

### (Solvent)

Examples of the solvent that can be used in the radiation-sensitive composition of the present embodiment include, but are not particularly limited to, propylene glycol monomethyl ether acetate, propylene glycol monomethyl ether, cyclohexanone, cyclopentanone, 2-heptanone, anisole, butyl acetate, ethyl propionate, and ethyl lactate. Among them, propylene glycol monomethyl ether acetate, propylene glycol monomethyl ether, or cyclohexanone is preferable. The solvent may be used alone as one kind or may be used in combination of two or more kinds.

The content of the solvent is 20 to 99 parts by mass based on 100 parts by mass in total of the radiation-sensitive composition, preferably 50 to 99 parts by mass, more preferably 60 to 98 parts by mass, and particularly preferably 90 to 98 parts by mass.

The content of components except for the solvent (solid components) is 1 to 80 parts by mass based on 100 parts by mass in total of the radiation-sensitive composition, preferably 1 to 50 parts by mass, more preferably 2 to 40 parts by mass, and particularly preferably 2 to 10 parts by mass.

### [Properties of Radiation-Sensitive Composition]

The radiation-sensitive composition of the present embodiment can form an amorphous film by spin coating. Also, the radiation-sensitive composition of the present embodiment can be applied to a general semiconductor production process. Any of positive type and negative type resist patterns can be individually prepared depending on the kind of a developing solution to be used.

In the case of a positive type resist pattern, the dissolution rate of the amorphous film formed by spin coating with the radiation-sensitive composition of the present embodiment in a developing solution at 23° C. is preferably 5 angstrom/sec or less, more preferably 0.05 to 5 angstrom/sec, and still more preferably 0.0005 to 5 angstrom/sec. When the dissolution rate is 5 angstrom/sec or less, the above portion is insoluble in a developing solution, and thus the amorphous film can form a resist. When the amorphous film has a dissolution rate of 0.0005 angstrom/sec or more, the resolution may improve. It is presumed that this is because due to the change in the solubility before and after exposure of the present embodiment (component (A)), contrast at the interface between the exposed portion being dissolved in a developing solution and the unexposed portion not being dissolved in a developing solution is increased. Also, there are effects of reducing LER and defects.

In the case of a negative type resist pattern, the dissolution rate of the amorphous film formed by spin coating with the radiation-sensitive composition of the present embodiment in a developing solution at 23° C. is preferably 10 angstrom/sec or more. When the dissolution rate is 10 angstrom/sec or more, the amorphous film more easily dissolves in a developing solution, and is more suitable for a resist. In addition, when the amorphous film has a dissolution rate of 10 angstrom/sec or more, the resolution may be improved. It is presumed that this is because the micro surface portion of the component (A) dissolves, and LER is reduced. Also, there are effects of reducing defects.

The above dissolution rate can be determined by immersing the amorphous film in a developing solution for a predetermined period of time at 23° C. and then measuring the film thickness before and after the immersion by a publicly known method such as visual inspection, ellipsometry, or QCM method.

In the case of a positive type resist pattern, the dissolution rate of the exposed portion after irradiation with radiation such as KrF excimer laser, extreme ultraviolet, electron beam or X-ray, or after heating at 20 to 500° C. (preferably 50 to 500° C.), of the amorphous film formed by spin coating with the radiation-sensitive composition of the present embodiment, in a developing solution at 23° C. is preferably 10 angstrom/sec or more, more preferably 10 to 10000 angstrom/sec, and still more preferably 100 to 1000 angstrom/sec. When the dissolution rate is 10 angstrom/sec or more, the amorphous film more easily dissolves in a developing solution, and is more suitable for a resist. When the amorphous film has a dissolution rate of 10000 angstrom/sec or less, the resolution may improve. It is presumed that this is because the micro surface portion of the component (A) dissolves, and LER is reduced. Also, there are effects of reducing defects.

In the case of a negative type resist pattern, the dissolution rate of the exposed portion after irradiation with radiation such as KrF excimer laser, extreme ultraviolet, electron beam or X-ray, or after heating at 20 to 500° C. (preferably 50 to 500° C.), of the amorphous film formed by spin coating with the radiation-sensitive composition of the present embodiment, in a developing solution at 23° C. is preferably 5 angstrom/sec or less, more preferably 0.05 to 5 angstrom/sec, and still more preferably 0.0005 to 5 angstrom/sec. When the dissolution rate is 5 angstrom/sec or less, the above portion is insoluble in a developing solution, and thus the amorphous film can form a resist. When the amorphous film has a dissolution rate of 0.0005 angstrom/sec or more, the resolution may improve. It is presumed that this is because due to the change in the solubility before and after exposure of the component (A), contrast at the interface between the unexposed portion being dissolved in a developing solution and the exposed portion not being dissolved in a developing solution is increased. Also, there are effects of reducing LER and defects.

### (Content Ratio of Each Component in Radiation-Sensitive Composition)

In the radiation-sensitive composition of the present embodiment, the content of the polymer of the present embodiment (component (A)) is preferably 1 to 99% by mass based on the total mass of the solid components (summation of the polymer of the present embodiment, the optically active diazonaphthoquinone compound (B), optionally used solid components such as further component (D), hereinafter the same applies to the radiation-sensitive composition), more preferably 5 to 95% by mass, still more preferably 10 to 90% by mass, and particularly preferably 25 to 75% by mass. When the content of the polymer of the present embodiment falls within the above range, the radiation-sensitive composition of the present embodiment can produce a pattern with high sensitivity and low roughness.

In the radiation-sensitive composition of the present embodiment, the content of the optically active diazonaphthoquinone compound (B) is preferably 1 to 99% by mass, more preferably 5 to 95% by mass, still more preferably 10 to 90% by mass, and particularly preferably 25 to 75% by mass, based on the total mass of the solid components. When the content of the optically active diazonaphthoquinone compound (B) falls within the above range, the radiation-sensitive composition of the present embodiment can produce a pattern with high sensitivity and low roughness.

### (Further Component (D))

To the radiation-sensitive composition of the present embodiment, if required, as a component other than the solvent, the polymer of the present embodiment and the optically active diazonaphthoquinone compound (B), one kind or two or more kinds of various additive agents such as the above acid generating agent, acid crosslinking agent, acid diffusion controlling agent, dissolution promoting agent, dissolution controlling agent, sensitizing agent, surfactant, and organic carboxylic acid or oxo acid of phosphorus or derivative thereof can be added. In the radiation-sensitive composition of the present embodiment, the further component (D) may be referred to as an optional component (D).

The content ratio of the polymer of the present embodiment (component (A)), the optically active diazonaphthoquinone compound (B), and the optional component (D) ((A)/(B)/(D)) is preferably 1 to 99% by mass/99 to 1% by mass/0 to 98% by mass based on 100% by mass of the solid content of the radiation-sensitive composition, more preferably 5 to 95% by mass/95 to 5% by mass/0 to 49% by mass, still more preferably 10 to 90% by mass/90 to 10% by mass/0 to 10% by mass, particularly preferably 20 to 80% by mass/80 to 20% by mass/0 to 5% by mass, and most preferably 25 to 75% by mass/75 to 25% by mass/0% by mass.

The content ratio of each component is selected from each range so that the summation thereof is 100% by mass. When the content ratio of each component falls within the above range, the radiation-sensitive composition of the present embodiment is excellent in performance such as sensitivity and resolution, in addition to roughness.

The radiation-sensitive composition of the present embodiment may contain an additional resin other than the polymer according to the present embodiment. Examples of such an additional resin include a novolac resin, a polyvinyl phenol, a polyacrylic acid, a polyvinyl alcohol, a styrene-maleic anhydride resin, and a polymer containing acrylic acid, vinyl alcohol or vinylphenol as a monomeric unit, and derivatives thereof. The content of additional resins, which is appropriately adjusted according to the kind of the polymer of the present embodiment to be used, is preferably 30 parts by mass or less based on 100 parts by mass of the polymer of the present embodiment, more preferably 10 parts by mass or less, still more preferably 5 parts by mass or less, and particularly preferably 0 parts by mass.

### [Method for Producing Amorphous Film]

The method for producing an amorphous film of the present embodiment comprises the step of forming an amorphous film on a substrate using the radiation-sensitive composition.

### [Resist Pattern Formation Method]

In the present embodiment, the resist pattern can be formed by using the resist composition of the present embodiment or by using the radiation-sensitive composition of the present embodiment. In addition, as described below, a resist pattern can also be formed using compositions for underlayer film formation for lithography of the present embodiment.

### [Resist Pattern Formation Method Using Resist Composition]

A resist pattern formation method using the resist composition of the present embodiment includes the steps of: forming a resist film on a substrate using the above resist composition of the present embodiment; exposing at least a portion of the formed resist film; and developing the exposed resist film, thereby forming a resist pattern. The resist pattern according to the present embodiment can also be formed as an upper layer resist in a multilayer process.

### [Resist Pattern Formation Method Using Radiation-Sensitive Composition]

A resist pattern formation method using the radiation-sensitive composition of the present embodiment includes the steps of: forming a resist film on a substrate using the radiation-sensitive composition; exposing at least a portion of the formed resist film; and developing the exposed resist film, thereby forming a resist pattern. Specifically, the same operation as in the following resist pattern formation method using the resist composition can be performed.

Hereinafter, the conditions for carrying out the resist pattern formation method which can be common between the case of using the resist composition of the present embodiment and the case of using the radiation-sensitive composition of the present embodiment will be described.

Examples of the resist pattern formation method include, but are not particularly limited to, the following method. A resist film is formed by coating a conventionally publicly known substrate with the resist composition of the present embodiment using a coating means such as spin coating, flow casting coating, and roll coating. Examples of the conventionally publicly known substrate can include, but are not particularly limited to, a substrate for electronic components, and the one having a predetermined wiring pattern formed thereon, or the like. More specific examples thereof include, but are not particularly limited to, a silicon wafer, a substrate made of a metal such as copper, chromium, iron and aluminum, and a glass substrate. Examples of the wiring pattern material include, but are not particularly limited to, copper, aluminum, nickel and gold. Also if required, the substrate may be a substrate having an inorganic and/or organic film provided thereon. Examples of the inorganic film include, but are not particularly limited to, an inorganic antireflection film (inorganic BARC). Examples of the organic film include, but are not particularly limited to, an organic antireflection film (organic BARC). The substrate may be subjected to surface treatment with hexamethylene disilazane or the like.

Next, the coated substrate is heated if required. The heating conditions vary according to the compounding composition of the resist composition, or the like, but are preferably 20 to 250° C., and more preferably 20 to 150° C. By heating, the adhesiveness of a resist to a substrate may be improved, which is preferable. Then, the resist film is exposed to a desired pattern by any radiation selected from the group consisting of visible light, ultraviolet, excimer laser, electron beam, extreme ultraviolet (EUV), X-ray, and ion beam. The exposure conditions or the like are appropriately selected according to the compounding composition of the resist composition, or the like. In the present embodiment, in order to stably form a fine pattern with a high degree of accuracy in exposure, the resist film is preferably heated after radiation irradiation.

Then, by developing the exposed resist film in a developing solution, a predetermined resist pattern is formed. As the developing solution, it is preferable to select a solvent having a solubility parameter (SP value) close to that of the component (A) to be used. A polar solvent such as a ketone-based solvent, an ester-based solvent, an alcohol-based solvent, an amide-based solvent and an ether-based solvent; and a hydrocarbon-based solvent, or an alkaline aqueous solution can be used. Examples of the solvent and the alkaline aqueous solution include those described in International Publication No. WO 2013/024778.

A plurality of above solvents may be mixed, or the solvent may be used by mixing the solvent with a solvent other than those described above or water within the range having performance. Here, from the viewpoint of further enhancing the desired effect of the present embodiment, the water content ratio as the whole developing solution is less than 70% by mass, and is preferably less than 50% by mass, more preferably less than 30% by mass, and still more preferably less than 10% by mass. Particularly preferably, the developing solution is substantially moisture free. That is, the content of the organic solvent in the developing solution is preferably 30% by mass or more and 100% by mass or less based on the total amount of the developing solution, preferably 50% by mass or more and 100% by mass or less, more preferably 70% by mass or more and 100% by mass or less, still more preferably 90% by mass or more and 100% by mass or less, and particularly preferably 95% by mass or more and 100% by mass or less.

Particularly, as the developing solution, a developing solution containing at least one kind of solvent selected from a ketone-based solvent, an ester-based solvent, an alcohol-based solvent, an amide-based solvent, and an ether-based solvent is preferable because it improves resist performance such as resolution and roughness of the resist pattern.

To the developing solution, a surfactant can be added in an appropriate amount, if required. The surfactant is not particularly limited, but an ionic or nonionic, fluorine-based and/or silicon-based surfactant or the like can be used, for example. Examples of the fluorine-based and/or silicon-based surfactant may include, for example, the surfactants described in Japanese Patent Laid-Open Nos. 62-36663, 61-226746, 61-226745, 62-170950, 63-34540, 7-230165, 8-62834, 9-54432, and 9-5988, and U.S. Pat. Nos. 5,405,720, 5,360,692, 5,529,881, 5,296,330, 5,436,098, 5,576,143, 5,294,511, and 5,824,451. The surfactant is preferably a nonionic surfactant. The nonionic surfactant is not particularly limited, but it is still more preferable to use a fluorine-based surfactant or a silicon-based surfactant.

The amount of the surfactant used is usually 0.001 to 5% by mass based on the total amount of the developing solution, preferably 0.005 to 2% by mass, and still more preferably 0.01 to 0.5% by mass.

For the development method, without particular limitations, for example, a method for dipping a substrate in a bath filled with a developing solution for a fixed time (dipping method), a method for raising a developing solution on a substrate surface by the effect of a surface tension and keeping it still for a fixed time, thereby conducting the development (puddle method), a method for spraying a developing solution on a substrate surface (spraying method), and a method for continuously ejecting a developing solution on a substrate rotating at a constant speed while scanning a developing solution ejecting nozzle at a constant rate (dynamic dispense method), or the like may be applied. The time for conducting the pattern development is not particularly limited, but is preferably 10 seconds to 90 seconds.

In addition, after the step of conducting the development, a step of stopping the development by the replacement with another solvent may be carried out.

After the development, it is preferable that a step of rinsing the resist film with a rinsing solution containing an organic solvent is included. The step of rinsing using the rinsing solution (rinsing step) is not particularly limited, and for example, the rinsing step described in International Publication No. WO 2020/145406 may be adopted as appropriate.

After forming the resist pattern, a pattern wiring substrate is obtained by etching. Etching can be performed by a publicly known method such as dry etching using plasma gas, and wet etching with an alkaline solution, a cupric chloride solution, a ferric chloride solution or the like.

After forming the resist pattern, plating can also be conducted. Examples of the plating method include copper plating, solder plating, nickel plating, and gold plating.

The remaining resist pattern after etching can be stripped by an organic solvent. Examples of the organic solvent are not particularly limited, and examples include PGMEA (propylene glycol monomethyl ether acetate), PGME (propylene glycol monomethyl ether), and EL (ethyl lactate). Examples of the stripping method include, but are not particularly limited to, a dipping method and a spraying method. In addition, a wiring substrate having a resist pattern formed thereon may be a multilayer wiring substrate, and may have a small diameter through hole.

In the present embodiment, the wiring substrate obtained can also be formed by a method for forming a resist pattern, then depositing a metal in vacuum, and subsequently dissolving the resist pattern in a solution, that is, a liftoff method.

### [Composition for Underlayer Film Formation for Lithography]

The composition for underlayer film formation for lithography of the present embodiment comprises a composition for film formation of the present embodiment. That is, the composition for underlayer film formation for lithography of the present embodiment contains the polymer according to the present embodiment as an essential component, and may further contain any of various optional components in consideration of use as an underlayer film forming material for lithography. Specifically, the composition for underlayer film formation for lithography of the present embodiment preferably further contains at least one selected from the group consisting of a solvent, an acid generating agent, a base generating agent, and a crosslinking agent.

The content of the polymer according to the present embodiment in the composition for underlayer film formation for lithography is preferably 1 to 100% by mass, more preferably 10 to 100% by mass, still more preferably 50 to 100% by mass, particularly preferably 100% by mass based on the total solid content, from the viewpoint of coatability and quality stability.

When the composition for underlayer film formation for lithography of the present embodiment comprises a solvent, the content of the polymer according to the present embodiment is not particularly limited, but is preferably 1 to 40 parts by mass based on 100 parts by mass in total including the solvent, more preferably 2 to 37.5 parts by mass, and still more preferably 3 to 35 parts by mass.

The composition for underlayer film formation for lithography of the present embodiment is applicable to a wet process and is excellent in heat resistance and etching resistance. Furthermore, the composition for underlayer film formation for lithography of the present embodiment contains the polymer according to the present embodiment and can therefore form an underlayer film that is prevented from deteriorating upon baking at a high temperature and is also excellent in etching resistance against oxygen plasma etching or the like. Moreover, the composition for underlayer film formation for lithography of the present embodiment is also excellent in adhesiveness to a resist layer and can therefore obtain an excellent resist pattern. The composition for underlayer film formation for lithography of the present embodiment may contain an already known underlayer film forming material for lithography or the like, within the range not deteriorating the desired effect of the present embodiment.

### (Solvent)

A publicly known solvent can be appropriately used as the solvent used in the composition for underlayer film formation for lithography of the present embodiment as long as at least the polymer of the present embodiment dissolves.

Specific examples of the solvent include, but are not particularly limited to, solvents described in International Publication No. WO 2013/024779. These solvents can be used alone as one kind, or can be used in combination of two or more kinds.

Among the solvents, cyclohexanone, propylene glycol monomethyl ether, propylene glycol monomethyl ether acetate, ethyl lactate, methyl hydroxyisobutyrate, or anisole is particularly preferable from the viewpoint of safety.

The content of the solvent is not particularly limited and is preferably 100 to 10,000 parts by mass based on 100 parts by mass of the polymer according to the present embodiment, more preferably 200 to 5,000 parts by mass, and still more preferably 200 to 1,000 parts by mass, from the viewpoint of solubility and film formation.

### (Crosslinking Agent)

The composition for underlayer film formation for lithography of the present embodiment may contain a crosslinking agent, if required, from the viewpoint of, for example, suppressing intermixing. The crosslinking agent that may be used in the present embodiment is not particularly limited, but a crosslinking agent described in, for example, International Publication No. WO 2013/024778, International Publication No. WO 2013/024779, or International Publication No. WO 2018/016614 can be used. In the present embodiment, the crosslinking agent can be used alone or can be used in combination of two or more kinds.

Specific examples of the crosslinking agent that may be used in the present embodiment include, but not particularly limited to, phenol compounds, epoxy compounds, cyanate compounds, amino compounds, benzoxazine compounds, acrylate compounds, melamine compounds, guanamine compounds, glycoluril compounds, urea compounds, isocyanate compounds, and azide compounds. These crosslinking agents can be used alone as one kind or can be used in combination of two or more kinds. Among these, a benzoxazine compound, an epoxy compound, or a cyanate compound is preferable, and a benzoxazine compound is more preferable from the viewpoint of improvement in etching resistance. Further, a melamine compound and a urea compound are more preferable in view of obtaining good reactivity. For example, the crosslinking agent described in PCT/JP2021/26669 can be used as appropriate as the crosslinking agent.

In the composition for underlayer film formation for lithography of the present embodiment, the content of the crosslinking agent is not particularly limited, but is preferably 5 to 50 parts by mass, and more preferably 10 to 40 parts by mass based on 100 parts by mass of the polymer according to the present embodiment. By setting the content of the crosslinking agent to the above preferable range, occurrence of a mixing event with a resist layer tends to be prevented. Also, an antireflection effect is enhanced, and film formability after crosslinking tends to be enhanced.

### (Crosslinking Promoting Agent)

In the composition for underlayer film formation for lithography of the present embodiment, if required, a crosslinking promoting agent for accelerating crosslinking and curing reaction can be used.

The crosslinking promoting agent is not particularly limited as long as it accelerates crosslinking or curing reaction, and examples thereof include amines, imidazoles, organic phosphines, and Lewis acids. These crosslinking promoting agents can be used alone as one kind or can be used in combination of two or more kinds. Among these, an imidazole or an organic phosphine is preferable, and an imidazole is more preferable from the viewpoint of decrease in crosslinking temperature.

As the crosslinking promoting agent, a known crosslinking promoting agent can be used, and it is not particularly limited, and examples thereof include those described in International Publication No. WO 2018/016614. From the viewpoint of heat resistance and acceleration of curing, 2-methylimidazole, 2-phenylimidazole, and 2-ethyl-4-methylimidazole are particularly preferable.

The content of the crosslinking promoting agent is usually preferably 0.1 to 10 parts by mass based on 100 parts by mass of the total mass of the composition, and is more preferably 0.1 to 5 parts by mass, and still more preferably 0.1 to 3 parts by mass, from the viewpoint of easy control and cost efficiency.

### (Radical Polymerization Initiator)

The composition for underlayer film formation for lithography of the present embodiment can contain, if required, a radical polymerization initiator. The radical polymerization initiator may be a photopolymerization initiator that initiates radical polymerization by light, or may be a thermal polymerization initiator that initiates radical polymerization by heat. The radical polymerization initiator can be at least one selected from the group consisting of a ketone-based photopolymerization initiator, an organic peroxide-based polymerization initiator and an azo-based polymerization initiator.

Such a radical polymerization initiator is not particularly limited, and a radical polymerization initiator conventionally used can be appropriately adopted. For example, examples thereof include those described in International Publication No. WO 2018/016614. Among these, dicumyl peroxide, 2,5-dimethyl-2,5-bis(t-butylperoxy)hexane, and t-butylcumyl peroxide are particularly preferable from the viewpoint of availability of raw materials and storage stability.

As the radical polymerization initiator used for the present embodiment, one kind thereof may be used alone, or two or more kinds may be used in combination. Alternatively, the radical polymerization initiator according to the present embodiment may be used in further combination with an additional publicly known polymerization initiator.

### (Acid Generating Agent)

The composition for underlayer film formation for lithography of the present embodiment may contain an acid generating agent, if required, from the viewpoint of, for example, further accelerating crosslinking reaction by heat. An acid generating agent that generates an acid by thermal decomposition, an acid generating agent that generates an acid by light irradiation, and the like are known, any of which can be used.

The acid generating agent is not particularly limited, and, for example, an acid generating agent described in International Publication No. WO 2013/024779 can be used. In the present embodiment, the acid generating agent can be used alone or can be used in combination of two or more kinds.

In the composition for underlayer film formation for lithography of the present embodiment, the content of the acid generating agent is not particularly limited, but is preferably 0.1 to 50 parts by mass, and more preferably 0.5 to 40 parts by mass based on 100 parts by mass of the polymer according to the present embodiment. By setting the content of the acid generating agent to the above preferable range, crosslinking reaction tends to be enhanced by an increased amount of an acid generated. Also, occurrence of a mixing event with a resist layer tends to be prevented.

### (Base Generating Agent)

The case where the base generating agent is a photobase generating agent will be described.

The photobase generating agent generates a base upon exposure and does not exhibit activity under normal conditions at normal temperature and pressure, but is not particularly limited as long as the photobase generating agent generates a base (basic substance) upon irradiation with an electromagnetic wave and heating as an external stimulus.

The photobase generating agent which can be used in the present invention is not particularly limited, and a publicly known one can be used, and examples thereof include, for example, a carbamate derivative, an amide derivative, an imide derivative, an a-cobalt complex, an imidazole derivative, a cinnamic acid amide derivative, and an oxime derivative.

The basic substance generated from the photobase generating agent is not particularly limited, and examples thereof include compounds having an amino group, particularly monoamines, polyamines such as diamines, and amidines.

The basic substance to be generated is preferably a compound having an amino group with a higher basicity (a higher pKa value of the conjugate acid) from the viewpoint of sensitivity and resolution.

Examples of the photobase generating agent include, for example, photobase generating agents having a cinnamic amide structure as disclosed in Japanese Patent Laid-Open No. 2009/80452 and International Publication NO. WO 2009/123122; base generating agents having a carbamate structure as disclosed in Japanese Patent Laid-Open No. 2006/189591 and Japanese Patent Laid-Open No. 2008/247747; base generating agents having an oxime structure or a carbamoyloxime structure as disclosed in Japanese Patent Laid-Open No. 2007/249013 and Japanese Patent Laid-Open No. 2008/003581; and compounds described in Japanese Patent Laid-Open No. 2010/243773, but these are not limited thereto, and other known structures of base generating agents can be used.

The photobase generating agent can be used alone or in combination of two or more kinds.

The preferred content of the photobase generating agent in actinic ray or radiation sensitive resin composition is similar to the preferred content of the aforementioned photoacid generating agent in actinic ray or radiation sensitive resin composition.

### (Basic Compound)

The composition for underlayer film formation for lithography of the present embodiment may further contain a basic compound from the viewpoint of, for example, improving storage stability.

The basic compound plays a role as a quencher against acids in order to prevent crosslinking reaction from proceeding due to a trace amount of an acid generated by the acid generating agent. Examples of such a basic compound include, but are not particularly limited to, primary, secondary or tertiary aliphatic amines, amine blends, aromatic amines, heterocyclic amines, nitrogen-containing compounds having a carboxy group, nitrogen-containing compounds having a sulfonyl group, nitrogen-containing compounds having a hydroxy group, nitrogen-containing compounds having a hydroxyphenyl group, alcoholic nitrogen-containing compounds, amide derivatives, and imide derivatives.

The basic compound used in the present embodiment is not particularly limited, and, for example, a basic compound described in International Publication No. WO 2013/024779 can be used. In the present embodiment, the basic compound can be used alone or can be used in combination of two or more kinds.

In the composition for underlayer film formation for lithography of the present embodiment, the content of the basic compound is not particularly limited, but is preferably 0.001 to 2 parts by mass, and more preferably 0.01 to 1 parts by mass based on 100 parts by mass of the polymer according to the present embodiment. By setting the content of the basic compound to the above preferable range, storage stability tends to be enhanced without excessively deteriorating crosslinking reaction.

### (Further Additive Agent)

The composition for underlayer film formation for lithography of the present embodiment may also contain an additional resin and/or compound for the purpose of conferring thermosetting properties or controlling absorbance. Examples of such an additional resin and/or compound include, but are not particularly limited to, a naphthol resin, a xylene resin, a naphthol-modified resin, a phenol-modified resin of a naphthalene resin; a polyhydroxystyrene, a dicyclopentadiene resin, a resin containing (meth)acrylate, dimethacrylate, trimethacrylate, tetramethacrylate, a naphthalene ring such as vinylnaphthalene or polyacenaphthylene, a biphenyl ring such as phenanthrenequinone or fluorene, or a heterocyclic ring having a heteroatom such as thiophene or indene, and a resin not containing an aromatic ring; and a resin or compound containing an alicyclic structure, such as a rosin-based resin, a cyclodextrin, an adamantine (poly)ol, a tricyclodecane (poly)ol, and a derivative thereof. The composition for underlayer film formation for lithography of the present embodiment may further contain a publicly known additive agent. Examples of the publicly known additive agent include, but are not limited to, ultraviolet absorbers, surfactants, colorants, and nonionic surfactants.

### [Underlayer Film for Lithography Formation Method]

The method for forming an underlayer film for lithography according to the present embodiment (production method) includes the step of forming an underlayer film on a substrate using the composition for underlayer film formation for lithography of the present embodiment.

### [Resist Pattern Formation Method Using Composition for Underlayer Film Formation for Lithography]

A resist pattern formation method using the composition for underlayer film formation for lithography of the present embodiment has the steps of: forming an underlayer film on a substrate using the composition for underlayer film formation for lithography of the present embodiment (step (A-1)); and forming at least one photoresist layer on the underlayer film (step (A-2)). The resist pattern formation method may further include irradiating a predetermined region of the photoresist layer with radiation for development, thereby forming a resist pattern (step (A-3)).

### [Circuit Pattern Formation Method Using Composition for Underlayer Film Formation for Lithography]

A circuit pattern formation method using the composition for underlayer film formation for lithography of the present embodiment has the steps of: forming an underlayer film on a substrate using the composition for underlayer film formation for lithography of the present embodiment (step (B-1)); forming an intermediate layer film on the underlayer film using a resist intermediate layer film material containing a silicon atom (step (B-2)); forming at least one photoresist layer on the intermediate layer film (step (B-3)); after the step (B-3), irradiating a predetermined region of the photoresist layer with radiation for development, thereby forming a resist pattern (step (B-4)); after the step (B-4), etching the intermediate layer film with the resist pattern as a mask, thereby forming an intermediate layer film pattern (step (B-5)); etching the underlayer film with the obtained intermediate layer film pattern as an etching mask, thereby forming an underlayer film pattern (step (B-6)); and etching the substrate with the obtained underlayer film pattern as an etching mask, thereby forming a pattern on the substrate (step (B-7)).

The underlayer film for lithography of the present embodiment is not particularly limited by its formation method as long as it is formed from the composition for underlayer film formation for lithography of the present embodiment. A publicly known approach can be applied thereto. The underlayer film can be formed by, for example, applying the composition for underlayer film formation for lithography of the present embodiment onto a substrate by a publicly known coating method or printing method such as spin coating or screen printing, and then removing an organic solvent by volatilization or the like.

It is preferable to perform baking in the formation of the underlayer film, for preventing occurrence of a mixing event with an upper layer resist while accelerating crosslinking reaction. In this case, the baking temperature is not particularly limited and is preferably in the range of 80 to 450° C., and more preferably 200 to 400° C. The baking time is not particularly limited and is preferably in the range of 10 to 300 seconds. The thickness of the underlayer film can be appropriately selected according to required performance and is not particularly limited, but is usually preferably about 30 to 20,000 nm, and more preferably 50 to 15,000 nm.

After preparing the underlayer film, it is preferable to prepare a silicon-containing resist layer or a usual single-layer resist containing hydrocarbon thereon in the case of a two-layer process, and to prepare a silicon-containing intermediate layer thereon and further a silicon-free single-layer resist layer thereon in the case of a three-layer process. In this case, a publicly known photoresist material can be used for forming this resist layer.

After preparing the underlayer film on the substrate, a silicon-containing resist layer or a usual single-layer resist containing hydrocarbon thereon can be prepared on the underlayer film in the case of a two-layer process. In the case of a three-layer process, a silicon-containing intermediate layer can be prepared on the underlayer film, and a silicon-free single-layer resist layer can be further prepared on the silicon-containing intermediate layer. In these cases, a publicly known photoresist material can be appropriately selected and used for forming the resist layer, without particular limitations.

For the silicon-containing resist material for a two-layer process, a silicon atom-containing polymer such as a polysilsesquioxane derivative or a vinylsilane derivative is used as a base polymer, and a positive type photoresist material further containing an organic solvent, an acid generating agent, and if required, a basic compound or the like is preferably used, from the viewpoint of oxygen gas etching resistance. Here, a publicly known polymer that is used in this kind of resist material can be used as the silicon atom-containing polymer.

A polysilsesquioxane-based intermediate layer is preferably used as the silicon-containing intermediate layer for a three-layer process. By imparting effects as an antireflection film to the intermediate layer, there is a tendency that reflection can be effectively suppressed. For example, use of a material containing a large amount of an aromatic group and having high substrate etching resistance as the underlayer film in a process for exposure at 193 nm tends to increase a k value and enhance substrate reflection. However, the intermediate layer suppresses the reflection so that the substrate reflection can be 0.5% or less. The intermediate layer having such an antireflection effect is not limited, and polysilsesquioxane that crosslinks by an acid or heat in which a light absorbing group having a phenyl group or a silicon-silicon bond is introduced is preferably used for exposure at 193 nm.

Alternatively, an intermediate layer formed by chemical vapor deposition (CVD) may be used. The intermediate layer highly effective as an antireflection film prepared by CVD is not limited, and, for example, a SiON film is known. In general, the formation of an intermediate layer by a wet process such as spin coating or screen printing is more convenient and more advantageous in cost than CVD. The upper layer resist for a three-layer process may be positive type or negative type, and the same as a single-layer resist usually used can be used.

The underlayer film according to the present embodiment can also be used as an antireflection film for usual single-layer resists or an underlying material for suppression of pattern collapse. The underlayer film of the present embodiment is excellent in etching resistance for an underlying process and can be expected to also function as a hard mask for an underlying process.

In the case of forming a resist layer from the photoresist material, a wet process such as spin coating or screen printing is preferably used, as in the case of forming the underlayer film. After coating with the resist material by spin coating or the like, prebaking is usually performed. This prebaking is preferably performed at 80 to 180° C. in the range of 10 to 300 seconds. Then, exposure, post-exposure baking (PEB), and development can be performed according to a conventional method to obtain a resist pattern. The thickness of the resist film is not particularly limited, and in general, is preferably 30 to 500 nm and more preferably 50 to 400 nm.

The exposure light can be appropriately selected and used according to the photoresist material to be used. General examples thereof can include a high energy ray having a wavelength of 300 nm or less, specifically, excimer laser of 248 nm, 193 nm, or 157 nm, soft x-ray of 3 to 20 nm, electron beam, and X-ray.

In a resist pattern formed by the above method, pattern collapse is suppressed by the underlayer film according to the present embodiment. Therefore, use of the underlayer film according to the present embodiment can produce a finer pattern and can reduce an exposure amount necessary for obtaining the resist pattern.

Next, etching is performed with the obtained resist pattern as a mask. Gas etching is preferably used as the etching of the underlayer film in a two-layer process. The gas etching is suitably etching using oxygen gas. In addition to oxygen gas, an inert gas such as He or Ar, or CO, CO₂, NH₃, SO₂, N₂, NO₂, or H₂ gas may be added. Alternatively, the gas etching may be performed with CO, CO₂, NH₃, N₂, NO₂, or H₂ gas without the use of oxygen gas. Particularly, the latter gas is preferably used for side wall protection in order to prevent the undercut of pattern side walls.

On the other hand, gas etching is also preferably used as the etching of the intermediate layer in a three-layer process. The same gas etching as described in the two-layer process mentioned above is applicable. Particularly, it is preferable to process the intermediate layer in a three-layer process by using chlorofluorocarbon-based gas and using the resist pattern as a mask. Then, as mentioned above, for example, the underlayer film can be processed by oxygen gas etching with the intermediate layer pattern as a mask.

Herein, in the case of forming an inorganic hard mask intermediate layer film as the intermediate layer, a silicon oxide film, a silicon nitride film, or a silicon oxynitride film (SiON film) is formed by CVD, atomic layer deposition (ALD), or the like. A method for forming the nitride film is not limited, and, for example, a method described in Japanese Patent Laid-Open No. 2002-334869 or International Publication No. WO 2004/066377 can be used. Although a photoresist film can be formed directly on such an intermediate layer film, an organic antireflection film (BARC) may be formed on the intermediate layer film by spin coating and a photoresist film may be formed thereon.

A polysilsesquioxane-based intermediate layer is preferably used as the intermediate layer. By imparting effects as an antireflection film to the resist intermediate layer film, there is a tendency that reflection can be effectively suppressed. A specific material for the polysilsesquioxane-based intermediate layer is not limited, and, for example, a material described in Japanese Patent Laid-Open No. 2007-226170 or Japanese Patent Laid-Open No. 2007-226204 can be used.

The subsequent etching of the substrate can also be performed by a conventional method. For example, the substrate made of SiO₂ or SiN can be etched mainly using chlorofluorocarbon-based gas, and the substrate made of p-Si, Al, or W can be etched mainly using chlorine- or bromine-based gas. In the case of etching the substrate with chlorofluorocarbon-based gas, the silicon-containing resist of the two-layer resist process or the silicon-containing intermediate layer of the three-layer process is stripped at the same time with substrate processing. On the other hand, in the case of etching the substrate with chlorine- or bromine-based gas, the silicon-containing resist layer or the silicon-containing intermediate layer is separately stripped and in general, stripped by dry etching using chlorofluorocarbon-based gas after substrate processing.

A feature of the underlayer film according to the present embodiment is that it is excellent in etching resistance of these substrates. The substrate can be appropriately selected from publicly known ones and used and is not particularly limited. Examples thereof include Si, α-Si, p-Si, SiO₂, SiN, SiON, W, TiN, and Al. The substrate may be a laminate having a film to be processed (substrate to be processed) on a base material (support). Examples of such a film to be processed include various low-k films such as Si, SiO₂, SiON, SiN, p-Si, α-Si, W, W—Si, Al, Cu, and Al—Si, and stopper films thereof. A material different from that for the base material (support) is usually used. The thickness of the substrate to be processed or the film to be processed is not particularly limited, and usually, it is preferably approximately 50 to 1,000,000 nm and more preferably 75 to 500,000 nm.

### [Resist Permanent Film]

The composition for film formation of the present embodiment can also be used to prepare a resist permanent film. The resist permanent film prepared by coating with the composition for film formation of the present embodiment on a base material or the like is suitable as a permanent film that also remains in a final product, if required, after formation of a resist pattern. Specific examples of the permanent film include, but are not particularly limited to, in relation to semiconductor devices, solder resists, package materials, underfill materials, package adhesive layers for circuit elements and the like, and adhesive layers between integrated circuit elements and circuit substrates, and in relation to thin displays, thin film transistor protecting films, liquid crystal color filter protecting films, black matrixes, and spacers. Particularly, the permanent film made of the composition for film formation of the present embodiment is excellent in heat resistance and humidity resistance and furthermore, also has the excellent advantage that contamination by sublimable components is reduced. Particularly, for a display material, a material that achieves all of high sensitivity, high heat resistance, and hygroscopic reliability with reduced deterioration in image quality due to significant contamination can be obtained.

In the case of using the composition for film formation of the present embodiment for resist permanent films, a curing agent as well as, if required, various additive agents such as an additional resin, a surfactant, a dye, a filler, a crosslinking agent, and a dissolution promoting agent can be further added and dissolved in an organic solvent to prepare a composition for resist permanent films.

In the case of using the composition for film formation according to the present embodiment for resist permanent films, the composition for a resist permanent film can be prepared by adding each of the above components and mixing them using a stirrer or the like. When the composition for film formation of the present embodiment contains a filler or a pigment, the composition for a resist permanent film can be prepared by dispersion or mixing using a dispersion apparatus such as a dissolver, a homogenizer, and a three-roll mill.

### [Composition for Optical Member Formation]

The composition for film formation of the present embodiment can also be used for forming optical members (or forming optical components). That is, the composition for optical member formation of the present embodiment contains the composition for film formation of the present embodiment. In other words, the composition for optical member formation of the present embodiment contains the polymer according to the present embodiment as an essential component. Herein, the “optical members (or optical components)” refers to a component in the form of a film or a sheet as well as a plastic lens (a prism lens, a lenticular lens, a microlens, a Fresnel lens, a viewing angle control lens, a contrast improving lens, etc.), a phase difference film, a film for electromagnetic wave shielding, a prism, an optical fiber, a solder resist for flexible printed wiring, a plating resist, an interlayer insulating film for multilayer printed circuit boards, or a photosensitive optical waveguide. The polymer according to the present embodiment are useful for forming these optical members. The composition for optical member formation of the present embodiment may further contain various optional components in consideration of being used as an optical member forming material. Specifically, the composition for optical member formation of the present embodiment preferably further contains at least one selected from the group consisting of a solvent, an acid generating agent, and a crosslinking agent. Specific examples that can be used as the solvent, the acid generating agent, and the crosslinking agent may be the same as those of the components that may be contained in the composition for underlayer film formation for lithography according to the present embodiment described above, and the blending ratio thereof may be appropriately set in consideration of specific application.

### EXAMPLES

Hereinafter, the present embodiment will be described in more detail based on Examples, and Comparative Examples, but the present embodiment is not limited thereto.

### (Structure of Compound)

¹H-NMR measurement was performed under the following conditions by using “Advance 60011 spectrometer” manufactured by Bruker Corp.
Frequency: 400 MHz
Solvent: d6-DMSO
Internal standard: TMS
Measurement temperature: 23° C.

### (Molecular Weight)

The molecular weights of the compounds were measured by LC-MS (Liquid Chromatography-Mass Spectrometry) analysis using Acquity UPLC/MALDI-Synapt HDMS manufactured by Waters Corp.

### (Polystyrene Equivalent Molecular Weight)

The weight-average molecular weight (Mw) and number-average molecular weight (Mn) were determined by gel permeation chromatography (GPC) analysis, and the dispersibility (Mw/Mn) in terms of polystyrene was determined.
Apparatus: Shodex GPC-101 model (manufactured by Showa Denko K.K.)
Column: KF-80M×3
Eluent: 1 mL/min THF
Temperature: 40° C.

### [Synthesis Working Example 1-1] Synthesis of Polymer (R1-1)

To a container (internal capacity: 500 mL) equipped with a stirrer, a condenser tube, and a burette, 11.0 g (100 mmol) of resorcinol represented by the following formula (manufactured by Tokyo Kasei Kogyo Co., Ltd.) and 10.1 g (20 mmol) of monobutylcopper phthalate were added, and 100 mL of chloroform was added as a solvent. The reaction solution was stirred at 61° C. for 6 hours and reacted.

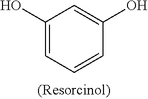

Then, after cooling, the precipitate was filtered and the resulting crude was dissolved in 100 mL of toluene. Next, 5 mL of hydrochloric acid was added to the obtained toluene solution, and the mixture was stirred at room temperature, and neutralized with sodium hydrogen carbonate. The toluene solution was concentrated, and the reaction product was precipitated by the addition of 200 mL of methanol to the concentrate, cooled to room temperature, and then filtered to separate solid matter. The obtained solid matter was dried to obtain 20.0 g of the polymer (R1-1) having a structure represented by the following formula.

The polystyrene equivalent molecular weight of the obtained polymer was measured by the method described above, and as a result, the obtained polymer had Mn: 880, Mw: 1,150, and Mw/Mn: 1.3.

The following peaks were found by NMR measurement performed on the obtained polymer under the measurement conditions described above, and it was confirmed that the polymer has a chemical structure of the following formula, and aromatic rings are directly bonded to each other.

δ (ppm) 10.0 (2H, —OH), 6.3-7.0 (2H, Ph-H); Ph-H represents the proton of the aromatic ring.

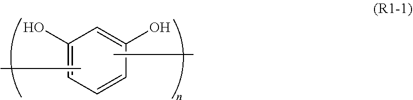

### [Synthesis Working Examples 1-2 to 1-4] Synthesis of Polymers (R1-2 to R1-4)

In Synthesis Working Examples 1-2 to 1-4, polymers (R1-2) to (R1-4) were synthesized in the same manner as in Synthesis Working Example 1-1, except that 1,3-dimethoxybenzene, aniline, or N,N-dimethylaniline, respectively, were used instead of resorcinol.

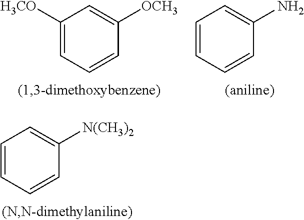 [SMILES: COc1cccc(OC)c1 ; Nc1ccccc1 ; CN(C)c1ccccc1]

As shown below, in the polymers (R1-2) to (R1-4), the following peaks were found by 400 MHz-¹H-NMR, and it was confirmed that each of the polymers had a chemical structures of the above formulas as a basic structure, and were polymers having a structure in which aromatic rings of the constituent units were directly bonded to each other. Further, the results of measuring the polystyrene equivalent molecular weight by the above method for each of the obtained polymers are also shown.

### (R1-2)

Mn: 888, Mw: 1180, Mw/Mn: 1.3

δ (ppm) 6.3-7.3 (2H, Ph-H), 3.8 (6H, —CH3)

### (R1-3) Mn: 628, Mw: 898, Mw/Mn: 1.4

δ (ppm) 6.7-7.2 (3H, Ph-H), 5.0 (2H, —NH2)

### (R1-4)

Mn: 622, Mw: 886, Mw/Mn: 1.4

δ (ppm) 6.7-7.2 (3H, Ph-H), 3.0 (6H, —N(CH3)2)

### [Synthesis Working Example 1A-1] Synthesis of Polymer (R1A-1)

To a container (internal capacity: 1,000 mL) equipped with a stirrer, a condenser tube, and a burette, 11.0 g (100 mmol) of resorcinol represented by the following formula (manufactured by Tokyo Kasei Kogyo Co., Ltd.), 46.7 g (100 mmol) of the compound (1A-1), and 20.2 g (40 mmol) of monobutylcopper phthalate were added, and 200 mL of chloroform was added as a solvent. The reaction solution was stirred at 61° C. for 6 hours and reacted.

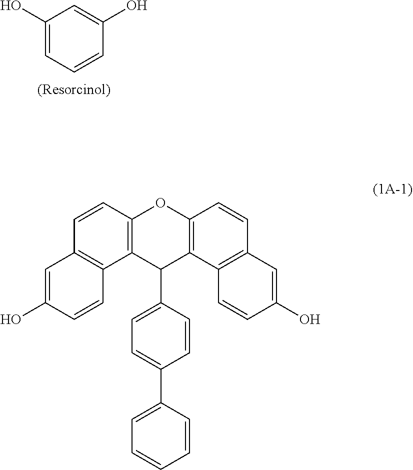 [SMILES: Oc1cccc(O)c1 ; Oc1ccc2c3c(ccc2c1)Oc1ccc2cc(O)ccc2c1C3c1ccc(-c2ccccc2)cc1]

Then, after cooling, the precipitate was filtered and the resulting crude was dissolved in 200 mL of toluene. Next, 10 mL of hydrochloric acid was added to the obtained toluene solution, and the mixture was stirred at room temperature, and neutralized with sodium hydrogen carbonate. The toluene solution was concentrated, and the reaction product was precipitated by the addition of 400 mL of methanol to the concentrate, cooled to room temperature, and then filtered to separate solid matter. The obtained solid matter was dried to obtain 52.0 g of the polymer (R1A-1) having a structure represented by the following formula.

The polystyrene equivalent molecular weight of the obtained polymer was measured by the method described above, and as a result, the obtained polymer had Mn: 4,682, Mw: 5,850, and Mw/Mn: 1.2.

The following peaks were found by NMR measurement performed on the obtained polymer under the measurement conditions described above, and it was confirmed that the polymer had a chemical structure of the following formula, and aromatic rings of the constituent units were directly bonded to each other.

δ (ppm) 10.0 (2H, —OH), 9.3-9.7 (2H, O—H), 7.2-8.5 (17H, Ph-H), 6.3-7.0 (2H, Ph-H), 6.7-6.9 (1H, C—H)

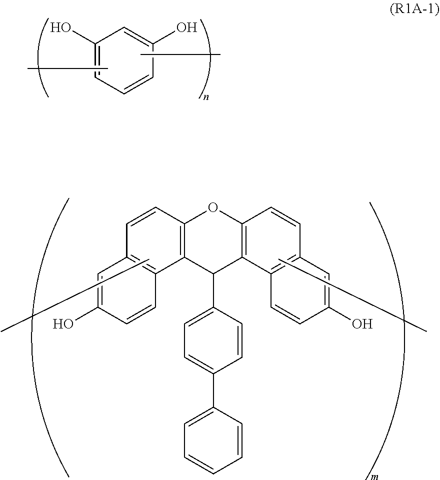

### [Synthesis Working Examples 1A-1a to 1A-1b] Synthesis of Polymers (R1A-1a) to (R1A-1b)

In Synthesis Working Example 1A-1a, a polymer (R1A-1a) was synthesized in the same manner as in Synthesis Working Example 1A-1, except that butanol was used instead of chloroform, copper acetate monohydrate was used instead of monobutylcopper phthalate, and the reaction solution was “stirred at 110° C. for 12 hours” instead of “stirred at 61° C. for 6 hours”.

In Synthesis Working Example 1A-1b, a polymer (R1A-1b) was synthesized in the same manner as in Synthesis Working Example 1A-1a, except that 7.4 g (67 mmol) of resorcinol and 15.4 g (33 mmol) of the compound (1A-1) were used instead of 11.0 g of resorcinol (100 mmol) and 46.7 g (100 mmol) of the compound (1A-1).

As shown below, in the polymers (R1A-1a) to (R1A-1b), the following peaks were found by 400 MHz-1H-NMR, and it was confirmed that each of the polymers had a chemical structures of the above formulas as a basic structure, and had a structure in which aromatic rings of the constituent units were directly bonded to each other. Further, the results of measuring the polystyrene equivalent molecular weight by the above method for each of the obtained polymers are also shown.

### (R1A-1a)

Mn: 4264, Mw: 6861, Mw/Mn: 1.6

δ (ppm) 10.0 (2H, —OH), 9.3-9.7 (2H, O—H), 7.2-8.5 (17H, Ph-H), 6.3-7.0 (2H, Ph-H), 6.7-6.9 (1H, C—H)

### (R1A-1b)

Mn: 6380, Mw: 11050, Mw/Mn: 1.7

δ (ppm) 10.0 (13H, —OH), 9.3-9.7 (6H, O—H), 7.2-8.5 (51H, Ph-H), 6.3-7.0 (13H, Ph-H), 6.7-6.9 (3H, C—H)

### [Synthesis Working Examples 1A-2 to 1A-15] Synthesis of Polymers (R1A-2) to (R1A-15)

In Synthesis Working Examples 1A-2 to 1A-15, polymers (R1A-2) to (R1A-15) were synthesized in the same manner as in Synthesis Example 1A-1, except that the following compounds (1A-2) to (1A-15) were used instead of the compound (1A-1), respectively.

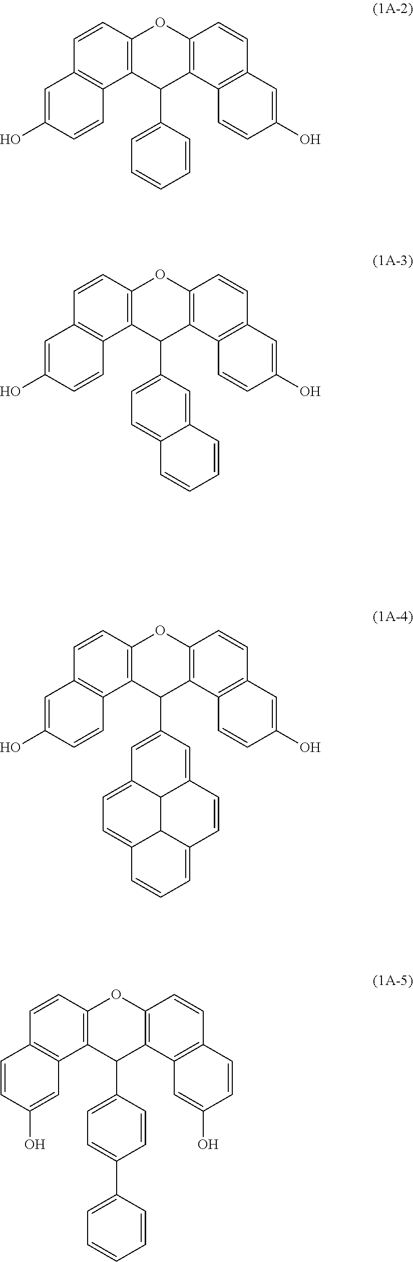 [SMILES: Oc1ccc2c3c(ccc2c1)Oc1ccc2cc(O)ccc2c1C3c1ccccc1 ; Oc1ccc2c3c(ccc2c1)Oc1ccc2cc(O)ccc2c1C3c1ccc2ccccc2c1 ; Oc1ccc2c3c(ccc2c1)Oc1ccc2cc(O)ccc2c1C3C1=CC2=CC=C3C=CC=C4C=CC(=C1)C2C43 ; Oc1ccc2ccc3c(c2c1)C(c1ccc(-c2ccccc2)cc1)c1c(ccc2ccc(O)cc12)O3]

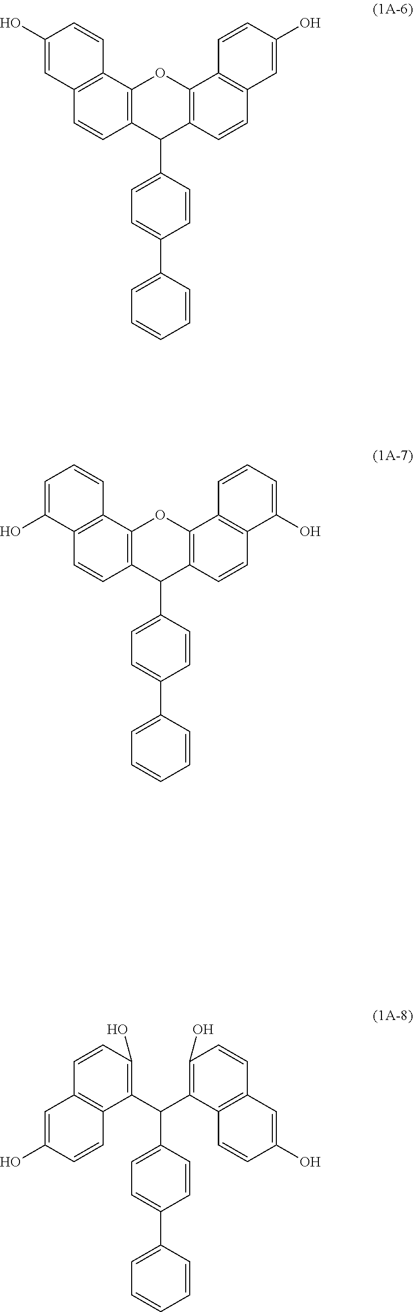 [SMILES: Oc1ccc2c3c(ccc2c1)C(c1ccc(-c2ccccc2)cc1)c1ccc2cc(O)ccc2c1O3 ; Oc1cccc2c3c(ccc12)C(c1ccc(-c2ccccc2)cc1)c1ccc2c(O)cccc2c1O3 ; Oc1ccc2c(C(c3ccc(-c4ccccc4)cc3)c3c(O)ccc4cc(O)ccc34)c(O)ccc2c1]

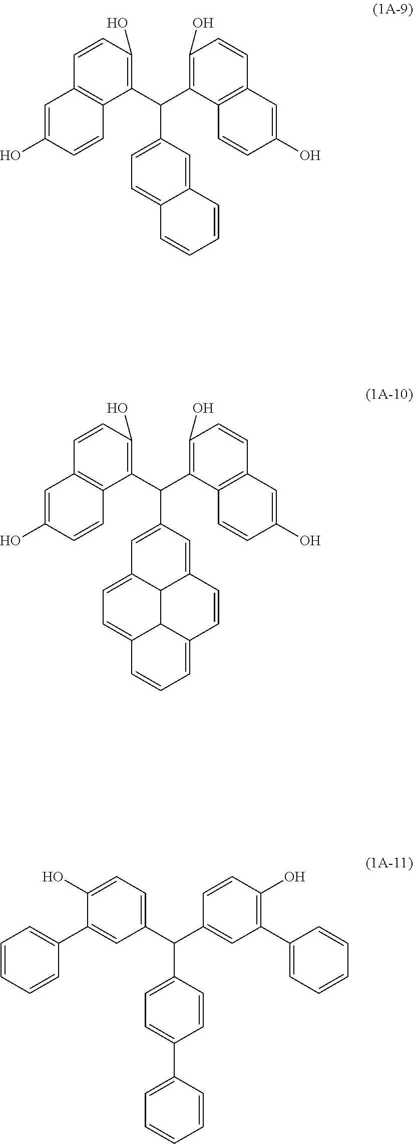 [SMILES: Oc1ccc2c(C(c3ccc4ccccc4c3)c3c(O)ccc4cc(O)ccc34)c(O)ccc2c1 ; Oc1ccc2c(C(C3=CC4=CC=C5C=CC=C6C=CC(=C3)C4C65)c3c(O)ccc4cc(O)ccc34)c(O)ccc2c1 ; Oc1ccc(C(c2ccc(-c3ccccc3)cc2)c2ccc(O)c(-c3ccccc3)c2)cc1-c1ccccc1]

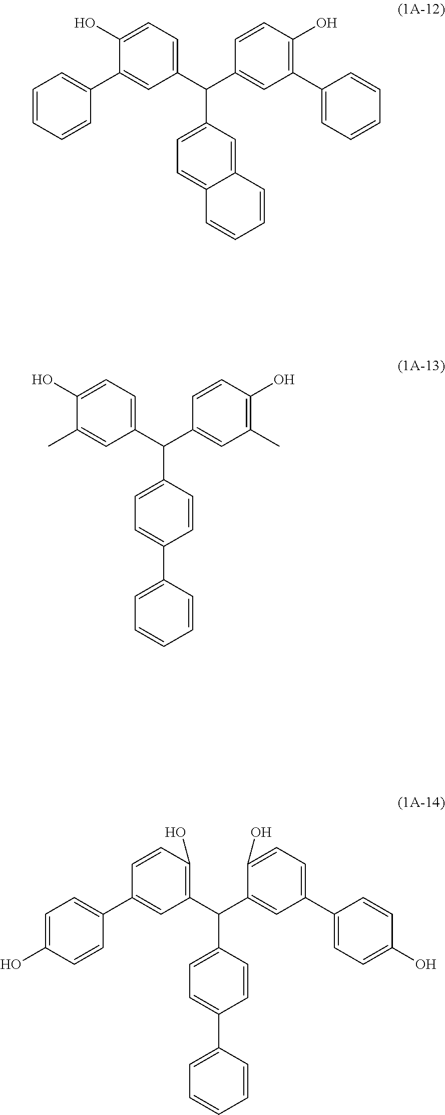 [SMILES: Oc1ccc(C(c2ccc(O)c(-c3ccccc3)c2)c2ccc3ccccc3c2)cc1-c1ccccc1 ; Cc1cc(C(c2ccc(-c3ccccc3)cc2)c2ccc(O)c(C)c2)ccc1O ; Oc1ccc(-c2ccc(O)c(C(c3ccc(-c4ccccc4)cc3)c3cc(-c4ccc(O)cc4)ccc3O)c2)cc1]

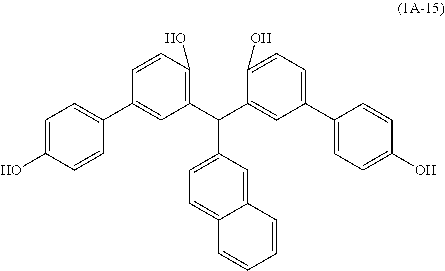 [SMILES: Oc1ccc(-c2ccc(O)c(C(c3ccc4ccccc4c3)c3cc(-c4ccc(O)cc4)ccc3O)c2)cc1]

As shown below, in the polymers (R1A-2) to (R1A-15), the following peaks were found by 400 MHz-¹H-NMR, and it was confirmed that each of the polymers had a chemical structures of the above formulas as a basic structure, and had a structure in which aromatic rings of the constituent units were directly bonded to each other. Further, the results of measuring the polystyrene equivalent molecular weight by the above method for each of the obtained polymers are also shown.

### (R1A-2)

Mn: 824, Mw: 1122, Mw/Mn: 1.4

δ (ppm) 10.0 (2H, —OH), 9.3-9.7 (2H, O—H), 7.2-8.5 (13H, Ph-H), 6.3-7.0 (2H, Ph-H), 6.7-6.9 (1H, C—H)

### (R1A-3)

Mn: 857, Mw: 1102, Mw/Mn: 1.3

δ (ppm) 10.0 (2H, —OH), 9.3-9.7 (2H, O—H), 7.2-8.5 (15H, Ph-H), 6.3-7.0 (2H, Ph-H), 6.7-6.9 (1H, C—H)

### (R1A-4)

Mn: 904, Mw: 1248, Mw/Mn: 1.4

δ (ppm) 10.0 (2H, —OH), 9.3-9.7 (2H, O—H), 7.2-8.5 (17H, Ph-H), 6.3-7.0 (2H, Ph-H), 6.7-6.9 (1H, C—H)

### (R1A-5)

Mn: 892, Mw: 1055, Mw/Mn: 1.2

δ (ppm) 10.0 (2H, —OH), 9.3-9.7 (2H, O—H), 7.2-8.5 (17H, Ph-H), 6.3-7.0 (2H, Ph-H), 6.7-6.9 (1H, C—H)

### (R1A-6)

Mn: 902, Mw: 1212, Mw/Mn: 1.3

δ (ppm) 10.0 (2H, —OH), 9.3-9.7 (2H, O—H), 7.2-8.5 (17H, Ph-H), 6.3-7.0 (2H, Ph-H), 6.7-6.9 (1H, C—H)

### (R1A-7)

Mn: 856, Mw: 1192, Mw/Mn: 1.4

δ (ppm) 10.0 (2H, —OH), 9.3-9.7 (2H, O—H), 7.2-8.5 (17H, Ph-H), 6.3-7.0 (2H, Ph-H), 6.7-6.9 (1H, C—H)

### (R1A-8)

Mn: 876, Mw: 1140, Mw/Mn: 1.3

δ (ppm) 10.0 (2H, —OH), 9.3-9.7 (4H, O—H), 7.2-8.5 (17H, Ph-H), 6.3-7.0 (2H, Ph-H), 6.7-6.9 (1H, C—H)

### (R1A-9)

Mn: 852, Mw: 1104, Mw/Mn: 1.3

δ (ppm) 10.0 (2H, —OH), 9.3-9.7 (4H, O—H), 7.2-8.5 (15H, Ph-H), 6.3-7.0 (2H, Ph-H), 6.7-6.9 (1H, C—H)

### (R1A-10)

Mn: 900, Mw: 1202, Mw/Mn: 1.3

δ (ppm) 10.0 (2H, —OH), 9.3-9.7 (4H, O—H), 7.2-8.5 (17H, Ph-H), 6.3-7.0 (2H, Ph-H), 6.7-6.9 (1H, C—H)

### (R1A-11)

Mn: 922, Mw: 1246, Mw/Mn: 1.4

δ (ppm) 10.0 (2H, —OH), 9.3-9.7 (2H, O—H), 7.2-8.5 (23H, Ph-H), 6.3-7.0 (2H, Ph-H), 6.7-6.9 (1H, C—H)

### (R1A-12)

Mn: 856, Mw: 1168, Mw/Mn: 1.4

δ (ppm) 10.0 (2H, —OH), 9.3-9.7 (2H, O—H), 7.2-8.5 (21H, Ph-H), 6.3-7.0 (2H, Ph-H), 6.7-6.9 (1H, C—H)

### (R1A-13)

Mn: 892, Mw: 1196, Mw/Mn: 1.3

δ (ppm) 10.0 (2H, —OH), 9.3-9.7 (2H, O—H), 7.2-8.5 (13H, Ph-H), 6.3-7.0 (2H, Ph-H), 6.7-6.9 (1H, C—H), 2.0-2.1 (6H, —CH3)

### (R1A-14)

Mn: 898, Mw: 1192, Mw/Mn: 1.3

δ (ppm) 10.0 (2H, —OH), 9.3-9.7 (4H, O—H), 7.2-8.5 (21H, Ph-H), 6.3-7.0 (2H, Ph-H), 6.7-6.9 (1H, C—H)

### (R1A-15)

Mn: 898, Mw: 1222, Mw/Mn: 1.4

δ (ppm) 10.0 (2H, —OH), 9.3-9.7 (2H, O—H), 7.2-8.5 (19H, Ph-H), 6.3-7.0 (2H, Ph-H), 6.7-6.9 (1H, C—H)

### [Synthesis Working Example 1B-1] Synthesis of Polymer (R1B-1)

To a container (internal capacity: 1,000 mL) equipped with a stirrer, a condenser tube, and a burette, 11.0 g (100 mmol) of resorcinol represented by the following formula (manufactured by Tokyo Kasei Kogyo Co., Ltd.), 14.4 g (100 mmol) of 2-naphthol (manufactured by Tokyo Kasei Kogyo Co., Ltd.) (the following compound 1B-1), and 20.2 g (40 mmol) of monobutylcopper phthalate were added, and 200 mL of chloroform was added as a solvent. The reaction solution was stirred at 61° C. for 6 hours and reacted.

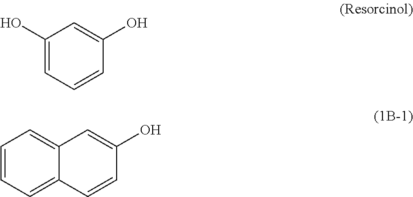

Then, after cooling, the precipitate was filtered and the resulting crude was dissolved in 200 mL of toluene. Next, 10 mL of hydrochloric acid was added to the obtained toluene solution, and the mixture was stirred at room temperature, and neutralized with sodium hydrogen carbonate. The toluene solution was concentrated, and the reaction product was precipitated by the addition of 400 mL of methanol to the concentrate, cooled to room temperature, and then filtered to separate solid matter. The obtained solid matter was dried to obtain 21.0 g of the polymer (R1B-1) having a structure represented by the following formula.

The polystyrene equivalent molecular weight of the obtained polymer was measured by the method described above, and as a result, the obtained polymer had Mn: 824, Mw: 1,002, and Mw/Mn: 1.2.

The following peaks were found by NMR measurement performed on the obtained polymer under the measurement conditions described above, and it was confirmed that the polymer had a chemical structure of the following formula, and aromatic rings of the constituent units were directly bonded to each other.

δ (ppm) 10.0 (2H, —OH), 9.2 (1H, —OH), 7.1-8.0 (5H, Ph-H), 6.3-7.0 (2H, Ph-H)

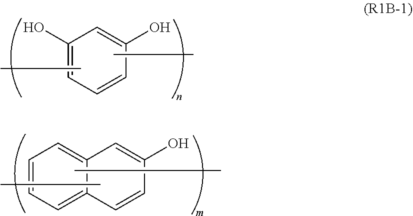

### [Synthesis Working Examples 1B-2 to 1B-8] Synthesis of Polymers (R1B-2) to (R1B-8)

In Synthesis Working Examples R1B-2 to R1B-8, polymers (R1B-2) to (R1B-8) were synthesized in the same manner as in Synthesis Example 1B-1, except that the following compounds (1B-2) to (1B-8) were used instead of the compound (1B-1), respectively.

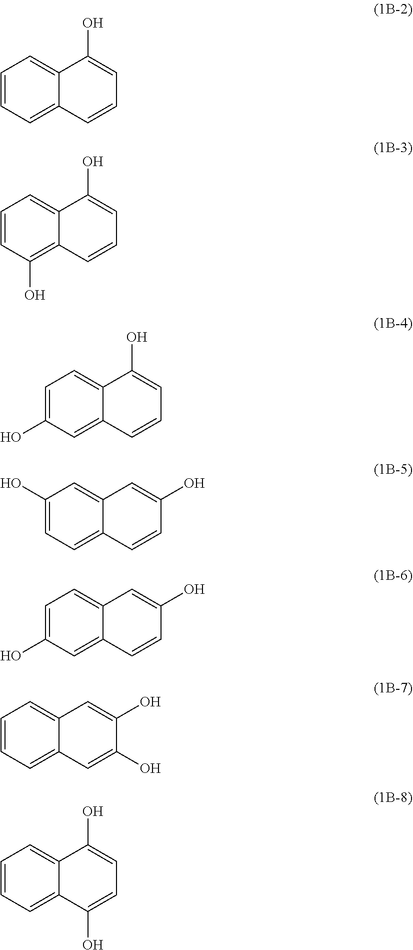

As shown below, in the polymers (R1B-2) to (R1B-8), the following peaks were found by 400 MHz-1H-NMR, and it was confirmed that each of the polymers had a chemical structures of the above formulas as a basic structure, and had a structure in which aromatic rings of the constituent units were directly bonded to each other. Further, the results of measuring the polystyrene equivalent molecular weight by the above method for each of the obtained polymers are also shown.

### (R1B-2)

Mn: 898, Mw: 1115, Mw/Mn: 1.2

δ (ppm) 10.0 (2H, —OH), 9.2 (1H, —OH), 7.1-8.0 (5H, Ph-H), 6.3-7.0 (2H, Ph-H)

### (R1B-3)

Mn: 920, Mw: 1222, Mw/Mn: 1.3

δ (ppm) 10.0 (2H, —OH), 9.2 (2H, —OH), 7.1-8.0 (4H, Ph-H), 6.3-7.0 (2H, Ph-H)

### (R1B-4)

Mn: 900, Mw: 1156, Mw/Mn: 1.3

δ (ppm) 10.0 (2H, —OH), 9.2 (2H, —OH), 7.1-8.0 (4H, Ph-H), 6.3-7.0 (2H, Ph-H)

### (R1B-5)

Mn: 802, Mw: 966, Mw/Mn: 1.2

δ (ppm) 10.0 (2H, —OH), 9.2 (2H, —OH), 7.1-8.0 (4H, Ph-H), 6.3-7.0 (2H, Ph-H)

### (R1B-6)

Mn: 822, Mw: 1012, Mw/Mn: 1.2

δ (ppm) 10.0 (2H, —OH), 9.2 (2H, —OH), 7.1-8.0 (4H, Ph-H), 6.3-7.0 (2H, Ph-H)

### (R1B-7)

Mn: 802, Mw: 965, Mw/Mn: 1.2

δ (ppm) 10.0 (2H, —OH), 9.2 (2H, —OH), 7.1-8.0 (4H, Ph-H), 6.3-7.0 (2H, Ph-H)

### (R1B-8)

Mn: 800, Mw: 970, Mw/Mn: 1.2

δ (ppm) 10.0 (2H, —OH), 9.2 (2H, —OH), 7.1-8.0 (4H, Ph-H), 6.3-7.0 (2H, Ph-H)

### [Synthesis Working Example 1C-1] Synthesis of Polymer (R1C-1)

To a container (internal capacity: 1,000 mL) equipped with a stirrer, a condenser tube, and a burette, 11.0 g (100 mmol) of resorcinol represented by the following formula (manufactured by Tokyo Kasei Kogyo Co., Ltd.), 29.0 g (100 mmol) of the compound (1C-1), and 20.2 g (40 mmol) of monobutylcopper phthalate were added, and 200 mL of chloroform was added as a solvent. The reaction solution was stirred at 61° C. for 6 hours and reacted.

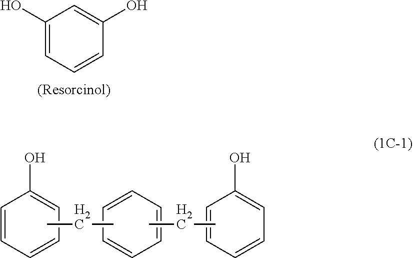

Then, after cooling, the precipitate was filtered and the resulting crude was dissolved in 200 mL of toluene. Next, 10 mL of hydrochloric acid was added to the toluene solution, and the mixture was stirred at room temperature, and neutralized with sodium hydrogen carbonate. The toluene solution was concentrated, and the reaction product was precipitated by the addition of 400 mL of methanol to the concentrate, cooled to room temperature, and then filtered to separate solid matter. The obtained solid matter was dried to obtain 29.0 g of the polymer (R1C-1) having a structure represented by the following formula.

The polystyrene equivalent molecular weight of the obtained polymer was measured by the method described above, and as a result, the obtained polymer had Mn: 1,024, Mw: 1,242, and Mw/Mn: 1.2.

The following peaks were found by NMR measurement performed on the obtained polymer under the measurement conditions described above, and it was confirmed that the polymer had a chemical structure of the following formula, and aromatic rings of the constituent units were directly bonded to each other.

δ (ppm) δ (ppm) 10.0 (2H, —OH), 9.1 (2H, —OH), 6.2-7.1 (14H, -Ph), 4.1 (4H, —CH2-)

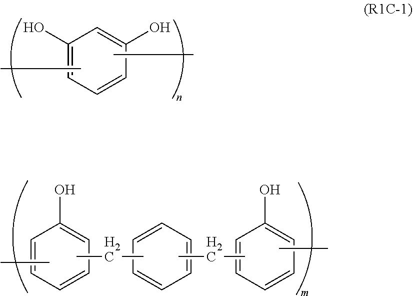

### [Synthesis Working Examples 1C-2 to 1C-4] Synthesis of Polymers (R1C-2) to (R1C-4)

In Synthesis Working Examples 1C-2 to 1C-4, polymers (R1C-2) to (R1C-4) were synthesized in the same manner as in Synthesis Working Example 1C-1, except that the following compounds (1C-2) to (1C-4) were used instead of the compound (1C-1), respectively.

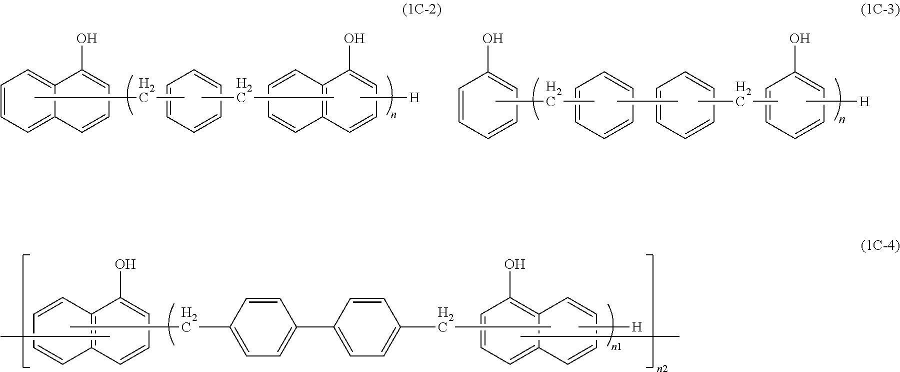

As shown below, in the polymers (R1C-2) to (R1C-4), the following peaks were found by 400 MHz-1H-NMR, and it was confirmed that each of the polymers had a chemical structures of the above formulas as a basic structure, and had a structure in which aromatic rings of the constituent units were directly bonded to each other. Further, the results of measuring the polystyrene equivalent molecular weight by the above method for each of the obtained polymers are also shown.

### (R1C-2)

Mn: 1001, Mw: 1221, Mw/Mn: 1.2

δ (ppm) 10.0 (2H, —OH), 9.1 (2H, —OH), 6.2-7.1 (16H, -Ph), 4.1 (4H, —CH2-)

### (R1C-3)

Mn: 1002, Mw: 1198, Mw/Mn: 1.2

δ (ppm) 10.0 (2H, —OH), 9.1 (2H, —OH), 6.2-7.1 (18H, -Ph), 4.1 (4H, —CH2-)

### (R1C-4)

Mn: 1002, Mw: 1120, Mw/Mn: 1.1

δ (ppm) 10.0 (2H, —OH), 9.1 (2H, —OH), 6.2-7.1 (22H, -Ph), 4.1 (4H, —CH2-)

### [Synthesis Working Example 1D-1] Synthesis of Polymer (R1D-1)

To a container (internal capacity: 1,000 mL) equipped with a stirrer, a condenser tube, and a burette, 11.0 g (100 mmol) of resorcinol represented by the following formula (manufactured by Tokyo Kasei Kogyo Co., Ltd.), 64.9 g (100 mmol) of 4-t-butylcalix[4]arene (manufactured by Tokyo Kasei Kogyo Co., Ltd.) (the compound 1D-1), and 20.2 g (40 mmol) of monobutylcopper phthalate were added, and 200 mL of chloroform was added as a solvent. The reaction solution was stirred at 61° C. for 6 hours and reacted.

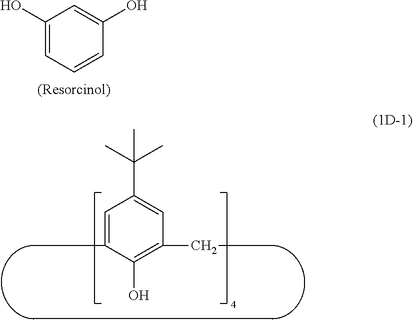

Then, after cooling, the precipitate was filtered and the resulting crude was dissolved in 200 mL of toluene. Next, 10 mL of hydrochloric acid was added to the obtained toluene solution, and the mixture was stirred at room temperature, and neutralized with sodium hydrogen carbonate. The toluene solution was concentrated, and the reaction product was precipitated by the addition of 400 mL of methanol to the concentrate, cooled to room temperature, and then filtered to separate solid matter. The obtained solid matter was dried to obtain 64.0 g of the polymer (R1D-1) having a structure represented by the following formula.

The polystyrene equivalent molecular weight of the obtained polymer was measured by the method described above, and as a result, the obtained polymer had Mn: 4,084, Mw: 5,212, and Mw/Mn: 1.3.

The following peaks were found by NMR measurement performed on the obtained polymer under the measurement conditions described above, and it was confirmed that the polymer had a chemical structure of the following formula, and aromatic rings of the constituent units were directly bonded to each other.

δ (ppm) 10.2 (4H, O—H), 10.0 (2H, —OH), 7.1-7.3 (6H, Ph-H), 6.3-7.0 (2H, Ph-H), 3.5-4.3 (8H, C—H), 1.2 (36H, —CH₃)

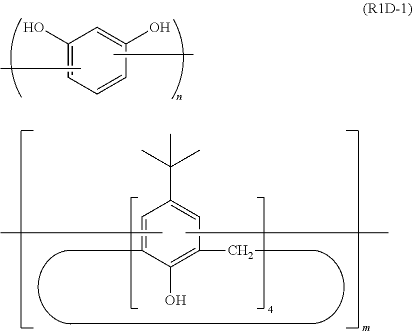

### [Synthesis Working Examples 1D-2 to 1D-5] Synthesis of Polymer (R1D-2) to (R1D-5)

In Synthesis Working Examples 1D-2 to 1D-5, polymers (R1D-2) to (R1D-5) were synthesized in the same manner as in Synthesis Working Example 1D-1, except that the following compounds (1D-2) to (1D-5) were used instead of the compound (1D-1), respectively.

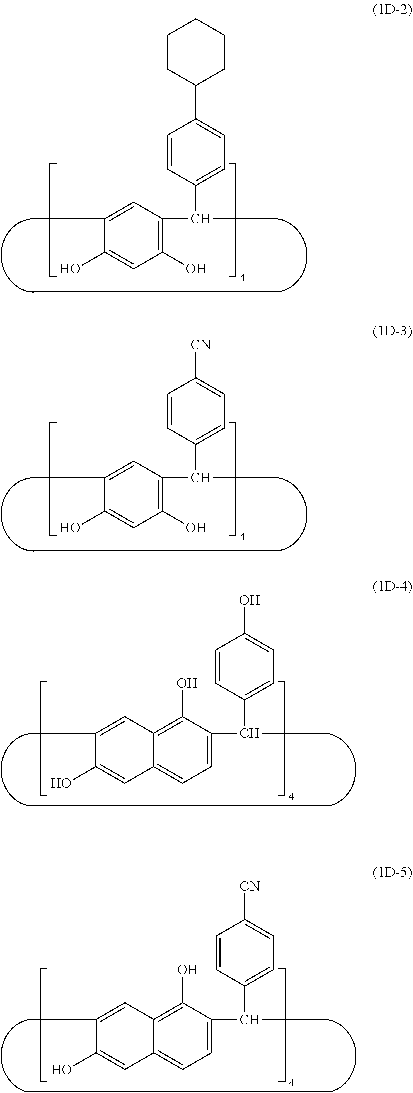

As shown below, in the polymers (R1D-2) to (R1D-5), the following peaks were found by 400 MHz-¹H-NMR, and it was confirmed that each of the polymers had a chemical structures of the above formulas as a basic structure, and had a structure in which aromatic rings of the constituent units were directly bonded to each other. Further, the results of measuring the polystyrene equivalent molecular weight by the above method for each of the obtained polymers are also shown.

### (R1D-2)

Mn: 4024, Mw: 5202, Mw/Mn: 1.3

δ (ppm) 10.0 (2H, —OH), 8.4-8.5 (8H, O—H), 6.0-7.0 (24H, Ph-H), 5.5-5.6 (4H, C—H), 0.8-1.9 (44H, -cyclohexyl group)

### (R1D-3)

Mn: 3980, Mw: 5002, Mw/Mn: 1.3

δ (ppm) 10.0 (2H, —OH), 8.4-8.5 (8H, O—H), 6.0-7.0 (24H, Ph-H), 5.5-5.6 (4H, C—H)

### (R1D-4)

Mn: 3898, Mw: 4988, Mw/Mn: 1.3

δ (ppm) 10.0 (2H, —OH), 9.0-9.6 (12H, O—H), 5.9-8.7 (36H, Ph-H, C—H)

### (R1D-5)

Mn: 4034, Mw: 5112, Mw/Mn: 1.3

δ (ppm) 10.0 (2H, —OH), 9.2-9.6 (8H, O—H), 5.9-8.7 (36H, Ph-H, C—H)

### [Synthesis Working Example 1E-1] Synthesis of Polymer (R1E-1)

To a container (internal capacity: 1,000 mL) equipped with a stirrer, a condenser tube, and a burette, 11.0 g (100 mmol) of resorcinol represented by the following formula (manufactured by Tokyo Kasei Kogyo Co., Ltd.), 11.7 g (100 mmol) of indole (the compound 1E-1), and 20.2 g (40 mmol) of monobutylcopper phthalate were added, and 200 mL of chloroform was added as a solvent. The reaction solution was stirred at 61° C. for 6 hours and reacted.

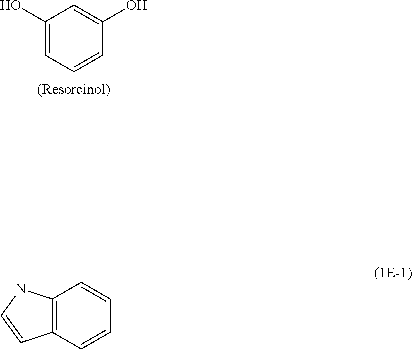 [SMILES: Oc1cccc(O)c1 ; c1ccc2[nH]ccc2c1]

Then, after cooling, the precipitate was filtered and the resulting crude was dissolved in 200 mL of toluene. Next, 10 mL of hydrochloric acid was added to the obtained toluene solution, and the mixture was stirred at room temperature, and neutralized with sodium hydrogen carbonate. The toluene solution was concentrated, and the reaction product was precipitated by the addition of 400 mL of methanol to the concentrate, cooled to room temperature, and then filtered to separate solid matter. The obtained solid matter was dried to obtain 12.2 g of the polymer (R1E-1) having a structure represented by the following formula.

The polystyrene equivalent molecular weight of the obtained polymer was measured by the method described above, and as a result, the obtained polymer had Mn: 1,050, Mw: 1,250, and Mw/Mn: 1.2.

The following peaks were found by NMR measurement performed on the obtained polymer under the measurement conditions described above, and it was confirmed that the polymer had a chemical structure of the following formula, and aromatic rings of the constituent units were directly bonded to each other.

δ (ppm) 10.1 (1H, N—H), 10.0 (2H, —OH), 6.3-7.0 (2H, Ph-H), 6.4-7.6 (4H, Ph-H)

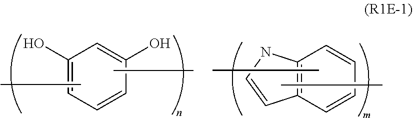

### [Synthesis Working Examples 1E-2 to 1E-6] Synthesis of Polymer (R1E-2) to (R1E-6)

In Synthesis Working Examples 1E-2 to 1E-6, polymers were synthesized in the same manner as in Synthesis Working Example 1D-1, except that the following compounds (1E-2) to (1E-6) were used instead of the compound (1D-1), respectively.

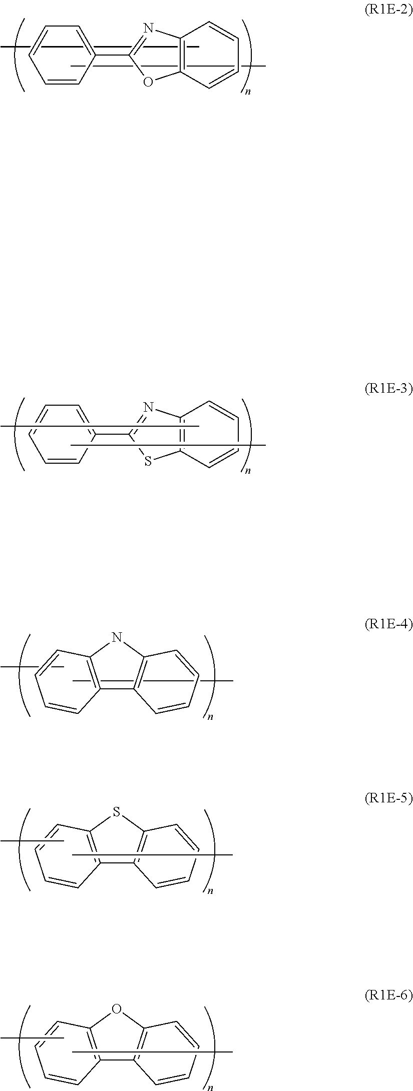

As shown below, in the polymers (R1E-2) to (R1E-6), the following peaks were found by 400 MHz-¹H-NMR, and it was confirmed that each of the polymers had a chemical structures of the above formulas as a basic structure, and had a structure in which aromatic rings of the constituent units were directly bonded to each other. Further, the results of measuring the polystyrene equivalent molecular weight by the above method for each of the obtained polymers are also shown.

### (R1E-2)

Mn: 1000, Mw: 1228, Mw/Mn: 1.2

δ (ppm) 10.0 (2H, —OH), 7.3-8.2 (7H, Ph-H), 6.3-7.0 (2H, Ph-H)

### (R1E-3)

Mn: 1012, Mw: 1220, Mw/Mn: 1.2

δ (ppm) 10.0 (2H, —OH), 7.5-8.2 (7H, Ph-H), 6.3-7.0 (2H, Ph-H) (R1E-4)

### (R1E-4)

Mn: 989, Mw: 1198, Mw/Mn: 1.2

δ (ppm) 12.1 (1H, N—H), 10.0 (2H, —OH), 7.2-8.2 (6H, Ph-H), 6.3-7.0 (2H, Ph-H) (R1E-5)

### (R1E-5)

Mn: 996, Mw: 1186, Mw/Mn: 1.2

δ (ppm) 10.0 (2H, —OH), 7.4-8.5 (6H, Ph-H), 6.3-7.0 (2H, Ph-H) (R1E-6)

### (R1E-6)

Mn: 998, Mw: 1198, Mw/Mn: 1.2

δ (ppm) 10.0 (2H, —OH), 7.3-8.0 (6H, Ph-H), 6.3-7.0 (2H, Ph-H)

### [Comparative Synthesis Example 1] Synthesis of NBisN-1

To a container (internal capacity: 500 mL) equipped with a stirrer, a condenser tube, and a burette, 32.0 g (200 mmol) of 2,7-naphthalenediol (reagent manufactured by Sigma-Aldrich), 18.2 g (100 mmol) of 4-biphenylaldehyde (manufactured by Mitsubishi Gas Chemical Co., Inc.), and 200 mL of 1,4-dioxane were added, and 10 mL of 95% sulfuric acid was added. The reaction solution was stirred at 100° C. for 6 hours and reacted. Next, the reaction solution was neutralized with 24% aqueous sodium hydroxide solution, and the reaction product was precipitated by the addition of 100 g of pure water, cooled to room temperature, and then filtered to separate solid matter. The solid matter obtained was dried and then separated and purified by column chromatography to obtain 25.5 g of the objective compound (BisN-1) represented by the following formula.

The following peaks were found by 400 MHz-¹H-NMR, and the obtained compound was confirmed to have a chemical structure of the following formula. From the doublets of proton signals at positions 3 and 4, it was confirmed that the substitution position of 2,7-dihydroxynaphthol was position 1.

¹H-NMR: (d-DMSO, internal standard TMS)

δ (ppm) 9.6 (2H, O—H), 7.2-8.5 (19H, Ph-H), 6.6 (1H, C—H)

LC-MS analysis confirmed that the molecular weight was 466 corresponding to the following chemical structure.

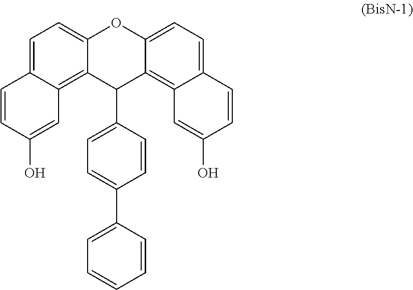 [SMILES: Oc1ccc2ccc3c(c2c1)C(c1ccc(-c2ccccc2)cc1)c1c(ccc2ccc(O)cc12)O3]

To a container (internal capacity: 100 ml) equipped with a stirrer, a condenser tube, and a burette, 10 g (21 mmol) of BisN-1, 0.7 g (42 mmol) of paraformaldehyde, 50 mL of glacial acetic acid, and 50 mL of PGME were added, and 8 mL of 95% sulfuric acid was added thereto. The reaction solution was stirred at 100° C. for 6 hours and reacted. Next, the reaction solution was concentrated, and the reaction product was precipitated by the addition of 1,000 mL of methanol to the concentrate, cooled to room temperature, and then filtered to separate solid matter. The obtained solid material was filtered and dried to obtain 7.2 g of the polymer (NBisN-1) having a structure represented by the following formula.

The polystyrene equivalent molecular weight of the obtained polymer was measured by the method described above, and as a result, the obtained polymer had Mn: 1,278, Mw: 1,993, and Mw/Mn: 1.56.

The following peaks were found by NMR measurement performed on the obtained polymer under the measurement conditions, and the polymer was confirmed to have a chemical structure of the following formula.

δ (ppm) 9.7 (2H, O—H), 7.2-8.5 (17H, Ph-H), 6.6 (1H, C—H), 4.1 (2H, —CH2)

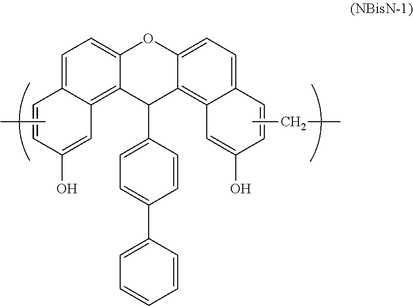

### Comparative Synthesis Example 2

A four necked flask (internal capacity: 10 L) equipped with a Dimroth condenser tube, a thermometer and a stirring blade, and having a detachable bottom was prepared. To this four necked flask, 1.09 kg (7 mol) of 1,5-dimethylnaphthalene (manufactured by Mitsubishi Gas Chemical Co., Inc.), 2.1 kg (28 mol as formaldehyde) of 40% by mass of an aqueous formalin solution (manufactured by Mitsubishi Gas Chemical Co., Inc.), and 0.97 mL of 98% by mass of sulfuric acid (manufactured by Kanto Chemical Co., Inc.) were added in a nitrogen stream, and the mixture was reacted for 7 hours while refluxed at 100° C. at normal pressure. Thereafter, 1.8 kg of ethylbenzene (special grade reagent manufactured by Wako Pure Chemical Industries, Ltd.) was added as a diluting solvent to the reaction solution, and the mixture was left to stand still, followed by removal of an aqueous phase as a lower phase. Neutralization and washing with water were further performed, and ethylbenzene and unreacted 1,5-dimethylnaphthalene were distilled off under reduced pressure to obtain 1.25 kg of a dimethylnaphthalene formaldehyde resin as a light brown solid.

Subsequently, a four necked flask (internal capacity: 0.5 L) equipped with a Dimroth condenser tube, a thermometer, and a stirring blade was prepared. To this four necked flask, 100 g (0.51 mol) of the dimethylnaphthalene formaldehyde resin obtained as mentioned above, and 0.05 g of p-toluenesulfonic acid were added in a nitrogen stream, and the temperature was raised to 190° C. at which the mixture was then heated for 2 hours, followed by stirring. Thereafter, 52.0 g (0.36 mol) of 1-naphthol was further added thereto, and the temperature was further raised to 220° C. at which the mixture was allowed to react for 2 hours. After dilution with a solvent, neutralization and washing with water were performed, and the solvent was distilled off under reduced pressure to obtain 126.1 g of a modified resin (CR-1) as a black-brown solid.

### Examples 1 to 42

Table 1 shows the results of evaluating the heat resistance by the evaluation methods shown below using the polymers obtained in Synthesis Working Examples and Comparative Synthesis Example 1.

### <Measurement of Thermal Decomposition Temperature>

EXSTAR 6000 TG/DTA apparatus manufactured by SII NanoTechnology Inc. was used. About 5 mg of a sample was placed in an unsealed container made of aluminum, and the temperature was raised to 700° C. at a temperature increase rate of 10° C./min in a nitrogen gas stream (30 mL/min). The temperature at which a heat loss of 10% by weight was observed was defined as the thermal decomposition temperature (Tg), and the heat resistance was evaluated according to the following criteria.
A: The thermal decomposition temperature was 430° C. or higher
B: The thermal decomposition temperature was 375° C. or higher and lower than 430° C.
C: The thermal decomposition temperature was lower than 375° C.

### <Measurement of Solubility>

At 23° C., the polymer obtained in each Example was dissolved in cyclohexanone (CHN) to give a 5% by mass solution. Thereafter, the appearance of the CHN solution after leaving the solution to stand still at 10° C. for 30 days was evaluated according to the following criteria.
A: No precipitates were visually confirmed.
C: Precipitates were visually confirmed.

TABLE 1

| | | | Heat | |
|---|---|---|---|---|
| | | | resistance | Solubility |
| | Polymer | | evaluation | evaluation |
| Example 1 | Synthesis Working Example 1-1 | R1-1 | B | A |
| Example 2 | Synthesis Working Example 1-2 | R1-2 | B | A |
| Example 3 | Synthesis Working Example 1-3 | R1-3 | B | A |
| Example 4 | Synthesis Working Example 1-4 | R1-4 | B | A |
| Example 5 | Synthesis Working Example 1A-1 | R1A-1 | A | A |
| Example 6 | Synthesis Working Example 1A-2 | R1A-2 | A | A |
| Example 7 | Synthesis Working Example 1A-3 | R1A-3 | A | A |
| Example 8 | Synthesis Working Example 1A-4 | R1A-4 | A | A |
| Example 9 | Synthesis Working Example 1A-5 | R1A-5 | A | A |
| Example 10 | Synthesis Working Example 1A-6 | R1A-6 | A | A |
| Example 11 | Synthesis Working Example 1A-7 | R1A-7 | A | A |
| Example 12 | Synthesis Working Example 1A-8 | R1A-8 | A | A |
| Example 13 | Synthesis Working Example 1A-9 | R1A-9 | A | A |
| Example 14 | Synthesis Working Example 1A-10 | R1A-10 | A | A |
| Example 15 | Synthesis Working Example 1A-11 | R1A-11 | A | A |
| Example 16 | Synthesis Working Example 1A-12 | R1A-12 | A | A |
| Example 17 | Synthesis Working Example 1A-13 | R1A-13 | A | A |
| Example 18 | Synthesis Working Example 1A-14 | R1A-14 | A | A |
| Example 19 | Synthesis Working Example 1A-15 | R1A-15 | A | A |
| Example 20 | Synthesis Working Example 1B-1 | R1B-1 | A | A |
| Example 21 | Synthesis Working Example 1B-2 | R1B-2 | A | A |
| Example 22 | Synthesis Working Example 1B-3 | R1B-3 | A | A |
| Example 23 | Synthesis Working Example 1B-4 | R1B-4 | A | A |
| Example 24 | Synthesis Working Example 1B-5 | R1B-5 | A | A |
| Example 25 | Synthesis Working Example 1B-6 | R1B-6 | A | A |
| Example 26 | Synthesis Working Example 1B-7 | R1B-7 | A | A |
| Example 27 | Synthesis Working Example 1B-8 | R1B-8 | A | A |
| Example 28 | Synthesis Working Example 1C-1 | R1C-1 | A | A |
| Example 29 | Synthesis Working Example 1C-2 | R1C-2 | A | A |
| Example 30 | Synthesis Working Example 1C-3 | R1C-3 | A | A |
| Example 31 | Synthesis Working Example 1C-4 | R1C-4 | A | A |
| Example 32 | Synthesis Working Example 1D-1 | R1D-1 | A | A |
| Example 33 | Synthesis Working Example 1D-2 | R1D-2 | A | A |
| Example 34 | Synthesis Working Example 1D-3 | R1D-3 | A | A |
| Example 35 | Synthesis Working Example 1D-4 | R1D-4 | A | A |
| Example 36 | Synthesis Working Example 1D-5 | R1D-5 | A | A |
| Example 37 | Synthesis Working Example 1E-1 | R1E-1 | A | A |
| Example 38 | Synthesis Working Example 1E-2 | R1E-2 | A | A |
| Example 39 | Synthesis Working Example 1E-3 | R1E-3 | A | A |
| Example 40 | Synthesis Working Example 1E-4 | R1E-4 | A | A |
| Example 41 | Synthesis Working Example 1E-5 | R1E-5 | A | A |
| Example 42 | Synthesis Working Example 1E-6 | R1E-6 | A | A |
| Comparative | Comparative Synthesis Example 1 | NBisN-1 | C | A |
| Example 1 | | | | |

As is evident from Table 1, it was able to be confirmed that the polymers used in Examples have good heat resistance whereas the polymers used in Comparative Example 1 is inferior in heat resistance. It was also confirmed that all of the polymers had good solubility.

### Examples 43 to 66

### <<Preparation of Composition for Underlayer Film Formation for Lithography>>

Compositions for underlayer film formation for lithography were prepared according to the composition shown in Table 2. Next, a silicon substrate was spin coated with each of these compositions for underlayer film formation for lithography, and then baked at 240° C. for 60 seconds and further at 400° C. for 120 seconds under a nitrogen gas atmosphere to prepare each underlayer film having a film thickness of 200 to 250 nm.

Then, etching test was conducted under conditions shown below to evaluate etching resistance. The evaluation results are shown in Table 2. Details of the evaluation method will be described later.

### <Etching Test>

Etching apparatus: “RIE-10NR” manufactured by Samco International, Inc.
Output: 50 W
Pressure: 20 Pa
Time: 2 min
Etching gas
Ar gas flow rate:CF₄ gas flow rate:O₂ gas flow rate=50:5:5 (sccm)

### (Evaluation of Etching Resistance)

The evaluation of etching resistance was conducted by the following procedures. First, an underlayer film of novolac was prepared under the same conditions as described above except that novolac (“PSM4357” manufactured by Gunei Chemical Industry Co., Ltd.) was used. This underlayer film of novolac was subjected to the above etching test, and the etching rate was measured.

Next, for the underlayer films of each of Examples and Comparative Example 2, the etching test was performed in the same manner, and the etching rate was measured. Then, the etching resistance for each of Examples and Comparative Example 2 was evaluated according to the following evaluation criteria on the basis of the etching rate of the underlayer film of novolac.

### [Evaluation Criteria]

A: The etching rate was less than −20% as compared with the underlayer film of novolac.
B: The etching rate was −20% or more and −10% or less as compared with the underlayer film of novolac.
C: The etching rate was more than −10% as compared with the underlayer film of novolac.

TABLE 2

| | | | Solvent | |
|---|---|---|---|---|
| | | | (parts by | Etching |
| | Polymer (parts by mass) | | mass) | evaluation |
| Example 43 | Synthesis Working | R1-1 | CHN | B |
| | Example 1-1 | (10) | (90) | |
| Example 44 | Synthesis Working | R1-2 | CHN | B |
| | Example 1-2 | (10) | (90) | |
| Example 45 | Synthesis Working | R1-3 | CHN | B |
| | Example 1-3 | (10) | (90) | |
| Example 46 | Synthesis Working | R1-4 | CHN | B |
| | Example 1-4 | (10) | (90) | |
| Example 47 | Synthesis Working | R1A-1 | CHN | A |
| | Example 1A-1 | (10) | (90) | |
| Example 48 | Synthesis Working | R1A-2 | CHN | A |
| | Example 1A-2 | (10) | (90) | |
| Example 49 | Synthesis Working | R1A-3 | CHN | A |
| | Example 1A-3 | (10) | (90) | |
| Example 50 | Synthesis Working | R1A-4 | CHN | A |
| | Example 1A-4 | (10) | (90) | |
| Example 51 | Synthesis Working | R1B-1 | CHN | A |
| | Example 1B-1 | (10) | (90) | |
| Example 52 | Synthesis Working | R1B-2 | CHN | A |
| | Example 1B-2 | (10) | (90) | |
| Example 53 | Synthesis Working | R1B-3 | CHN | A |
| | Example 1B-3 | (10) | (90) | |
| Example 54 | Synthesis Working | R1B-4 | CHN | A |
| | Example 1B-4 | (10) | (90) | |
| Example 55 | Synthesis Working | R1C-1 | CHN | A |
| | Example 1C-1 | (10) | (90) | |
| Example 56 | Synthesis Working | R1C-2 | CHN | A |
| | Example 1C-2 | (10) | (90) | |
| Example 57 | Synthesis Working | R1C-3 | CHN | A |
| | Example 1C-3 | (10) | (90) | |
| Example 58 | Synthesis Working | R1C-4 | CHN | A |
| | Example 1C-4 | (10) | (90) | |
| Example 59 | Synthesis Working | R1D-1 | CHN | A |
| | Example 1D-1 | (10) | (90) | |
| Example 60 | Synthesis Working | R1D-2 | CHN | A |
| | Example 1D-2 | (10) | (90) | |
| Example 61 | Synthesis Working | R1D-3 | CHN | A |
| | Example 1D-3 | (10) | (90) | |
| Example 62 | Synthesis Working | R1D-4- | CHN- | A |
| | Example 1D-4 | 10 | 90 | |
| Example 63 | Synthesis Working | R1E-1 | CHN | A |
| | Example 1E-1 | (10) | (90) | |
| Example 64 | Synthesis Working | R1E-2 | CHN | A |
| | Example 1E-2 | (10) | (90) | |
| Example 65 | Synthesis Working | R1E-3 | CHN | A |
| | Example 1E-3 | (10) | (90) | |
| Example 66 | Synthesis Working | R1E-4 | CHN | A |
| | Example 1E-4 | (10) | (90) | |
| Comparative | Comparative | NBisN-1 | CHN | C |
| Example 2 | Synthesis | (10) | (90) | |
| | Example 1 | | | |

It was found that in each of Examples, the etching rate was equal to or superior to that of the novolac underlayer film and the polymer of Comparative Example 2. On the other hand, it was found that the etching rate of the polymer of Comparative Example 2 was poor as compared with the underlayer film of novolac.

### <<Purification of Polymer>>

The metal content before and after purification of polymer and the storage stability of the solution were evaluated by the following method.

### <Measurement of Various Metal Contents>

The metal contents of the propylene glycol monomethyl ether acetate (PGMEA) solutions of various polymers obtained in the following Examples and Comparative Examples were measured using inductively coupled plasma mass spectrometry (ICP-MS) under the following measurement conditions.
Apparatus: AG8900 manufactured by Agilent Technologies
Temperature: 25° C.
Environment: Class 100 clean room

### <Storage Stability Evaluation>

The PGMEA solutions obtained in the following Examples were retained at 23° C. for 240 hours, and then the turbidity (HAZE) of the solutions was measured using a color difference/turbidity meter to evaluate the storage stability of the solutions according to the following criteria.
Apparatus: Color difference/turbidity meter COH400 (manufactured by Nippon Denshoku Industries Co., Ltd.)
Optical path length: 1 cm
Quartz cell use

### [Evaluation Criteria]

0≤HAZE≤1.0: Good
1.0<HAZE≤2.0: Fair
2.0<HAZE: Poor

### [Example 1F] Purification of Polymer (R1-1) with Acid

In a four necked flask (capacity: 1000 mL, with a detachable bottom), 150 g of a solution (10% by mass) formed by dissolving the polymer (R1-1) obtained in Synthesis Working Example 1-1 in CHN was charged, and was heated to 80° C. with stirring. Then, 37.5 g of an aqueous oxalic acid solution (pH 1.3) was added to the obtained solution, and the resultant mixture was stirred for 5 minutes and then left to stand still for 30 minutes. This separated the mixture into an oil phase and an aqueous phase, and the aqueous phase was then removed. After repeating this operation once, 37.5 g of ultrapure water was charged to the obtained oil phase, and after stirring for 5 minutes, the mixture was left to stand still for 30 minutes and the aqueous phase was removed. After repeating this operation three times, the residual water and CHN were concentrated and distilled off by heating to 80° C. and reducing the pressure in the flask to 200 hPa or less. Thereafter, by diluting with CHN of EL grade (a reagent manufactured by Kanto Chemical Co., Inc.) such that the concentration of the CHN solution was adjusted to 10% by mass, a CHN solution of a polymer (R1-1) with a reduced metal content was obtained.

### [Reference Example 1] Purification of Polymer (R1-1) with Ultrapure Water

In the same manner as of Example 1F except that ultrapure water was used instead of the aqueous oxalic acid solution, and by adjusting the concentration to 10% by mass, a CHN solution of the polymer (R1-1) was obtained.

For the 10% by mass CHN solution of the polymer (R1-1) before the treatment, and the solutions obtained in Example 1F and Reference Example 1, the contents of various metals were measured by ICP-MS. The measurement results are shown in Table 3.

### [Example 2F] Purification of Polymer (R1A-1) with Acid

In a four necked flask (capacity: 1000 mL, with a detachable bottom), 140 g of a solution (10% by mass) formed by dissolving the polymer (R1A-1) obtained in Synthesis Working Example 1A-1 in CHN was charged, and was heated to 60° C. with stirring. Then, 37.5 g of an aqueous oxalic acid solution (pH 1.3) was added to the obtained solution, and the resultant mixture was stirred for 5 minutes and then left to stand still for 30 minutes. This separated the mixture into an oil phase and an aqueous phase, and the aqueous phase was then removed. After repeating this operation once, 37.5 g of ultrapure water was charged to the obtained oil phase, and after stirring for 5 minutes, the mixture was left to stand still for 30 minutes and the aqueous phase was removed. After repeating this operation three times, the residual water and CHN were concentrated and distilled off by heating to 80° C. and reducing the pressure in the flask to 200 hPa or less. Thereafter, by diluting with CHN of EL grade (a reagent manufactured by Kanto Chemical Co., Inc.) such that the concentration of the CHN solution was adjusted to 10% by mass, a CHN solution of a polymer (R1A-1) with a reduced metal content was obtained.

### [Reference Example 2] Purification of Polymer (R1A-1) with Ultrapure Water

In the same manner as of Example 2F except that ultrapure water was used instead of the aqueous oxalic acid solution, and by adjusting the concentration to 10% by mass, a CHN solution of the polymer (R1A-1) was obtained.

For the 10% by mass CHN solution of the polymer (R1A-1) before the treatment, and the solutions obtained in Example 2F and Reference Example 2, the contents of various metals were measured by ICP-MS. The measurement results are shown in Table 3.

### [Example 3F] Purification by Passing Through Filter

In a class 1000 clean booth, 500 g of a solution of 10% by mass concentration of the polymer (R1-1) obtained in Synthesis Working Example 1-1 dissolved in CHN was charged in a four necked flask (capacity: 1000 mL, with a detachable bottom), and then the air inside the flask was depressurized and removed, nitrogen gas was introduced to return it to atmospheric pressure, and the oxygen concentration inside was adjusted to less than 1% under the ventilation of 100 mL of nitrogen gas per minute, and the flask was heated to 30° C. with stirring. The solution was drawn out from the bottom-vent valve, and passed through a pressure tube made of fluororesin through a diaphragm pump at a flow rate of 100 mL per minute to a hollow fiber membrane filter (manufactured by KITZ MICRO FILTER CORPORATION, trade name: Polyfix Nylon Series) made of nylon with a nominal pore size of 0.01 μm. The contents of various metals in the obtained polymer (R1-1) solution were measured by ICP-MS. The oxygen concentration was measured with an oxygen concentration meter “OM-25MF10” manufactured by AS ONE Corporation (the same applies hereinafter). The measurement results are shown in Table 3.

### Examples 4F

The solution was passed through in the same manner as in Example 3F except that a hollow fiber membrane filter (manufactured by KITZ MICRO FILTER CORPORATION, trade name: Polyfix) made of polyethylene (PE) with a nominal pore size of 0.01 μm was used, and the contents of various metals in the obtained polymer (R1-1) solution were measured by ICP-MS. The measurement results are shown in Table 3.

### Examples 5F

The solution was passed through in the same manner as in Example 3F except that a hollow fiber membrane filter (manufactured by KITZ MICRO FILTER CORPORATION, trade name: Polyfix) made of nylon with a nominal pore size of 0.04 μm was used, and the contents of various metals in the obtained polymer (R1-1) solution were measured by ICP-MS. The measurement results are shown in Table 3.

### Examples 6F

The solution was passed through in the same manner as in Example 3F except that a zeta potential filter (Zeta Plus filter 40QSH (manufactured by 3M Company, having an ion exchange capacity)) with a nominal pore size of 0.2 μm was used, and the contents of various metals in the obtained polymer (R1-1) solution were measured by ICP-MS. The measurement results are shown in Table 3.

### Examples 7F

The solution was passed through in the same manner as in Example 3F except that a zeta potential filter (Zeta Plus filter 020GN (manufactured by 3M Company, having an ion exchange capacity, and having different filtration areas and filter material thicknesses from those of Zeta Plus filter 40QSH)) with a nominal pore size of 0.2 μm was used, and the contents of various metals in the obtained polymer (R1-1) solution were measured by ICP-MS. The measurement results are shown in Table 3.

### Examples 8F

The solution was passed through in the same manner as in Example 3F except that the polymer (R1A-1) obtained in Synthesis Working Example 1A-1 was used instead of the polymer (R1-1) in Example 3F, and the contents of various metals in the obtained polymer (R1A-1) solution were measured by ICP-MS. The measurement results are shown in Table 3.

### Examples 9F

The solution was passed through in the same manner as in Example 4F except that the polymer (R1A-1) obtained in Synthesis Working Example 1A-1 was used instead of the polymer (R1-1) in Example 4F, and the contents of various metals in the obtained polymer (R1A-1) solution were measured by ICP-MS. The measurement results are shown in Table 3.

### Examples 10F

The solution was passed through in the same manner as in Example 5F except that the polymer (R1A-1) obtained in Synthesis Working Example 1A-1 was used instead of the polymer (R1-1) in Example 5F, and the contents of various metals in the obtained polymer (R1A-1) solution were measured by ICP-MS. The measurement results are shown in Table 3.

### Examples 11F

The solution was passed through in the same manner as in Example 6F except that the polymer (R1A-1) obtained in Synthesis Working Example 1A-1 was used instead of the polymer (R1-1) in Example 6F, and the contents of various metals in the obtained polymer (R1A-1) solution were measured by ICP-MS. The measurement results are shown in Table 3.

### Examples 12F

The solution was passed through in the same manner as in Example 7F except that the polymer (R1A-1) obtained in Synthesis Working Example 1A-1 was used instead of the polymer (R1-1) in Example 7F, and the contents of various metals in the obtained polymer (R1A-1) solution were measured by ICP-MS. The measurement results are shown in Table 3.

### [Examples 13F] Combination of Acid Washing and Filter Passage 1

In a class 1000 clean booth, 140 g of the 10% by mass CHN solution of the polymer (R1-1) with a reduced metal content obtained by Example 1F was charged in a four necked flask (capacity: 300 mL, with a detachable bottom), and then the air inside the flask was depressurized and removed, nitrogen gas was introduced to return it to atmospheric pressure, and the oxygen concentration inside was adjusted to less than 1% under the ventilation of 100 mL of nitrogen gas per minute, and the flask was heated to 30° C. with stirring. The solution was drawn out from the bottom-vent valve, passed through a pressure tube made of fluororesin through a diaphragm pump at a flow rate of 10 mL per minute to an ion exchange filter (manufactured by Nihon Pall Ltd., trade name: IonKleen Series) with a nominal pore size of 0.01 μm. The collected solution was then returned to the four necked flask (capacity: 300 mL), and the filter was changed to a filter made of high-density PE with a nominal diameter of 1 nm (manufactured by Entegris Japan Co., Ltd.), and pumped through the flask in the same manner. The contents of various metals in the obtained polymer (R1-1) solution were measured by ICP-MS. The oxygen concentration was measured with an oxygen concentration meter “OM-25MF10” manufactured by AS ONE Corporation. The measurement results are shown in Table 3.

### [Examples 14F] Combination of Acid Washing and Filter Passage 2

In a class 1000 clean booth, 140 g of the 10% by mass CHN solution of the polymer (R1-1) with a reduced metal content obtained by Example 1F was charged in a four necked flask (capacity: 300 mL, with a detachable bottom), and then the air inside the flask was depressurized and removed, nitrogen gas was introduced to return it to atmospheric pressure, and the oxygen concentration inside was adjusted to less than 1% under the ventilation of 100 mL of nitrogen gas per minute, and the flask was heated to 30° C. with stirring. The solution was drawn out from the bottom-vent valve, and passed through a pressure tube made of fluororesin through a diaphragm pump at a flow rate of 10 mL per minute to a hollow fiber membrane filter (manufactured by KITZ MICRO FILTER CORPORATION, trade name: Polyfix) made of nylon with a nominal pore size of 0.01 μm. The collected solution was then returned to the four necked flask (capacity: 300 mL), and the filter was changed to a filter made of high-density PE with a nominal diameter of 1 nm (manufactured by Entegris Japan Co., Ltd.), and pumped through the flask in the same manner. The contents of various metals in the obtained polymer (R1-1) solution were measured by ICP-MS. The oxygen concentration was measured with an oxygen concentration meter “OM-25MF10” manufactured by AS ONE Corporation. The measurement results are shown in Table 3.

### [Examples 15F] Combination of Acid Washing and Filter Passage 3

The same procedure as in Example 13F was carried out except that the 10% by mass CHN solution of the polymer (R1-1) used in Example 1F was changed to the 10% by mass CHN solution of the polymer (R1A-1) obtained by Example 2F to collect a 10% by mass PGMEA solution of the polymer (R1A-1) with a reduced metal amount. The contents of various metals in the obtained solution were measured by ICP-MS. The oxygen concentration was measured with an oxygen concentration meter “OM-25MF10” manufactured by AS ONE Corporation. The measurement results are shown in Table 3.

### [Examples 16F] Combination of Acid Washing and Filter Passage 4

The same procedure as in Example 14F was carried out except that the 10% by mass CHN solution of the polymer (R1-1) used in Example 1F was changed to the 10% by mass CHN solution of the polymer (R1A-1) obtained by Example 2F to collect a 10% by mass PGMEA solution of the polymer (R1A-1) with a reduced metal amount. The contents of various metals in the obtained solution were measured by ICP-MS. The oxygen concentration was measured with an oxygen concentration meter “OM-25MF10” manufactured by AS ONE Corporation. The measurement results are shown in Table 3.

TABLE 3

| | | Metal content (ppb) | | | | Storage |
|---|---|---|---|---|---|---|
| | Purification method | Cr | Fe | Cu | Zn | stability |
| Before | — | 74 | 332 | 736 | 100 | Poor |
| treatment | | | | | | |
| R1-1 | | | | | | |
| Example 1F | Acid washing | 14 | 12 | 68 | 6 | Good |
| Example 3F | Hollow fiber membrane nylon | 2 | 2 | 25 | 3 | Good |
| | filter | | | | | |
| Example 4F | Hollow fiber membrane PE filter | 40 | 111 | 211 | 78 | Fair |
| Example 5F | Hollow fiber membrane nylon | 6 | 10 | 14 | 9 | Good |
| | filter | | | | | |
| Example 6F | Zeta potential filter | 8 | 14 | 27 | 13 | Good |
| Example 7F | Zeta potential filter | 5 | 11 | 27 | 8 | Good |
| Example 13F | Combined use of acid washing/ | <0.1 | <0.1 | <0.1 | <0.1 | Good |
| | ion exchange filter/PE filter | | | | | |
| Example 14F | Combined use of acid washing/ | <0.1 | <0.1 | <0.1 | <0.1 | Good |
| | hollow fiber membrane nylon | | | | | |
| | filter/PE filter | | | | | |
| Reference | Water washing | 60 | 248 | 400 | 66 | Poor |
| Example 1 | | | | | | |
| Before | — | 84 | 330 | 800 | 200 | Poor |
| treatment | | | | | | |
| R1A-1 | | | | | | |
| Example 2F | Acid washing | 20 | 12 | 42 | 12 | Good |
| Example 8F | Hollow fiber membrane nylon | 5 | 3 | 33 | 11 | Good |
| | filter | | | | | |
| Example 9F | Hollow fiber membrane PE filter | 76 | 120 | 312 | 110 | Fair |
| Example 10F | Hollow fiber membrane nylon | 6 | 6 | 26 | 4 | Good |
| | filter | | | | | |
| Example 11F | Zeta potential filter | 12 | 15 | 25 | 3 | Good |
| Example 12F | Zeta potential filter | 2 | 85 | 2 | 76 | Good |
| Example 15F | Combined use of acid washing/ | <0.1 | <0.1 | <0.1 | <0.1 | Good |
| | ion exchange filter/PE filter | | | | | |
| Example 16F | Combined use of acid washing/ | <0.1 | <0.1 | <0.1 | <0.1 | Good |
| | hollow fiber membrane nylon | | | | | |
| | filter/PE filter | | | | | |
| Reference | Water washing | 68 | 180 | 444 | 102 | Poor |
| Example 2 | | | | | | |

As shown in Table 3, it was confirmed that the storage stability of the polymer solutions according to the present embodiment was improved by reducing the metal derived from the oxidizing agent through various purification methods.

In particular, the acid cleaning method and the use of ion exchange or nylon filters can effectively reduce ionic metals, and the combination of high-definition high-density polyethylene particulate removal filters can provide dramatic metal removal effects.

### Examples 1R to 7R and Comparative Example 3

### <Resist Performance>

Using the polymers obtained in Synthesis Working Examples and Comparative Synthesis Example 1 shown in Table 4, the test for evaluation of resist performance below were carried out, and the results thereof are shown in Table 4.

### (Preparation of Resist Composition)

A resist composition was prepared according to the ratio shown in Table 4 using each polymer synthesized above. Among the components of the resist composition in Table 4, the following acid generating agent (C), acid diffusion controlling agent (E), and solvent were used.

Acid Generating Agent (C)
P-1: triphenylbenzenesulfonium trifluoromethanesulfonate (Midori Kagaku Co., Ltd.)

Acid Crosslinking Agent (G)
C-1: NIKALAC MW-100LM (Sanwa Chemical Co., Ltd.)

Acid Diffusion Controlling Agent (E)
Q-1: trioctylamine (Tokyo Kasei Kogyo Co., Ltd.)

Solvent
S-1: CHN (Tokyo Kasei Kogyo Co., Ltd.)

### (Method for Evaluating Resist Performance of Resist Composition)

A clean silicon wafer was spin coated with the homogeneous resist composition, and then prebaked (PB) before exposure in an oven of 110° C. to form a resist film with a thickness of 60 nm. The obtained resist film was irradiated with electron beams of 1:1 line and space setting with a 50 nm interval using an electron beam lithography system (ELS-7500 manufactured by ELIONIX INC.). After the electron beam irradiation, the resist film was heated at each predetermined temperature for 90 seconds, and immersed in 2.38% by mass tetramethylammonium hydroxide (TMAH) alkaline developing solution for 60 seconds for development. Thereafter, the resist film was washed with ultrapure water for 30 seconds, and dried to form a resist pattern.

Concerning the formed resist pattern, the line and space were observed by a scanning electron microscope (“S-4800” manufactured by Hitachi High-Technologies Corporation) to evaluate the reactivity by electron beam irradiation of the resist composition.

TABLE 4

| | | Resist composition | | | | | Resist |
|---|---|---|---|---|---|---|---|
| | | Polymer | P-1 | C-1 | Q-1 | S-1 | performance |
| | Polymer | [g] | [g] | [g] | [g] | [g] | evaluation |
| Example 1R | R1-1 | 1.0 | 0.3 | 0.3 | 0.03 | 50.0 | Good |
| Example 2R | R1A-1 | 1.0 | 0.3 | 0.3 | 0.03 | 50.0 | Good |
| Example 3R | R1B-1 | 1.0 | 0.3 | 0.3 | 0.03 | 50.0 | Good |
| Example 4R | R1C-1 | 1.0 | 0.3 | 0.3 | 0.03 | 50.0 | Good |
| Example 5R | R1D-1 | 1.0 | 0.3 | 0.3 | 0.03 | 50.0 | Good |
| Example 6R | R1E-1 | 1.0 | 0.3 | 0.3 | 0 | 50.0 | Good |
| Example 7R | R1-1 | 1.0 | 0.2 | 0.2 | 0.02 | 50.0 | Good |
| Comparative | NBisN-1 | 1.0 | 0.3 | 0.3 | 0.03 | 50.0 | Poor |
| Example 3 | | | | | | | |

In the resist pattern evaluation, a good resist pattern was obtained by irradiation with electron beams of 1:1 line and space setting with a 50 nm interval in each of Examples. As for the line edge roughness, a pattern having asperities of less than 5 nm was evaluated to be good. On the other hand, it was not possible to obtain a good resist pattern in Comparative Example 3.

When the polymer satisfying the requirements of the present embodiment is used as described above, the polymer can impart a good shape to a resist pattern, as compared with the polymer (NBisN-1) of Comparative Example 3 which does not satisfy the requirements. As long as the above requirements of the present embodiment are met, compounds other than the polymers described in Examples also exhibit the same effects.

### Examples 1S to 6S and Comparative Example 4

### (Preparation of Radiation-Sensitive Composition)

The components were mixed in the proportions shown in Table 5 to obtain homogeneous solutions, and the obtained homogeneous solutions were filtered through a Teflon® membrane filter with a pore diameter of 0.1 μm to prepare radiation-sensitive compositions. Each of the prepared radiation-sensitive compositions was evaluated as described below.

TABLE 5

| | Composition | | |
|---|---|---|---|
| | | Optically active | |
| | Polymer | compound (B) | Solvent |
| | [g] | [g] | [g] |
| Example 1S | R1-1 | B-1 | S-1 |
| | 0.5 | 1.5 | 30.0 |
| Example 2S | R1A-1 | B-1 | S-1 |
| | 0.5 | 1.5 | 30.0 |
| Example 3S | R1B-1 | B-1 | S-1 |
| | 0.5 | 1.5 | 30.0 |
| Example 4S | R1C-1 | B-1 | S-1 |
| | 0.5 | 1.5 | 30.0 |
| Example 5S | R1D-1 | B-1 | S-1 |
| | 0.5 | 1.5 | 30.0 |
| Example 6S | R1E-1 | B-1 | S-1 |
| | 0.5 | 1.0 | 30.0 |
| Comparative | PHS-1 | B-1 | S-1 |
| Example 4 | 0.5 | 1.5 | 30.0 |

The following resist base material (component (A)) was used in Comparative Example 4.
PHS-1: polyhydroxystyrene Mw=8000 (Sigma-Aldrich)

The following optically active compound (B) was used.
B-1: naphthoquinonediazide-based sensitizing agent having the following chemical structural formula (G) (product name “4NT-300”, Toyo Gosei Co., Ltd.) The following solvent was used.
S-1: CHN (Tokyo Kasei Kogyo Co., Ltd.)

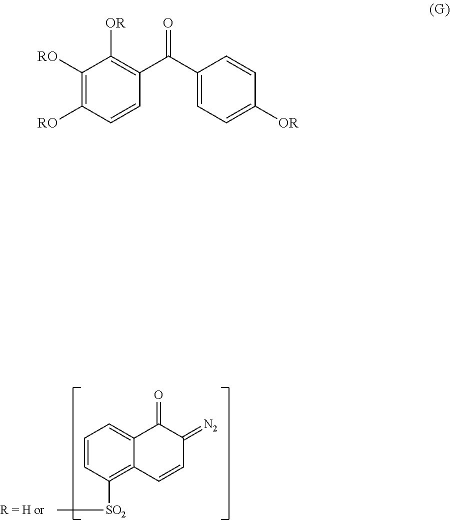

### <Evaluation of Resist Performance of Radiation-Sensitive Composition>

A clean silicon wafer was spin coated with the radiation-sensitive composition obtained as described above, and then prebaked (PB) before exposure in an oven of 110° C. to form a resist film with a thickness of 200 nm. The resist film was exposed to ultraviolet using an ultraviolet exposure apparatus (mask aligner MA-10 manufactured by Mikasa Co., Ltd.). The ultraviolet lamp used was a super high pressure mercury lamp (relative intensity ratio: g-ray:h-ray:i-ray:j-ray=100:80:90:60). After irradiation, the resist film was heated at 110° C. for 90 seconds, and immersed in a 2.38% by mass TMAH alkaline developing solution for 60 seconds for development. Thereafter, the resist film was washed with ultrapure water for 30 seconds, and dried to form a 5 μm resist pattern.

The obtained line and space were observed in the formed resist pattern by a scanning electron microscope (S-4800 manufactured by Hitachi High-Technologies Corporation). As for the line edge roughness, a pattern having asperities of less than 5 nm was evaluated to be good.

In the case of using the radiation-sensitive composition according to each of Examples in Table 5, a good resist pattern with a resolution of 5 μm was able to be obtained. The roughness of the pattern was also small and good.

On the other hand, in the case of using the radiation-sensitive composition according to Comparative Example 4, a good resist pattern with a resolution of 5 μm was able to be obtained. However, the roughness of the pattern was large and poor.

As described above, it was found that each of the radiation-sensitive compositions according to Examples 1S to 6S can form a resist pattern that has small roughness and a good shape, as compared with the radiation-sensitive composition according to Comparative Example 4. As long as the above requirements of the present embodiment are met, radiation-sensitive compositions other than those described in Examples also exhibit the same effects.

### <Etching Resistance of Composition for Underlayer Film Formation for Lithography>

Each of the polymers obtained in Synthesis Working Examples has a relatively low molecular weight and a low viscosity. As such, it was evaluated that the embedding properties and film surface flatness of underlayer film forming materials for lithography containing these compounds or polymers can be relatively advantageously enhanced. Furthermore, each of these compounds or polymers has a thermal decomposition temperature of 430° C. or higher (evaluation A) and has high heat resistance, so that it was evaluated that they can be used even under high temperature baking conditions. In order to confirm these points, the following evaluation was performed assuming the application to the underlayer film.

### Examples 1U to 7U and Comparative Examples 5 and 6

### (Preparation of Composition for Underlayer Film Formation for Lithography)

Compositions for underlayer film formation for lithography were prepared according to the composition shown in Table 6. Next, a silicon substrate was spin coated with each of these compositions for underlayer film formation for lithography, and then baked at 240° C. for 60 seconds and further at 400° C. for 120 seconds to prepare each underlayer film having a film thickness of 200 nm. The following acid generating agent, crosslinking agent, and organic solvent were used.

Acid Generating Agent:
di-tertiary butyl diphenyliodonium nonafluoromethanesulfonate (DTDPI) manufactured by Midori Kagaku Co., Ltd.

Crosslinking Agent:
NIKALAC MX270 (NIKALAC) manufactured by Sanwa Chemical Co., Ltd.
TMOM-BP (compound represented by the following formula) manufactured by Honshu Chemical Industry Co., Ltd.

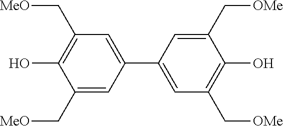 [SMILES: COCc1cc(-c2cc(COC)c(O)c(COC)c2)cc(COC)c1O]

Organic solvent: CHN, PGMEA
Novolac: PSM4357 manufactured by Gunei Chemical Industry Co., Ltd.

Next, etching test was conducted under conditions shown below to evaluate etching resistance. The evaluation results are shown in Table 6. Details of the evaluation method will be described later.

### <Etching Test>

Etching apparatus: RIE-10NR manufactured by Samco International, Inc.
Output: 50 W
Pressure: 20 Pa
Time: 2 min
Etching gas
Ar gas flow rate:CF₄ gas flow rate:O₂ gas flow rate=50:5:5 (sccm)

### <Evaluation of Etching Resistance>

The evaluation of etching resistance was conducted by the following procedures. First, an underlayer film of novolac was prepared under the same conditions as described above except that novolac (“PSM4357” manufactured by Gunei Chemical Industry Co., Ltd.) was used. This underlayer film of novolac was subjected to the above etching test, and the etching rate was measured.

Next, underlayer films of Examples and Comparative Examples 5 to 6 shown in Table 6 were prepared under the same conditions as the novolac underlayer films and subjected to the etching test in the same way as above, and the etching rate was measured. Then, the etching resistance for each of Examples and Comparative Example was evaluated according to the following evaluation criteria on the basis of the etching rate of the underlayer film of novolac.

### [Evaluation Criteria]

A: The etching rate was less than −20% as compared with the underlayer film of novolac.
B: The etching rate was −20% or more and 0% or less as compared with the underlayer film of novolac.
C: The etching rate was more than +0% as compared with the underlayer film of novolac.

TABLE 6

| | | | | Crosslinking | |
|---|---|---|---|---|---|
| | | | Acid generating | agent | |
| | Polymer | Solvent | agent | (parts by | Etching |
| | (parts by mass) | (parts by mass) | (parts by mass) | mass) | resistance |
| Example 1U | R1-1 | CHN | DTDPI | TMOM-BP | A |
| | (10) | (90) | (0.5) | (0.5) | |
| Example 2U | R1A-1 | CHN | DTDPI | TMOM-BP | A |
| | (10) | (90) | (0.5) | (0.5) | |
| Example 3U | R1B-1 | CHN | DTDPI | TMOM-BP | A |
| | (10) | (90) | (0.5) | (0.5) | |
| Example 4U | R1C-1 | CHN | DTDPI | TMOM-BP | A |
| | (10) | (90) | (0.5) | (0.5) | |
| Example 5U | R1D-1 | CHN | DTDPI | TMOM-BP | A |
| | (10) | (90) | (0.5) | (0.5) | |
| Example 6U | R1E-1 | CHN | DTDPI | TMOM-BP | A |
| | (10) | (90) | (0.5) | (0.5) | |
| Example 7U | R1A-1 | CHN/PGMEA | — | NIKALAC | A |
| | (10) | (81/9) | | (1.0) | |
| Comparative | CR-1 | CHN | DTDPI | NIKALAC | C |
| Example 5 | (10) | (90) | (0.5) | (0.5) | |
| Comparative | NBisN-1 | CHN | DTDPI | NIKALAC | B |
| Example 6 | (10) | (90) | (0.5) | (0.5) | |

As shown in Table 6, it was found that an excellent etching rate is exerted in each of Examples in the table as compared with the underlayer film of novolac and the underlayer films of Comparative Examples 5 to 6. On the other hand, it was found that in the underlayer film of Comparative Example 5 or 6, the etching rate was equal to or inferior to that of the underlayer film of novolac.

### Examples 8U to 14U and Comparative Example 7

Next, a SiO₂ substrate having a film thickness of 80 nm and a line and space pattern of 60 nm was coated with each of the compositions for underlayer film formation for lithography prepared in Examples and Comparative Example 5 in Table 6, and baked at 240° C. for 60 seconds to form a 90 nm underlayer film.

### (Evaluation of Embedding Properties)

The embedding properties were evaluated by the following procedures. The cross section of the film obtained under the above conditions was cut out and observed under an electron microscope to evaluate the embedding properties. The evaluation results are shown in Table 7.

### [Evaluation Criteria]

A: The underlayer film was embedded without defects in the asperities of the SiO₂ substrate having a line and space pattern of 50 nm.
C: The asperities of the SiO₂ substrate having a line and space pattern of 50 nm had defects which hindered the embedding of the underlayer film.

TABLE 7

| | Composition for underlayer film | |
|---|---|---|
| | formation for lithography | Embedding properties |
| Example 8U | Example 1U | A |
| Example 9U | Example 2U | A |
| Example 10U | Example 3U | A |
| Example 11U | Example 4U | A |
| Example 12U | Example 5U | A |
| Example 13U | Example 6U | A |
| Example 14U | Example 7U | A |
| Comparative | Comparative Example 5 | C |
| Example 7 | | |

It was found that embedding properties are good in each of Examples in Table 7. On the other hand, it was found that defects are seen in the asperities of the SiO₂ substrate and embedding properties are inferior in Comparative Example 7.

### Examples 15U to 21U

Next, a SiO₂ substrate having a film thickness of 300 nm was coated with the composition for underlayer film formation for lithography prepared in each of Examples in Table 6, and baked at 240° C. for 60 seconds and further at 400° C. for 120 seconds to form an underlayer film having a film thickness of 85 nm. This underlayer film was coated with a resist solution for ArF and baked at 130° C. for 60 seconds to form a photoresist layer having a film thickness of 140 nm.

The ArF resist solution used was prepared by compounding 5 parts by mass of a compound of the following formula (16), 1 part by mass of triphenylsulfonium nonafluoromethanesulfonate, 2 parts by mass of tributylamine, and 92 parts by mass of PGMEA.

The compound of the following formula (16) was prepared as follows. That is, 4.15 g of 2-methyl-2-methacryloyloxyadamantane, 3.00 g of methacryloyloxy-y-butyrolactone, 2.08 g of 3-hydroxy-1-adamantyl methacrylate, and 0.38 g of azobisisobutyronitrile were dissolved in 80 mL of tetrahydrofuran to prepare a reaction solution. This reaction solution was polymerized for 22 hours with the reaction temperature kept at 63° C. in a nitrogen atmosphere. Then, the reaction solution was added dropwise into 400 mL of n-hexane. The product resin thus obtained was solidified and purified, and the resulting white powder was filtered and dried overnight at 40° C. under reduced pressure to obtain a compound represented by the following formula (16).

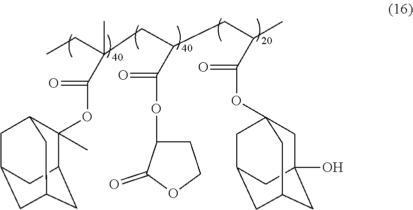

wherein 40, 40, and 20 represent the ratio of each constituent unit and do not represent a block copolymer.

Then, the photoresist layer was exposed using an electron beam lithography system (manufactured by ELIONIX INC.; ELS-7500, 50 keV), baked (PEB) at 115° C. for 90 seconds, and developed for 60 seconds in a 2.38% by mass tetramethylammonium hydroxide (TMAH) aqueous solution to obtain a positive type resist pattern.

### Comparative Example 8

The same operations as in Example 50 were performed except that no underlayer film was formed so that a photoresist layer was formed directly on a SiO₂ substrate to obtain a positive type resist pattern.

### [Evaluation]

Concerning each of Examples and Comparative Example 8 in Table 8, the shapes of the obtained 40 nm L/S (1:1) and 80 nm L/S (1:1) resist patterns were observed under an electron microscope manufactured by Hitachi, Ltd. “S-4800”. The shapes of the resist patterns after development were evaluated as “goodness” when having good rectangularity without pattern collapse, and as “poorness” if this was not the case. The smallest line width having good rectangularity without pattern collapse as a result of this observation was used as an index for resolution evaluation. The smallest electron beam energy quantity capable of lithographing good pattern shapes was used as an index for sensitivity evaluation. The results are shown in Table 8.

TABLE 8

| | Composition | | | Resist |
|---|---|---|---|---|
| | for under- | | | pattern |
| | layer film | | | shape |
| | formation for | Resolution | Sensitivity | after |
| | lithography | (nmL/S) | (μC/cm²) | development |
| Example 15U | Example 1U | 40 | 10 | Good |
| Example 16U | Example 2U | 40 | 10 | Good |
| Example 17U | Example 3U | 40 | 10 | Good |
| Example 18U | Example 4U | 40 | 10 | Good |
| Example 19U | Example 5U | 40 | 10 | Good |
| Example 20U | Example 6U | 40 | 10 | Good |
| Example 21U | Example 7U | 40 | 10 | Good |
| Comparative | None | 81 | 25 | Poor |
| Example 8 | | | | |

As is evident from Table 8, the resist pattern of each of Examples in the table was confirmed to be significantly superior in both resolution and sensitivity to Comparative Example 8. Such a result is considered to be due to the influence of the heteroatom. Also, the resist pattern shapes after development were confirmed to have good rectangularity without pattern collapse. The difference in the resist pattern shapes after development indicated that the underlayer film forming compositions for lithography of each of Examples in the table have good adhesiveness to a resist material.

### Example 22U

A SiO₂ substrate having a film thickness of 300 nm was coated with the composition for underlayer film formation for lithography prepared in Example 22U, and baked at 240° C. for 60 seconds and further at 400° C. for 120 seconds to form an underlayer film having a film thickness of 90 nm. This underlayer film was coated with a silicon-containing intermediate layer material and baked at 200° C. for 60 seconds to form an intermediate layer film having a film thickness of 35 nm. This intermediate layer film was further coated with the resist solution for ArF and baked at 130° C. for 60 seconds to form a photoresist layer having a film thickness of 150 nm. The silicon-containing intermediate layer material used was the silicon atom-containing polymer (polymer 1) described in <Synthesis Example 1> of Japanese Patent Laid-Open No. 2007-226170.

Then, the photoresist layer was mask exposed using an electron beam lithography system (manufactured by ELIONIX INC.; ELS-7500, 50 keV), baked (PEB) at 115° C. for 90 seconds, and developed for 60 seconds in 2.38% by mass tetramethylammonium hydroxide (TMAH) aqueous solution to obtain a 45 nm L/S (1:1) positive type resist pattern.

Thereafter, the silicon-containing intermediate layer film (SOG) was dry etched with the obtained resist pattern as a mask using “RIE-10NR” manufactured by Samco International, Inc. Subsequently, dry etching of the underlayer film using the obtained silicon-containing intermediate layer film pattern as a mask and dry etching of the SiO₂ film using the obtained underlayer layer film pattern as a mask were sequentially performed.

Respective etching conditions are as shown below.

(Conditions for Etching of Resist Intermediate Layer Film with Resist Pattern)
Output: 50 W
Pressure: 20 Pa
Time: 1 min

Etching Gas
Ar gas flow rate:CF₄ gas flow rate:O₂ gas flow rate=50:8:2 (sccm)
   (Conditions for Etching of Resist Underlayer Film with Resist Intermediate Film Pattern)
Output: 50 W
Pressure: 20 Pa
Time: 2 min

Etching Gas
Ar gas flow rate:CF₄ gas flow rate:O₂ gas flow rate=50:5:5 (sccm)
   (Conditions for Etching of SiO₂ Film with Resist Underlayer Film Pattern 9
Output: 50 W
Pressure: 20 Pa
Time: 2 min

Etching Gas
Ar gas flow rate:C₅F₁₂ gas flow rate:C₂F₆ gas flow rate:O₂ gas flow rate=50:4:3:1 (sccm)

### <Evaluation of Pattern Shape>

The pattern cross section (the shape of the SiO₂ film after etching) of Example 22U obtained as described above was observed under an electron microscope manufactured by Hitachi, Ltd. “S-4800”. As a result, it was confirmed that the shape of the SiO₂ film after etching in a multilayer resist process is a rectangular shape in Examples using the underlayer film of the present embodiment and is good without defects.

### <Characteristic Evaluation of Resin Film (Resin Single Film)>

### <Preparation of Resin Film>

### Example A01

Using PGMEA as a solvent, R1-1 of Synthesis Working Example 1 was dissolved to prepare a resin solution having a solid content concentration of 10% by mass (resin solution of Example A01).

The prepared resin solution was formed on a 12 inch silicon wafer using a spin coater Lithius Pro (manufactured by Tokyo Electron Limited), and after forming a film while adjusting the number of revolutions so as to have a film thickness of 200 nm, the baking was performed under the condition of a baking temperature of 250° C. for 1 minute to prepare a substrate on which a film made of the polymer (R1-1) was laminated. The prepared substrate was further baked under the condition of 350° C. for 1 minute using a hot plate capable of treating at a high temperature to obtain a cured resin film. At this time, when the change in film thickness before and after immersing the obtained cured resin film in the CHN tank for 1 minute was 3% or less, it was determined that the film was cured. When the curing was determined to be insufficient, the curing temperature was changed by 50° C. to investigate the curing temperature, and baking for curing was performed under the condition of the lowest temperature in the curing temperature range.

### <Optical Characteristic Values Evaluation>

The prepared resin film was evaluated for optical characteristic values (refractive index n and extinction coefficient k as optical constants) using spectroscopic ellipsometry VUV-VASE (manufactured by J.A. Woollam).

### Examples A02 to A06 and Comparative Example A01

The resin film was prepared in the same manner as in Example A01 except that the polymers used were changed from the polymer (R1-1) to the polymers shown in Table 9, and the optical characteristic values were evaluated.

### [Evaluation Criteria] Refractive Index n

A: 1.4 or more
C: less than 1.4

### [Evaluation Criteria] Extinction Coefficient k

A: less than 0.5
C: 0.5 or more

TABLE 9

| | | Optical | |
|---|---|---|---|
| | | characteristic values | |
| | Used polymer | n | k |
| Example A01 | R1-1 | A | A |
| Example A02 | R1A-1 | A | A |
| Example A03 | R2A-1 | A | A |
| Example A04 | R3A-1 | A | A |
| Example A05 | R4A-1 | A | A |
| Example A06 | R5A-1 | A | A |
| Comparative | CR-1 (Comparative | C | C |
| Example A01 | Synthesis Example 2) | | |

From the results of Examples A01 to A06, it was found that a resin film having a high n-value and a low k-value at wavelengths 193 nm used in ArF exposure can be formed by the composition for film formation containing the polymer of the present embodiment.

### <Heat Resistance Evaluation of Cured Film>

### Example B01

The heat resistance of the resin film prepared in Example A01 was evaluated by using a lamp annealing oven. As the heat treatment resistance condition, heating was continued at 450° C. in a nitrogen atmosphere, and a film thickness change rate was obtained by comparing the film thickness after an elapsed time of 4 minutes from the start of heating and the film thickness after an elapsed time of 10 minutes. In addition, heating was continued at 550° C. in a nitrogen atmosphere, and a film thickness change rate was obtained by comparing the film thickness after an elapsed time of 4 minutes from the start of heating and the film thickness after an elapsed time of 10 minutes at 550° C. These film thickness change rates were evaluated as indicators of the heat resistance of the cured film. The film thicknesses before and after the heat resistance test were measured by an interference film thickness meter, and a ratio of the fluctuation value of the film thickness to the film thickness before the heat resistance test treatment was defined as a film thickness change rate (%)

### [Evaluation Criteria]

A: Film thickness change rate is less than 10%.
B: Film thickness change rate is 10% or more and 15% or less.
C: Film thickness change rate is more than 15%.

### Examples B02 to B06 and Comparative Examples B01 to B02

Heat resistance was evaluated in the same manner as in Example B01 except that the polymers used were changed from the polymer (R1-1) to the polymers shown in Table 10.

TABLE 10

| | | Cured film heat | Film thickness |
|---|---|---|---|
| | | resistance | change rate % |
| | Used polymer | 450° C. | 550° C. |
| Example B01 | R1-1 | A | A |
| Example B02 | R1A-1 | A | A |
| Example B03 | R2A-1 | A | A |
| Example B04 | R3A-1 | A | A |
| Example B05 | R4A-1 | A | A |
| Example B06 | R5A-1 | A | A |
| Comparative | CR-1 | C | C |
| Example B01 | | | |
| Comparative | NBisN-1 | B | B |
| Example B02 | | | |

From the results of Examples B01 to B06, it was found that a resin film having high heat resistance with little change in film thickness even at a temperature of 550° C. can be formed by using a film forming composition containing the polymer of the present embodiment as compared with Comparative Examples B01 and B02.

### Example C01

### <Evaluation of PE-CVD Film Formation>

A 12 inch silicon wafer was subjected to thermal oxidation treatment, and a resin film was formed on the substrate having the obtained silicon oxide film by the same method as in Example A01 using the resin solution of Example A01 with a thickness of 100 nm. A silicon oxide film having a film thickness of 70 nm was formed on the resin film using a film forming apparatus TELINDY (manufactured by Tokyo Electron Limited) and tetraethylsiloxane (TEOS) as a raw material at a substrate temperature of 300° C. The wafer with the cured film in which the prepared silicon oxide film was laminated was further subjected to defect inspection using a defect inspection device “SP5” (manufactured by KLA-Tencor), and the number of defects of the formed oxide film was evaluated according to the following criteria using the number of defects of 21 nm or more as an index.

### (Criteria)

A number of defects≤20
B 20<number of defects≤50
C 50<number of defects≤100
D 100<number of defects≤1000
E 1000<number of defects≤5000
F 5000≤number of defects

### <Evaluation of SiN Film>

On a cured film formed on a substrate having a silicon oxide film thermally oxidized on a 12 inch silicon wafer with a thickness of 100 nm by the same method as described above, a film forming apparatus TELINDY (manufactured by Tokyo Electron Limited) was used to form a SiN film having a thickness of 40 nm, a refractive index of 1.94, and a film stress of −54 MPa at a substrate temperature of 350° C. using SiH₄ (monosilane) and ammonia as raw materials. The wafer with the cured film in which the prepared SiN film was laminated was further subjected to defect inspection using a defect inspection device “SP5” (manufactured by KLA-tencor), and the number of defects of the formed oxide film was evaluated according to the following criteria using the number of defects of 21 nm or more as an index.

### (Criteria)

A number of defects≤20
B 20<number of defects≤50
C 50<number of defects≤100
D 100<number of defects≤1000
E 1000<number of defects≤5000
F 5000≤number of defects

### Examples C02 to C06 and Comparative Examples C01 to C02

Defect evaluation of the film was performed in the same manner as in Example C01 except that the resins used were changed from the polymer (R1-1) to the resins shown in Table 11.

TABLE 11

| | | PE-CVD defect evaluation | |
|---|---|---|---|
| | Used polymer | Oxide film | SiN film |
| Example C01 | R1-1 | B | B |
| Example C02 | R1A-1 | B | B |
| Example C03 | R2A-1 | B | B |
| Example C04 | R3A-1 | B | B |
| Example C05 | R4A-1 | B | B |
| Example C06 | R5A-1 | B | B |
| Comparative | CR-1 (Comparative | F | F |
| Example C01 | Synthesis Example 2) | | |
| Comparative | NBisN-1 | E | E |
| Example C02 | | | |

In the silicon oxide film or SiN film formed on the resin film of Examples C01 to C06, the number of defects of 21 nm or more was 50 or less (B or higher), which was smaller than the number of defects of Comparative Example C01 or C02.

### Example D01

<Etching Evaluation after High Temperature Treatment>

A 12 inch silicon wafer was subjected to thermal oxidation treatment, and a resin film was formed on the substrate having the obtained silicon oxide film by the same method as in Example A01 using the resin solution of Example A01 with a thickness of 100 nm. The resin film was further annealed by heating under the condition of 600° C. for 4 minutes using a hot plate which can be further treated at a high temperature in a nitrogen atmosphere to prepare a wafer on which the annealed resin film was laminated. The prepared annealed resin film was carved out, and the carbon content was determined by elemental analysis.

Furthermore, a 12 inch silicon wafer was subjected to thermal oxidation treatment, and a resin film was formed on the substrate having the obtained silicon oxide film by the same method as in Example A01 using the resin solution of Example A01 with a thickness of 100 nm. The resin film was further annealed by heating under the condition of 600° C. for 4 minutes under a nitrogen atmosphere to form a resin film, and then the substrate was subjected to an etching treatment using an etching apparatus “TELIUS” (manufactured by Tokyo Electron Limited) under the conditions of using CF₄/Ar as an etching gas and Cl₂/Ar as an etching gas to evaluate an etching rate. The etching rate was evaluated by using a resin film having a film thickness of 200 nm formed by annealing a photoresist “SU8 3000” manufactured by Nippon Kayaku Co., Ltd. at 250° C. for 1 minute as a reference and determining the ratio of the etching rate to the SU8 3000 as a relative value according to the following evaluation criteria.

### [Evaluation Criteria]

A: The etching rate was less than −20% as compared with the resin film of SU8 3000.
B: The etching rate was −20% or more and 0% or less as compared with the resin film of SU8 3000.
C: The etching rate was more than +0% as compared with the resin film of SU8 3000.

### Examples D02 to D06, Reference Example D01, and Comparative Examples D01 to D02

Etching rate was evaluated in the same manner as in Example D01 except that the polymers used were changed from the polymer (R1-1) to the polymers shown in Table 12.

TABLE 12

| | | | Etching rate evaluation | |
|---|---|---|---|---|
| | | Carbon | (relative value) | |
| | | content | CF₄/ | Cl₂/ |
| | Used polymer | (%) | Ar | Ar |
| Example D01 | R1-1 | A | A | A |
| Example D02 | RA-1 | A | A | A |
| Example D03 | R2A-1 | A | A | A |
| Example D04 | R3A-1 | A | A | A |
| Example D05 | R4A-1 | A | A | A |
| Example D06 | R5A-1 | A | A | A |
| Comparative | CR-1 (Comparative | B | B | B |
| Example D01 | Synthesis Example 2) | | | |
| Comparative | NBisN-1 | B | B | B |
| Example D02 | | | | |

From the results of Examples D01 to D06, it was found that a resin film excellent in etching resistance after high temperature treatment can be formed when a composition containing the polymer of the present embodiment is used as compared with Comparative Examples D01 and D02.

### [Defect Evaluation Before and After Purification Treatment]

### <Evaluation of Etching Defects on Laminated Film>

The polymers obtained in Synthesis Working Examples below were subjected to quality evaluation before and after the purification treatment. That is, before and after the purification treatment described below, the resin film formed on the wafer using the polymer was transferred to the substrate side by etching, and then subjected to defect evaluation to evaluate.

A 12-inch silicon wafer was subjected to thermal oxidation treatment to obtain a substrate having a silicon oxide film having a thickness of 100 nm. The resin solution of the polymer was formed on the substrate by adjusting the spin coating conditions so as to have a thickness of 100 nm, followed by baking at 150° C. for 1 minute, and then baking at 350° C. for 1 minute to prepare a laminated substrate in which the polymer was laminated on silicon with a thermal oxide film.

Using “TELIUS” (manufactured by Tokyo Electron Limited) as an etching apparatus, the resin film was etched under the condition of CF₄/O₂/Ar to expose the substrate on the surface of the oxide film. Further, an etching treatment was performed under the condition that the oxide film was etched by 100 nm at the gas composition ratio of CF₄/Ar to prepare an etched wafer.

The prepared etched wafer was measured for the number of defects of 19 nm or more with a defect inspection device SP5 (manufactured by KLA-tencor), and was subjected to defect evaluation by etching treatment of the laminated film according to the following criteria.

### (Criteria)

A number of defects<20
B 20<number of defects≤50
C 50<number of defects≤100
D 100<number of defects≤1000
E 1000<number of defects≤5000
F 5000≤number of defects

### [Example E01] Purification of Polymer (R1-1) with Acid

In a four necked flask (capacity: 1000 mL, with a detachable bottom), 150 g of a solution (10% by mass) formed by dissolving the polymer (R1-1) obtained in Synthesis Working Example 1 in CHN was charged, and was heated to 80° C. with stirring. Then, 37.5 g of an aqueous oxalic acid solution (pH 1.3) was added thereto, and the resultant mixture was stirred for 5 minutes and then left to stand still for 30 minutes. This separated the mixture into an oil phase and an aqueous phase, and the aqueous phase was thus removed. After repeating this operation once, 37.5 g of ultrapure water was charged to the obtained oil phase, and after stirring for 5 minutes, the mixture was left to stand still for 30 minutes and the aqueous phase was removed. After repeating this operation three times, the residual water and CHN were concentrated and distilled off by heating to 80° C. and reducing the pressure in the flask to 200 hPa or less. Thereafter, by diluting with CHN of EL grade (a reagent manufactured by Kanto Chemical Co., Inc.) such that the concentration of the CHN solution was adjusted to 10% by mass, a CHN solution of R1-1 with a reduced metal content was obtained. The polymer solution thus prepared was filtered with a UPE filter having a nominal pore size of 3 nm, manufactured by Entegris Japan Co., Ltd., under a condition of 0.5 MPa, to prepare a solution sample.

For each of the solution samples before and after the purification treatment, a resin film was formed on the wafer as described above, the resin film was transferred to the substrate side by etching, and then etching defect evaluation was performed on the laminated film.

### [Example E02] Purification of Polymer (R1A-1) with Acid

In a four necked flask (capacity: 1000 mL, with a detachable bottom), 140 g of a solution (10% by mass) formed by dissolving the polymer (R1A-1) obtained in Synthesis Working Example 1A-1 in CHN was charged, and was heated to 60° C. with stirring. Then, 37.5 g of an aqueous oxalic acid solution (pH 1.3) was added thereto, and the resultant mixture was stirred for 5 minutes and then left to stand still for 30 minutes. This separated the mixture into an oil phase and an aqueous phase, and the aqueous phase was then removed. After repeating this operation once, 37.5 g of ultrapure water was charged to the obtained oil phase, and after stirring for 5 minutes, the mixture was left to stand still for 30 minutes and the aqueous phase was removed. After repeating this operation three times, the residual water and CHN were concentrated and distilled off by heating to 80° C. and reducing the pressure in the flask to 200 hPa or less. Thereafter, by diluting with CHN of EL grade (a reagent manufactured by Kanto Chemical Co., Inc.) such that the concentration of the CHN solution was adjusted to 10% by mass, a CHN solution of a polymer (R1A-1) with a reduced metal content was obtained. The polymer solution thus prepared was filtered with a UPE filter having a nominal pore size of 3 nm, manufactured by Entegris Japan Co., Ltd., under a condition of 0.5 MPa, to prepare a solution sample, and then etching defect evaluation on the laminated film was carried out in the same manner as in Example E01.

### [Example E03] Purification by Passing Through Filter

In a class 1000 clean booth, 500 g of a solution of 10% by mass concentration of the polymer (R1-1) obtained in Synthesis Working Example 1-1 dissolved in CHN was charged in a four necked flask (capacity: 1000 mL, with a detachable bottom), and then the air inside the flask was depressurized and removed, nitrogen gas was introduced to return it to atmospheric pressure, and the oxygen concentration inside was adjusted to less than 1% under the ventilation of 100 mL of nitrogen gas per minute, and the flask was heated to 30° C. with stirring. The solution was drawn out from the bottom-vent valve, and passed through a pressure tube made of fluororesin through a diaphragm pump at a flow rate of 100 mL per minute to a hollow fiber membrane filter (manufactured by KITZ MICRO FILTER CORPORATION, trade name: Polyfix Nylon Series) made of nylon with a nominal pore size of 0.01 μm under a filtration pressure of 0.5 MPa by pressure filtration. By diluting the resin solution after filtration with CHN of EL grade (a reagent manufactured by Kanto Chemical Co., Inc.) such that the concentration of the CHN solution was adjusted to 10% by mass, a CHN solution of the polymer (R1-1) with a reduced metal content was obtained. The polymer solution thus prepared was filtered with a UPE filter having a nominal pore size of 3 nm, manufactured by Entegris Japan Co., Ltd., under a condition of 0.5 MPa, to prepare a solution sample, and then etching defect evaluation on the laminated film was carried out in the same manner as in Example E01. The oxygen concentration was measured with an oxygen concentration meter “OM-25MF10” manufactured by AS ONE Corporation (the same applies hereinafter).

### Example E04

As the purification step by the filter, “IONKLEEN” manufactured by Pall Corporation, “Nylon Filter” manufactured by Pall Corporation, and a UPE filter with a nominal pore size of 3 nm manufactured by Entegris Japan Co., Ltd. were connected in series in this order to construct a filter line. In the same manner as in Example E03, except that the prepared filter line was used instead of the 0.1 μm hollow fiber membrane filter made of nylon, the solution was passed by pressure filtration so that the conditions of the filtration pressure was 0.5 MPa. By diluting with CHN of EL grade (a reagent manufactured by Kanto Chemical Co., Inc.) such that the concentration of the CHN solution was adjusted to 10% by mass, a CHN solution of a polymer (R1-1) with a reduced metal content was obtained. The polymer solution thus prepared was subjected to pressure filtration with a UPE filter having a nominal pore size of 3 nm, manufactured by Entegris Japan Co., Ltd., under a condition of the filtration pressure of 0.5 MPa, to prepare a solution sample, and then etching defect evaluation on the laminated film was carried out in the same manner as in Example E01.

### Example E05

The solution sample prepared in Example E01 was further subjected to pressure filtration with the filter line prepared in Example E04 under a condition of the filtration pressure of 0.5 MPa, to prepare a solution sample, and then etching defect evaluation on the laminated film was carried out in the same manner as in Example E01.

### Example E06

For the polymer (R1A-1) prepared in Synthesis Working Example 1A-1, a solution sample purified by the same method as in Example E05 was prepared, and then an etching defect evaluation on the laminated film was carried out in the same manner as in Example E01.

### Example E06-1

For the polymer (R1E-1) prepared in Synthesis Working Example 1E-1, a solution sample purified by the same method as in Example E05 was prepared, and then an etching defect evaluation on the laminated film was carried out in the same manner as in Example E01.

### Example E07

For the polymer (R1B-1) prepared in Synthesis Working Example 3, a solution sample purified by the same method as in Example E05 was prepared, and then an etching defect evaluation on the laminated film was carried out.

TABLE 13

| | | PE-CVD defect evaluation | |
|---|---|---|---|
| | | Before purification | After purification |
| | Used resin | treatment | treatment |
| Example E01 | R1-1 | B | A |
| Example E02 | R1A-1 | B | A |
| Example E03 | R1-1 | B | A |
| Example E04 | R1-1 | B | A |
| Example E05 | R1-1 | B | A |
| Example E06 | R1A-1 | B | A |
| Example E06-1 | R1E-1 | B | A |
| Example E07 | R1B-1 | B | A |

From the results of Examples E01 to E07, it was found that the quality of the obtained resin film was further improved when the composition containing the polymer of the present embodiment was used, as compared with when the polymer before purification treatment was used.

### Examples 1L to 7L and Comparative Example 9

A SiO₂ substrate having a film thickness of 300 nm was coated with the composition for optical member formation having the same composition as that of the solution of the underlayer film forming compositions for lithography prepared in each of Examples and Comparative Example 5 in Table 6, and baked at 260° C. for 300 seconds to form each film for optical members with a film thickness of 100 nm. Then, tests for the refractive index and the transparency at a wavelength of 633 nm were carried out by using a vacuum ultraviolet with variable angle spectroscopic ellipsometer “VUV-VASE” manufactured by J.A. Woollam Japan, and the refractive index and the transparency were evaluated according to the following criteria. The evaluation results are shown in Table 14.

### [Evaluation Criteria for Refractive Index]

A: The refractive index is 1.60 or more.
C: The refractive index is less than 1.60.

### [Evaluation Criteria for Transparency]

A: The extinction constant is less than 0.03.
C: The extinction constant is 0.03 or more.

TABLE 14

| | Composition for optical | Refractive | |
|---|---|---|---|
| | member formation | index | Transparency |
| Example 1L | Same composition as | A | A |
| | Example 1U | | |
| Example 2L | Same composition as | A | A |
| | Example 2U | | |
| Example 3L | Same composition as | A | A |
| | Example 3U | | |
| Example 4L | Same composition as | A | A |
| | Example 4U | | |
| Example 5L | Same composition as | A | A |
| | Example 5U | | |
| Example 6L | Same composition as | A | A |
| | Example 6U | | |
| Example 7L | Same composition as | A | A |
| | Example 7U | | |
| Comparative | Same composition as | C | C |
| Example 9 | Comparative Example 5 | | |

It was found that the compositions for optical member formation of each of Examples in the table not only had a high refractive index but also a low absorption coefficient and excellent transparency. On the other hand, it was found that the composition of Comparative Example 9 was inferior in performance as an optical member.

### [Synthesis Working Examples X1 to X2] Synthesis of Polymers (R1A-16) to (R1A-17)

Polymers (R1A-16) to (R1A-17) were synthesized in the same manner as in Synthesis Working Example 1A-1, except that the following compounds (1A-16) to (1A-17) were used instead of the compound (1A-1), respectively. The compound (1A-16) is a mixture of o-, m-, and p-substituted compounds.

As shown below, in the polymers (R1A-16) to (R1A-17), the following peaks were found by 400 MHz-1H-NMR, and it was confirmed that each of the polymers had a chemical structures of the above formulas as a basic structure, and had a structure in which aromatic rings of the constituent units were directly bonded to each other. Further, the results of measuring the polystyrene equivalent molecular weight by the above method for each of the obtained polymers are also shown.

### (R1A-16)

Mn: 863, Mw: 1126, Mw/Mn: 1.3

δ (ppm) 9.5-10.0 (4H, O—H), 7.2-8.5 (23H, Ph-H), 6.2-6.9 (2H, Ph-H), 6.7-6.9 (1H, C—H)

### (R1A-17)

Mn: 789, Mw: 916, Mw/Mn: 1.2

δ (ppm) 9.5-10.0 (4H, O—H), 7.2-8.5 (23H, Ph-H), 6.2-6.9 (2H, Ph-H), 6.7-6.9 (1H, C—H)

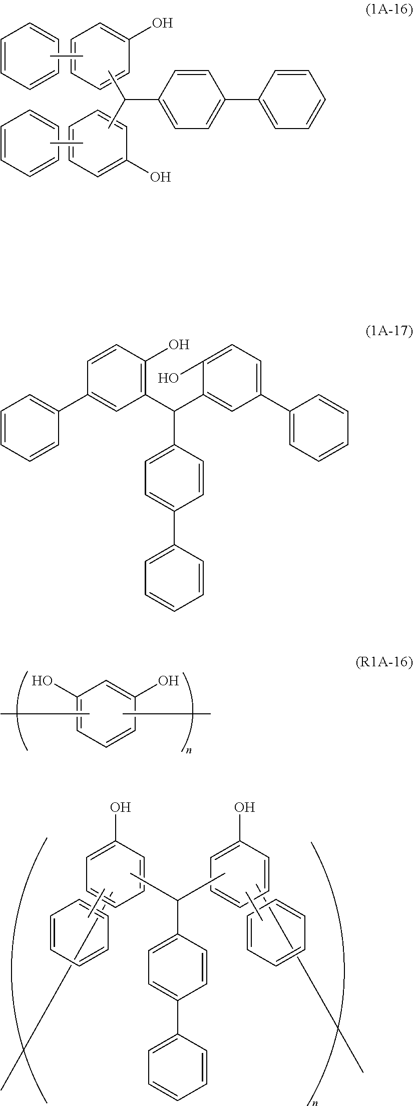

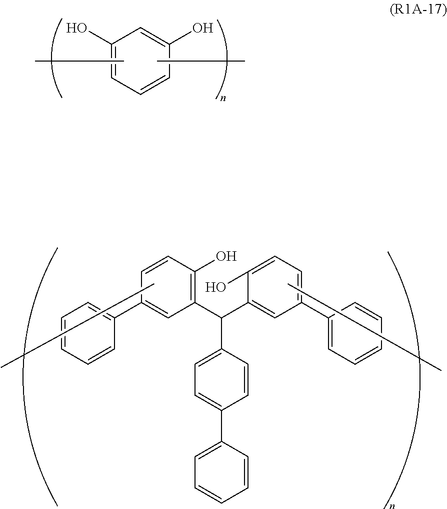

### [Synthesis Working Examples X3 to X5] Synthesis of Polymers (R1B-9) to (R1B-11)

Polymers (R1B-9) to (R1B-11) were synthesized in the same manner as in Synthesis Working Example 1B-1, except that the following compounds (1B-9) to (1B-11) were used instead of the compound (1B-1), respectively. The compound (1B-11) is a mixture of o-, m-, and p-substituted compounds.

As shown below, in the polymers (R1B-9) to (R1B-11), the following peaks were found by 400 MHz-1H-NMR, and it was confirmed that each of the polymers had a chemical structures of the above formulas as a basic structure, and had a structure in which aromatic rings of the constituent units were directly bonded to each other. Further, the results of measuring the polystyrene equivalent molecular weight by the above method for each of the obtained polymers are also shown.

### (R1B-9)

Mn: 700, Mw: 870, Mw/Mn: 1.2

δ (ppm) 10.0 (2H, —OH) 9.0-9.2 (1H, —OH), 7.1-8.0 (7H, Ph-H), 6.3-7.0 (2H, Ph-H)

### (R1B-10)

Mn: 1805, Mw: 2122, Mw/Mn: 1.2

δ (ppm) 10.0 (2H, —OH) 9.0-9.2 (1H, —OH), 7.0-8.0 (7H, Ph-H), 6.3-7.0 (2H, Ph-H)

### (R1B-11)

Mn: 1508, Mw: 1912, Mw/Mn: 1.3

δ (ppm) 10.0 (2H, —OH) 9.0-9.2 (1H, —OH), 7.0-8.0 (7H, Ph-H), 6.3-7.0 (2H, Ph-H)

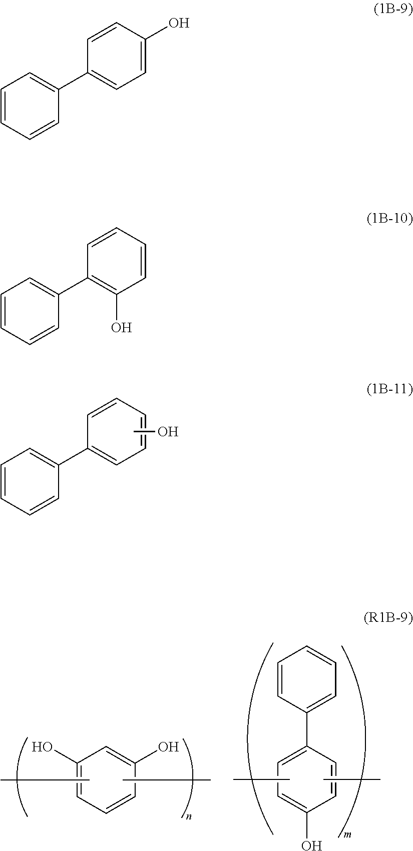

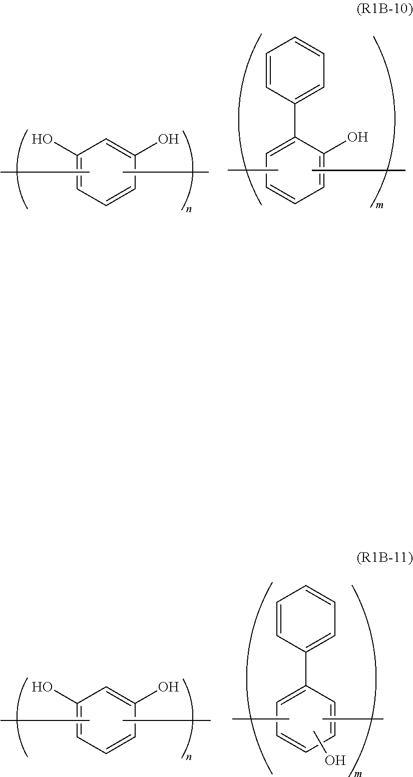

### [Synthesis Working Examples X6 to X8] Synthesis of Polymers (RX6) to (RX8)

Polymer (RX6) to (RX8) were synthesized in the same manner as in Synthesis Working Example 1A-5, except that the following compounds (X6; catechol), (X7; 3,3′-dimethylbiphenyl-4,4′-diol), and (X8; diaminobenzene) were used instead of resorcinol, respectively.

As shown below, in the polymers (RX6) to (RX8), the following peaks were found by 400 MHz-1H-NMR, and it was confirmed that each of the polymers had a chemical structures of the above formulas as a basic structure, and had a structure in which aromatic rings of the constituent units were directly bonded to each other. Further, the results of measuring the polystyrene equivalent molecular weight by the above method for each of the obtained polymers are also shown.

### (RX6)

Mn: 1021, Mw: 1125, Mw/Mn: 1.1

δ (ppm) 10.0 (2H, —OH), 8.6-9.1 (2H, O—H), 7.2-8.5 (17H, Ph-H), 6.3-7.0 (2H, Ph-H), 6.7-6.9 (1H, C—H)

### (RX7)

Mn: 743, Mw: 810, Mw/Mn: 1.1

δ (ppm) 10.0 (2H, —OH), 9.4-9.6 (2H, O—H), 7.2-6.3 (23H, Ph-H), 6.7-6.9 (1H, C—H), 2.0-2.1 (6H, CH₂—H)

### (RX8)

Mn: 1021, Mw: 1125, Mw/Mn: 1.1

δ (ppm) 10.3 (2H, NH—H), 9.4-9.6 (2H, —OH), 7.0-8.5 (18H, Ph-H), 6.7-6.9 (1H, C—H), 5.8-6.2 (1H, Ph-H)

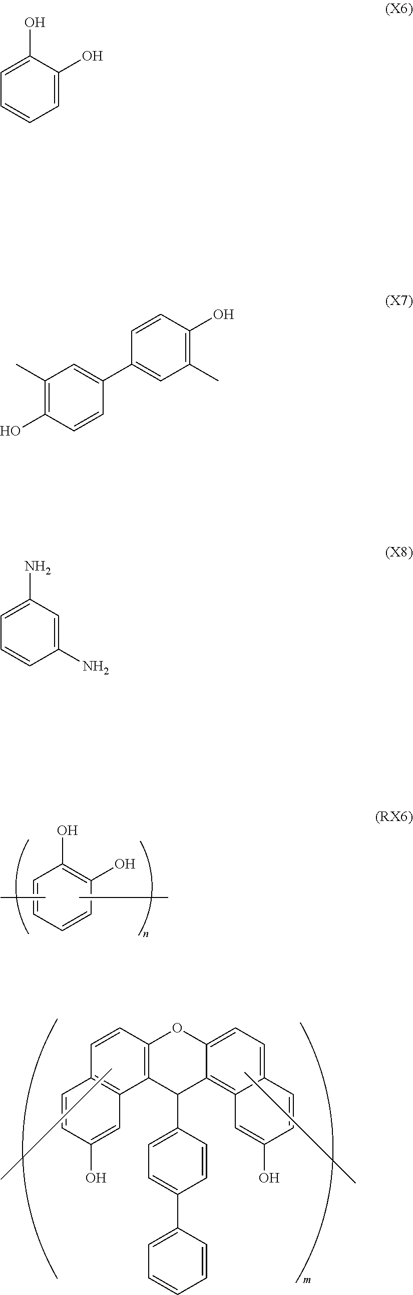

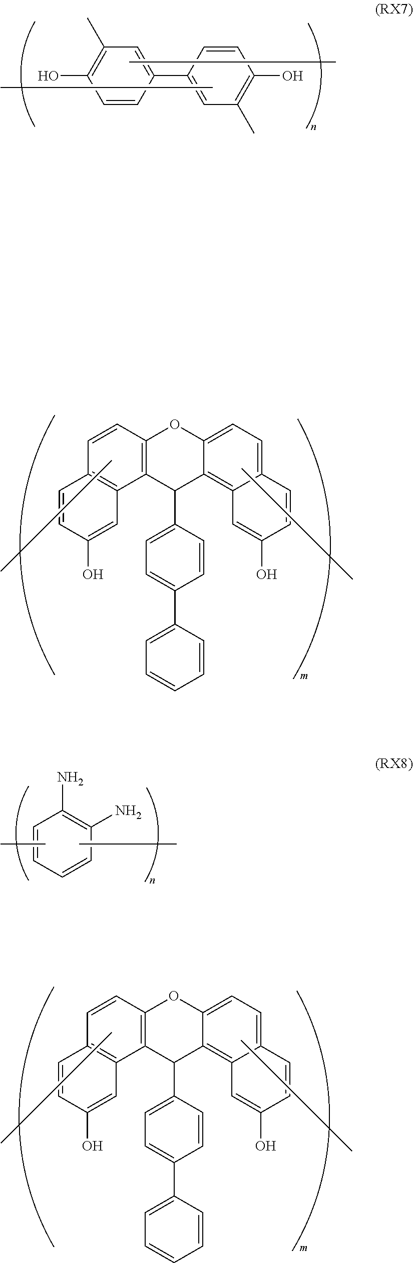

### [Synthesis Working Examples X9 to X11] Synthesis of Polymers (RX9) to (RX11)

Polymer (RX9) to (RX11) were synthesized in the same manner as in Synthesis Working Example X3, except that the above compound (X6; catechol), the above compound (X7; 3,3′-dimethylbiphenyl-4,4′-diol), and the above compound (X8; diaminobenzene) were used instead of resorcinol, respectively.

As shown below, in the polymers (RX9) to (RX11), the following peaks were found by 400 MHz-1H-NMR, and it was confirmed that each of the polymers had a chemical structures of the above formulas as a basic structure, and had a structure in which aromatic rings of the constituent units were directly bonded to each other. Further, the results of measuring the polystyrene equivalent molecular weight by the above method for each of the obtained polymers are also shown.

### (RX9)

Mn: 750, Mw: 860, Mw/Mn: 1.1

δ (ppm) 10.0 (2H, —OH), 9.0-9.3 (1H, —OH), 7.1-8.0 (7H, Ph-H), 6.3-7.0 (2H, Ph-H)

### (RX10)

Mn: 704, Mw: 801, Mw/Mn: 1.1

δ (ppm) 10.0 (2H, —OH), 9.0-9.5 (3H, —OH), 6.3-8.0 (11H, Ph-H), 2.0-2.1 (6H, CH₂—H)

### (RX11)

Mn: 700, Mw: 870, Mw/Mn: 1.2

δ (ppm) 10.3 (2H, NH—H), 9.0-9.2 (1H, —OH), 7.1-8.0 (7H, Ph-H), 7.0-5.7 (2H, Ph-H)

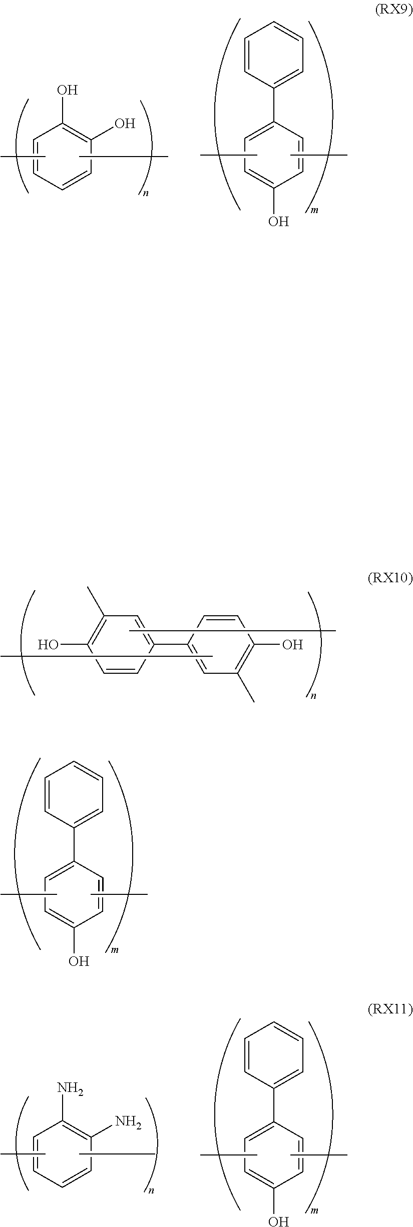

### Examples X1 to X11

The polymers obtained in Synthesis Working Examples X1 to X11 were evaluated for heat resistance and solubility in the same manner as in Example 1. The results are shown in the following Table.

TABLE 15

| | | Heat resistance | Solubility |
|---|---|---|---|
| | Polymer | evaluation | evaluation |
| Example X1 | R1A-16 | A | A |
| Example X2 | R1A-17 | A | A |
| Example X3 | R1B-9 | A | A |
| Example X4 | R1B-10 | A | A |
| Example X5 | R1B-11 | A | A |
| Example X6 | RX6 | A | A |
| Example X7 | RX7 | A | A |
| Example X8 | RX8 | A | A |
| Example X9 | RX9 | A | A |
| Example X10 | RX10 | A | A |
| Example X11 | RX11 | A | A |

### Examples X1A to X11A

In Example 43, compositions for underlayer film formation for lithography were prepared in the same manner as in Example 43, except that the polymers described in the following table were used instead of the polymer R1-1 obtained in Synthesis Working Example 1-1. Next, a silicon substrate was spin coated with each of these compositions for underlayer film formation for lithography, and then baked at 240° C. for 60 seconds and further at 400° C. for 120 seconds under a nitrogen gas atmosphere to prepare each underlayer film having a film thickness of 200 to 250 nm. For each of the obtained underlayer films, etching test was carried out in the same manner as in Example 43 to evaluate the etching resistance.

TABLE 16

| | Polymer (parts | Solvent (parts | Etching |
|---|---|---|---|
| | by mass) | by mass) | evaluation |
| Example X1A | R1A-16 | CHN | A |
| | (10) | (90) | |
| Example X2A | 1A-17 | CHN | A |
| | (10) | (90) | |
| Example X3A | R1B-9 | CHN | A |
| | (10) | (90) | |
| Example X4A | R1B-10 | CHN | A |
| | (10) | (90) | |
| Example X5A | R1B-11 | CHN | A |
| | (10) | (90) | |
| Example X6A | RX6 | CHN | A |
| | (10) | (90) | |
| Example X7A | RX7 | CHN | A |
| | (10) | (90) | |
| Example X8A | RX8 | CHN | B |
| | (10) | (90) | |
| Example X9A | RX9 | CHN | A |
| | (10) | (90) | |
| Example X10A | RX10 | CHN | A |
| | (10) | (90) | |
| Example X11A | RX11 | CHN | B |
| | (10) | (90) | |

As shown in the above table, Examples X9A and X11A having a unit derived from diaminobenzene were evaluated as “B” in the etching evaluation, but the other Examples were evaluated as “A” and were more excellent.

### Examples Z1 to Z4

### [Stability Test]

At 23° C., each of the polymers obtained in Examples described in the following table was dissolved in propylene glycol monomethyl ether (PGME) to form a 10% by mass solution to prepare a composition for underlayer film formation for lithography having the composition shown in the table. Thereafter, the composition was stored at 10° C. for 30 days. A silicon substrate was spin coated with each of these compositions for underlayer film formation for lithography, and then baked at 400° C. for 60 seconds to prepare each underlayer film with a film thickness of 200 nm. The prepared underlayer film was further subjected to defect inspection using a defect inspection device “SP5” (manufactured by KLA-Tencor), and the number of defects of the formed underlayer film was evaluated according to the following criteria using the number of defects of 21 nm or more as an index.

### [Criteria]

A number of defects≤20
B 20<number of defects≤50
C 50<number of defects≤100

TABLE 17

| | | | Solvent (parts | Stability |
|---|---|---|---|---|
| | Polymer (parts by mass) | | by mass) | test |
| Example Z1 | Synthesis Working | R1A-5 | PGME | A |
| | Example 1A-5 | (10) | (90) | |
| Example Z2 | Synthesis Working | RX6 | PGME | B |
| | Example X6 | (10) | (90) | |
| Example Z3 | Synthesis Working | RX7 | PGME | B |
| | Example X7 | (10) | (90) | |
| Example Z4 | Synthesis Working | RX8 | PGME | B |
| | Example X8 | (10) | (90) | |

As shown in the above table, Example Z1 in which resorcinol was used as the monomer represented by the formula (0) was superior to Examples Z2 to Z4 in which catechol, 3,3′-dimethylbiphenyl-4,4′-diol, or diaminobenzene was used as the monomer represented by the formula (0) in the stability evaluation result.

### INDUSTRIAL APPLICABILITY

The present invention provides a novel polymer having sites in which aromatic rings of a monomer represented by the formula (0) are linked without a crosslinking group, that is, a novel polymer in which aromatic rings are linked by a direct bond. Such a polymer is excellent in heat resistance, etching resistance, solvent solubility and the like, particularly excellent in heat resistance and etching resistance, and can be used as a coating agent for semiconductors, a material for resists, and a semiconductor underlayer film forming material.

The present invention has industrial applicability as a composition that can be used in optical members, photoresist components, resin raw materials for materials for electric or electronic components, raw materials for curable resins such as photocurable resins, resin raw materials for structural materials, or resin curing agents, etc.

The disclosure of Japanese Patent Application No. 2021-006655 filed on Jan. 19, 2021, is incorporated herein by reference in its entirety.

All reference documents, patent applications, and technical standards described in the specification are incorporated by reference herein to the same extent as if each of those reference documents, patent applications, and technical standards were specifically and individually described as being incorporated by reference.

1. A polymer comprising a constituent unit derived from a monomer represented by the following formula (0),
wherein the polymer has sites in which the constituent units are linked by direct bonding between aromatic rings: 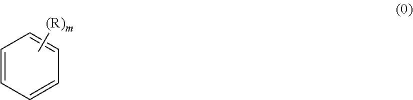
wherein R is a monovalent group, and m is an integer of 1 to 5, wherein at least one R is a hydroxyl group, an alkoxy group having 1 to 40 carbon atoms and optionally having a substituent, or an amino group having 0 to 40 carbon atoms and optionally having a substituent.

2. The polymer according to claim 1, wherein in the formula (0), m is 2 or more, and at least two R are a hydroxyl group, an alkoxy group having 1 to 40 carbon atoms and optionally having a substituent, or an amino group having 0 to 40 carbon atoms and optionally having a substituent.

3. The polymer according to claim 1, further comprising a constituent unit derived from an other copolymerizable compound that is copolymerizable with the monomer represented by the formula (0), wherein a molar ratio (x:y) of the constituent unit (x) derived from the monomer represented by the formula (0) to the constituent unit derived from the other copolymerizable compound (y) is 1:99 to 99:1.

4. The polymer according to claim 3, wherein the other copolymerizable compound is selected from the group consisting of monomers represented by the following formulas (1A) to (1D), and a heteroatom-containing aromatic monomer: 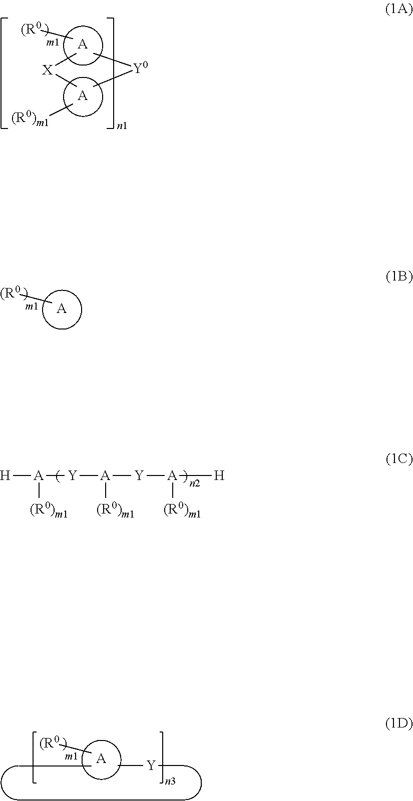
wherein in the formula (1A), each X independently represents an oxygen atom, a sulfur atom, a single bond or not a crosslink, Y⁰ is a 2n-valent group having 1 to 60 carbon atoms or a single bond, wherein when X is not a crosslink, Y⁰ is the 2n1-valent group, each A is independently benzene, biphenyl, terphenyl, diphenylmethylene, or a fused ring, each R⁰ is independently a hydrogen atom, an alkyl group having 1 to 40 carbon atoms and optionally having a substituent, an aryl group having 6 to 40 carbon atoms and optionally having a substituent, an alkenyl group having 2 to 40 carbon atoms and optionally having a substituent, an alkynyl group having 2 to 40 carbon atoms, an alkoxy group having 1 to 40 carbon atoms and optionally having a substituent, a halogen atom, a thiol group, an amino group, a nitro group, a carboxyl group, or a hydroxyl group, wherein at least one R⁰ is a hydroxyl group, an alkoxy group having 1 to 40 carbon atoms and optionally having a substituent, or an amino group having 0 to 40 carbon atoms and optionally having a substituent, each m1 is independently an integer of 1 or more, and n1 is an integer of 1 to 4;
in the formula (1B), A, R⁰, and m1 are as defined in the formula (1A), and at least one R⁰ is a hydroxyl group, an alkoxy group having 1 to 40 carbon atoms and optionally having a substituent, or an amino group having 0 to 40 carbon atoms and optionally having a substituent;
in the formula (1C), n2 is an integer of 1 to 500, and Y is a divalent group having 1 to 60 carbon atoms or a single bond, and A, R⁰, and m1 are as defined in the formula (1A), and at least one R⁰ is a hydroxyl group, an alkoxy group having 1 to 40 carbon atoms and optionally having a substituent, or an amino group having 0 to 40 carbon atoms and optionally having a substituent; and
in the formula (1D), n3 is an integer of 1 to 10, Y is as defined in the formula (1C), A, R⁰, and m1 are as defined in the formula (1A), and at least one R⁰ is a hydroxyl group, an alkoxy group having 1 to 40 carbon atoms and optionally having a substituent, or an amino group having 0 to 40 carbon atoms and optionally having a substituent.

5. The polymer according to claim 4, wherein the compound represented by the following formula (1A) is a compound represented by the following formula (1A-1): 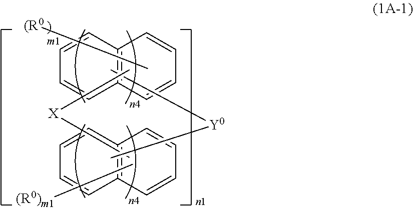
wherein each n4 is independently an integer of 0 to 3, and X, Y⁰, R⁰, m1, and n1 are as defined in the formula (1A).

6. The polymer according to claim 4, wherein A is benzene, biphenyl, terphenyl, diphenylmethylene, naphthalene, anthracene, naphthacene, pentacene, benzopyrene, chrysene, pyrene, triphenylene, coronylene, coronene, ovalene, and fluorene.

7. The polymer according to claim 4, wherein the compound represented by the formula (1C) is a compound represented by the following formula (1C-1): 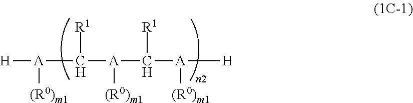
wherein each R¹ is independently a hydrogen atom, an alkyl group having 1 to 40 carbon atoms and optionally having a substituent, an aryl group having 6 to 40 carbon atoms and optionally having a substituent, an alkenyl group having 2 to 40 carbon atoms and optionally having a substituent, an alkynyl group having 2 to 40 carbon atoms, an alkoxy group having 1 to 40 carbon atoms and optionally having a substituent, a halogen atom, a thiol group, an amino group, a nitro group, a carboxyl group, or a hydroxyl group, A, R⁰, m1, and n2 are as defined in the formula (1C), and at least one R⁰ is a hydroxyl group, an alkoxy group having 1 to 40 carbon atoms and optionally having a substituent, or an amino group having 0 to 40 carbon atoms and optionally having a substituent.

8. The polymer according to claim 4, wherein the compound represented by the formula (1D) is a compound represented by the following formula (1D-1): 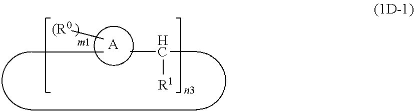
wherein each R¹ is independently a hydrogen atom, an alkyl group having 1 to 40 carbon atoms and optionally having a substituent, an aryl group having 6 to 40 carbon atoms and optionally having a substituent, an alkenyl group having 2 to 40 carbon atoms and optionally having a substituent, an alkynyl group having 2 to 40 carbon atoms, an alkoxy group having 1 to 40 carbon atoms and optionally having a substituent, a halogen atom, a thiol group, an amino group, a nitro group, a carboxyl group, or a hydroxyl group, A, R⁰, m1, and n3 are as defined in the formula (1D), and at least one R⁰ is a hydroxyl group, an alkoxy group having 1 to 40 carbon atoms and optionally having a substituent, or an amino group having 0 to 40 carbon atoms and optionally having a substituent.

9. The polymer according to claim 4, wherein the heteroatom-containing aromatic monomer comprises a heterocyclic aromatic compound.

10. A composition comprising the polymer according to claim 1.

11. The composition according to claim 10, further comprising a solvent.

12. The composition according to claim 11, wherein the solvent comprises at least one selected from the group consisting of propylene glycol monomethyl ether, propylene glycol monomethyl ether acetate, cyclohexanone, cyclopentanone, ethyl lactate, and methyl hydroxyisobutyrate.

13. The composition according to claim 11, wherein a content of impurity metal is less than 500 ppb for each metal species.

14. The composition according to claim 13, wherein the impurity metal comprises at least one selected from the group consisting of copper, manganese, iron, cobalt, ruthenium, chromium, nickel, tin, lead, silver, and palladium.

15. The composition according to claim 13, wherein the content of the impurity metal is 1 ppb or less.

16. A method for producing the polymer according to claim 1 comprising the step of:
polymerizing one or more monomers represented by the formula (0) in the presence of an oxidizing agent.

17. The method for producing the polymer according to claim 16, comprising the step of:
polymerizing one or more monomers represented by the formula (0) and an other copolymerizable compound that is copolymerizable with the monomer represented by the formula (0) in the presence of an oxidizing agent.

18. The method for producing the polymer according to claim 16, wherein the oxidizing agent is a metal salt or metal complex containing at least one selected from the group consisting of copper, manganese, iron, cobalt, ruthenium, chromium, nickel, tin, lead, silver, and palladium.

19. A composition for film formation comprising the polymer according to claim 1.

20. A resist composition comprising the composition for film formation according to claim 19.

21. The resist composition according to claim 20, further comprising at least one selected from the group consisting of a solvent, an acid generating agent, a base generating agent, and an acid diffusion controlling agent.

22. A resist pattern formation method, comprising the steps of:
forming a resist film on a substrate using the resist composition according to claim 20;
exposing at least a portion of the formed resist film; and
developing the exposed resist film, thereby forming a resist pattern.

23. A radiation-sensitive composition comprising the composition for film formation according to claim 19, an optically active diazonaphthoquinone compound, and a solvent,
wherein a content of the solvent is 20 to 99 parts by mass based on 100 parts by mass in total of the radiation-sensitive composition, and
a content of a solid content except for the solvent is 1 to 80 parts by mass based on 100 parts by mass in total of the radiation-sensitive composition.

24. A resist pattern formation method, comprising the steps of:
forming a resist film on a substrate using the radiation-sensitive composition according to claim 23;
exposing at least a portion of the formed resist film; and
developing the exposed resist film, thereby forming a resist pattern.

25. A composition for underlayer film formation for lithography comprising the composition for film formation according to claim 19.

26. The composition for underlayer film formation for lithography according to claim 25, further comprising at least one selected from the group consisting of a solvent, an acid generating agent, a base generating agent, and a crosslinking agent.

27. A method for producing an underlayer film for lithography, comprising the step of:
forming an underlayer film on a substrate using the composition for underlayer film formation for lithography according to claim 25.

28. A resist pattern formation method, comprising the steps of:
forming an underlayer film on a substrate using the composition for underlayer film formation for lithography according to claim 25;
forming at least one photoresist layer on the underlayer film; and
irradiating a predetermined region of the photoresist layer with radiation for development, thereby forming a resist pattern.

29. A circuit pattern formation method, comprising the steps of:
forming an underlayer film on a substrate using the composition for underlayer film formation for lithography according to claim 25;
forming an intermediate layer film on the underlayer film using a resist intermediate layer film material containing a silicon atom;
forming at least one photoresist layer on the intermediate layer film;
irradiating a predetermined region of the photoresist layer with radiation for development, thereby forming a resist pattern;
etching the intermediate layer film with the resist pattern as a mask, thereby forming an intermediate layer film pattern;
etching the underlayer film with the intermediate layer film pattern as an etching mask, thereby forming an underlayer film pattern; and
etching the substrate with the underlayer film pattern as an etching mask, thereby forming a pattern on the substrate.

30. A composition for optical member formation comprising the composition for film formation according to claim 19.

31. The composition for optical member formation according to claim 30, further comprising at least one selected from the group consisting of a solvent, an acid generating agent, a base generating agent, and a crosslinking agent.

32. A purification method comprising the steps of:
obtaining a solution (S) by dissolving the polymer according to claim 1 in a solvent; and
extracting impurities in the polymer by bringing the obtained solution (S) into contact with an acidic aqueous solution (a first extraction step),
wherein the solvent used in the step of obtaining the solution (S) contains an organic solvent that does not inadvertently mix with water.
